(19) United States
(12) Patent Application Publication
(10) Pub. No.: US 2024/0347644 A1
(43) Pub. Date: Oct. 17, 2024

(54) SEMICONDUCTOR DEVICE

(71) Applicant: Semiconductor Energy Laboratory Co., Ltd., Atsugi-shi (JP)

(72) Inventors: Shun OHTA, Atsugi (JP); Rena WAKASA, Atsugi (JP); Jesper EKLIND, Uppsala (SE); Yuichi SATO, Isehara (JP)

(21) Appl. No.: 18/627,560

(22) Filed: Apr. 5, 2024

(30) Foreign Application Priority Data
Apr. 12, 2023 (JP) 2023-065108
May 11, 2023 (JP) 2023-078845

(51) Int. Cl. H01L 29/786

(52) U.S. Cl. CPC H01L 29/7869

(57) ABSTRACT

A semiconductor device having excellent electrical characteristics is provided. The semiconductor device includes a first conductive layer, a first insulating layer over the first conductive layer, an oxide semiconductor layer over the first insulating layer, a second conductive layer, a third conductive layer, and a second insulating layer over the oxide semiconductor layer, and a fourth conductive layer over the second insulating layer. The second conductive layer and the third conductive layer each contain tantalum and nitrogen. In each of the second conductive layer and the third conductive layer, the percentage of a first tantalum bonding state is lower than or equal to 3%, and the percentage of a second tantalum bonding state is higher than or equal to 5%. The first tantalum bonding state is a bonding state of tantalum metal and a bonding state of tantalum nitride with stoichiometrically less nitrogen per tantalum, and the second tantalum bonding state is a bonding state of tantalum nitride with stoichiometrically equal nitrogen per tantalum.

### BACKGROUND OF THE INVENTION

### 1. Field of the Invention

One embodiment of the present invention relates to a semiconductor device, a memory device, a display device, and an electronic device. One embodiment of the present invention also relates to a method for fabricating a semiconductor device.

One embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device means a device that utilizes semiconductor characteristics, and refers to a semiconductor element (e.g., a transistor, a diode, or a photodiode), a circuit including the semiconductor element, a device that includes the circuit including the semiconductor element, and the like. The semiconductor device also means devices that can function by utilizing semiconductor characteristics. For example, an integrated circuit, a chip including an integrated circuit, and an electronic component including a chip in a package are examples of the semiconductor device. In some cases, a memory device, a display device, a light-emitting apparatus, a lighting device, and an electronic device themselves are semiconductor devices and also include a semiconductor device.

### 2. Description of the Related Art

In recent years, semiconductor devices have been developed to be used mainly for a large scale integration (LSI), a central processing unit (CPU), a memory, and the like. A CPU is an aggregation of semiconductor elements; the CPU includes a semiconductor integrated circuit (including at least a transistor) formed into a chip by processing a semiconductor wafer, and is provided with an electrode that is a connection terminal.

A semiconductor circuit (integrated circuit (IC) chip) of an LSI, a CPU, a memory, or the like is mounted on a circuit board, for example, a printed wiring board, to be used as one of components of a variety of electronic devices.

A technique by which a transistor is formed using a semiconductor thin film formed over a substrate having an insulating surface has been attracting attention. The transistor is used in a wide range of electronic devices such as an IC and an image display device (also simply referred to as a display device). A silicon-based semiconductor material is widely known as a material of a semiconductor thin film that can be used in a transistor. As another material, an oxide semiconductor has been attracting attention.

It is known that a transistor including an oxide semiconductor has an extremely low leakage current in an off state. For example, Patent Document 1 discloses a low-power CPU utilizing a characteristic of a low leakage current of the transistor including an oxide semiconductor. Furthermore, for example, Patent Document 2 discloses a memory device that can retain stored data for a long time by utilizing a characteristic of a low leakage current of the transistor including an oxide semiconductor.

In recent years, demand for an integrated circuit with higher density has risen with reductions in size and weight of electronic devices. In addition, the productivity of a semiconductor device including an integrated circuit is desired to be improved.

### REFERENCES

### Patent Documents

[Patent Document 1] Japanese Published Patent Application No. 2012-257187
[Patent Document 2] Japanese Published Patent Application No. 2011-151383

### SUMMARY OF THE INVENTION

An object of one embodiment of the present invention is to provide a semiconductor device having excellent electrical characteristics. Another object of one embodiment of the present invention is to provide a semiconductor device with a high on-state current. Another object of one embodiment of the present invention is to provide a semiconductor device with a small variation in electrical characteristics of transistors. Another object of one embodiment of the present invention is to provide a highly reliable semiconductor device. Another object of one embodiment of the present invention is to provide a semiconductor device that can be scaled down or highly integrated. Another object of one embodiment of the present invention is to provide a semiconductor device with low power consumption.

Note that the description of these objects does not preclude the existence of other objects. One embodiment of the present invention does not need to achieve all of these objects. Other objects will be apparent from and can be derived from the description of the specification, the drawings, the claims, and the like.

One embodiment of the present invention is a semiconductor device including a first conductive layer, a first insulating layer over the first conductive layer, an oxide semiconductor layer over the first insulating layer, a second conductive layer, a third conductive layer, and a second insulating layer over the oxide semiconductor layer, a third insulating layer over the second conductive layer and the third conductive layer, and a fourth conductive layer over the second insulating layer. The third insulating layer has an opening portion reaching the oxide semiconductor layer. The second insulating layer and the fourth conductive layer are positioned in the opening portion. The top surface of the third insulating layer is level with the top surface of the fourth conductive layer. The second conductive layer and the third conductive layer each contain tantalum and nitrogen. The percentage of a first tantalum bonding state is lower than or equal to 3% and the percentage of a second tantalum bonding state is higher than or equal to 5% in each of the second conductive layer and the third conductive layer. The first tantalum bonding state is a bonding state of tantalum metal and a bonding state of tantalum nitride with stoichiometrically less nitrogen per tantalum. The second tantalum bonding state is a bonding state of tantalum nitride with stoichiometrically equal nitrogen per tantalum.

In the semiconductor device, the percentage of the first tantalum bonding state and the percentage of the second tantalum bonding state are preferably calculated by waveform analysis on an X-ray photoelectron spectroscopy (XPS) spectrum of tantalum 4f obtained by XPS.

In the semiconductor device, it is preferable that X-ray diffraction (XRD) spectra of the second conductive layer and the third conductive layer each have a first peak having a peak position in a range of 2θ=35.5±1.0 deg. and a second peak having a peak position in a range of 2θ=41.2±2.0 deg., and that the ratio of a peak level of the second peak to a peak level of the first peak be greater than or equal to 0.2 and less than or equal to 1.0.

In the semiconductor device, the oxide semiconductor layer preferably contains at least one of indium and zinc.

Another embodiment of the present invention is a semiconductor device including a first conductive layer, a first insulating layer over the first conductive layer, an oxide semiconductor layer over the first insulating layer, a second conductive layer, a third conductive layer, and a second insulating layer over the oxide semiconductor layer, a third insulating layer over the second conductive layer and the third conductive layer, and a fourth conductive layer over the second insulating layer. The third insulating layer has an opening portion reaching the oxide semiconductor layer. The second insulating layer and the fourth conductive layer are positioned in the opening portion. The top surface of the third insulating layer is level with the top surface of the fourth conductive layer. XRD spectra of the second conductive layer and the third conductive layer each have a first peak having a peak position in a range of 2θ=35.5±1.0 deg. and a second peak having a peak position in a range of 2θ=41.2±2.0 deg. The ratio of a peak level of the second peak to a peak level of the first peak is greater than or equal to 0.2 and less than or equal to 1.0.

In the semiconductor device, the second conductive layer and the third conductive layer each preferably contain tantalum and nitrogen.

In the semiconductor device, the oxide semiconductor layer preferably contains at least one of indium and zinc.

One embodiment of the present invention can provide a semiconductor device having excellent electrical characteristics. One embodiment of the present invention can provide a semiconductor device with a high on-state current. One embodiment of the present invention can provide a semiconductor device with a small variation in electrical characteristics of transistors. One embodiment of the present invention can provide a highly reliable semiconductor device. One embodiment of the present invention can provide a semiconductor device that can be scaled down or highly integrated. One embodiment of the present invention can provide a semiconductor device with low power consumption.

Note that the description of these effects does not preclude the existence of other effects. One embodiment of the present invention does not necessarily achieve all of these effects. Other effects will be apparent from and can be derived from the description of the specification, the drawings, the claims, and the like.

### BRIEF DESCRIPTION OF THE DRAWINGS

In the accompanying drawings:

FIG. 1A is a plan view illustrating an example of a semiconductor device, and

FIGS. 1B to 1D are cross-sectional views illustrating an example of the semiconductor device;

FIGS. 2A and 2B are cross-sectional views illustrating examples of a semiconductor device;

FIG. 3 is a cross-sectional view illustrating an example of a semiconductor device;

FIGS. 4A and 4B are cross-sectional views illustrating an example of a semiconductor device;

FIGS. 5A and 5B are cross-sectional views illustrating an example of a semiconductor device;

FIG. 6A is a plan view illustrating an example of a semiconductor device, and FIG. 6B is a cross-sectional view illustrating an example of the semiconductor device;

FIG. 7 is a cross-sectional view illustrating an example of a semiconductor device;

FIG. 8A is a block diagram illustrating a structure example of a memory device of one embodiment of the present invention, and FIG. 8B is a perspective view illustrating a structure example of the memory device of one embodiment of the present invention;

FIGS. 9A to 9I are circuit diagrams each illustrating a structure example of a memory cell of one embodiment of the present invention;

FIG. 10 is a cross-sectional view illustrating an example of a memory device;

FIG. 11 is a cross-sectional view illustrating an example of a memory device;

FIGS. 12A and 12B illustrate examples of electronic components;

FIGS. 13A and 13B illustrate examples of electronic devices, and FIGS. 13C to 13E illustrate an example of a large computer;

FIG. 14 illustrates an example of space equipment;

FIG. 15 illustrates an example of a storage system that can be used in a data center;

FIGS. 16A to 16C are schematic cross-sectional views of samples in Example;

FIGS. 17A to 17C show XPS spectra in Example;

FIGS. 18A to 18H show XPS spectra in Example;

FIG. 19 shows XPS analysis results in Example;

FIG. 20 shows the resistivity of tantalum nitride films in Example;

FIG. 21 shows the relationship between conductivity and chemical shift values in Example;

FIG. 22 shows XRD analysis results in Example;

FIG. 23 shows XRD analysis results in Example;

FIG. 24 shows XRD analysis results in Example;

FIG. 25 shows D-SIMS analysis results in Example;

FIGS. 26A to 26H are cross-sectional STEM images of samples in Example;

FIGS. 27A and 27B are cross-sectional STEM images of samples in Example;

FIGS. 28A and 28B show EDX analysis results in Example;

FIGS. 29A and 29B are cross-sectional STEM images of samples in Example, and FIGS. 29C to 29F show EDX maps of the samples in Example;

FIGS. 30A to 30D show UPS spectra in Example;

FIGS. 31A to 31D show UPS spectra in Example;

FIGS. 32A to 32C show UPS spectra in Example;

FIG. 33A shows the Tauc plot in Example, and FIG. 33B shows absorption spectra in Example;

FIGS. 34A to 34C each show the Tauc plot in Example;

FIGS. 35A to 35D show the Id-Vg curves of transistors fabricated in Example;

FIGS. 36A to 36D show the Id-Vg curves of transistors fabricated in Example;

FIG. 37 shows the resistivity of tantalum nitride films in Example;

FIG. 38 shows results obtained by a TLM method in Example; and

FIG. 39A shows the relationship between contact conductance and chemical shift values in Example, and FIG. 39B shows XPS analysis results in Example.

### DETAILED DESCRIPTION OF THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in the structures of the invention described below, the same portions or portions having similar functions are denoted by the same reference numerals in different drawings, and description of such portions is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

A transistor is a kind of semiconductor element and enables amplification of current or voltage, switching operation for controlling conduction or non-conduction, and the like. A transistor in this specification includes, in its category, an insulated-gate field effect transistor (IGFET) and a thin film transistor (TFT).

In this specification and the like, a transistor containing an oxide semiconductor or a metal oxide in its semiconductor layer and a transistor containing an oxide semiconductor or a metal oxide in its channel formation region are each sometimes referred to as an OS transistor. In addition, a transistor containing silicon in its channel formation region is sometimes referred to as a Si transistor.

In this specification and the like, a transistor is an element including at least three terminals of a gate, a drain, and a source. The transistor includes a region where a channel is formed (also referred to as a channel formation region) between the drain (a drain terminal, a drain region, or a drain electrode) and the source (a source terminal, a source region, or a source electrode), and current can flow between the source and the drain through the channel formation region. Note that in this specification and the like, a channel formation region refers to a region through which current mainly flows.

The functions of a “source” and a “drain” are sometimes replaced with each other when a transistor of different polarity is used or when the direction of current flow is changed in circuit operation, for example. Thus, the terms “source” and “drain” can be used interchangeably in this specification.

Note that impurities in a semiconductor refer to, for example, elements other than the main components of the semiconductor. For example, an element with a concentration lower than 0.1 atomic % is an impurity. When a semiconductor contains an impurity, an increase in density of defect states or a reduction in crystallinity of the semiconductor may occur, for example. In the case where the semiconductor is an oxide semiconductor, examples of an impurity that changes the characteristics of the semiconductor include Group 1 elements, Group 2 elements, Group 13 elements, Group 14 elements, Group 15 elements, and transition metals other than the main components of the oxide semiconductor. Specific examples include hydrogen, lithium, sodium, silicon, boron, phosphorus, carbon, and nitrogen. Note that water also serves as an impurity in some cases. Entry of an impurity may cause oxygen vacancies (also referred to as V_{O}) in an oxide semiconductor, for example.

Note that in this specification and the like, an oxynitride refers to a material in which an oxygen content is higher than a nitrogen content. A nitride oxide refers to a material in which a nitrogen content is higher than an oxygen content.

The contents of elements such as hydrogen, oxygen, carbon, and nitrogen in a film can be analyzed by secondary ion mass spectrometry (SIMS) or XPS, for example. Note that XPS is suitable when the content percentage of a target element is high (e.g., 0.5 atomic % or higher, or 1 atomic % or higher). By contrast, SIMS is suitable when the content percentage of a target element is low (e.g., 0.5 atomic % or lower, or 1 atomic % or lower). To compare the contents of elements, analysis with a combination of SIMS and XPS is preferably used.

Note that the terms “film” and “layer” can be used interchangeably depending on the case or the circumstances. For example, the term “conductive layer” can be replaced with the term “conductive film”. For another example, the term “insulating film” can be replaced with the term “insulating layer”.

In this specification and the like, the term “parallel” indicates that the angle formed between two straight lines is greater than or equal to −10° and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. The term “substantially perpendicular” indicates that the angle formed between two straight lines is greater than or equal to 60° and less than or equal to 120°.

In this specification and the like, the term “electrically connected” includes the case where components are connected to each other through an “object having any electric action”. There is no particular limitation on an “object having any electric action” as long as electric signals can be transmitted and received between components that are connected through the object. Examples of the “object having any electric action” include a switching element such as a transistor, a resistor, a coil, and an element with a variety of functions as well as an electrode and a wiring.

Unless otherwise specified, an off-state current in this specification and the like refers to leakage current between a source and a drain generated when a transistor is in an off state (also referred to as a non-conducting state or a cutoff state). Unless otherwise specified, the off state of an n-channel transistor means that a gate-source voltage V_{gs} is lower than a threshold voltage Vₜₕ, and the off state of a p-channel transistor means that V_{gs} is higher than Vₜₕ.

In this specification and the like, “normally on” means a state where a channel exists without application of voltage to a gate and current flows through a transistor. Furthermore, “normally off” means a state where current does not flow through a transistor when no potential or a ground potential is applied to a gate.

In this specification and the like, the term “leakage current” sometimes expresses the same meaning as “off-state current”. In this specification and the like, the off-state current sometimes refers to current that flows between a source and a drain of a transistor in the off state, for example.

In this specification and the like, a top surface shape of a component means the outline of the component in a plan view. A plan view means that the component is observed from a normal direction of a surface where the component is formed or from a normal direction of a surface of a support (e.g., a substrate) where the component is formed.

In this specification and the like, the expression “having substantially the same top-view shapes” means that the outlines of stacked layers at least partly overlap with each other. For example, the expression encompasses the case of processing or partly processing an upper layer and a lower layer with the use of the same mask pattern. The expression “having substantially the same top-view shapes” also sometimes encompasses the case where the outlines do not completely overlap with each other; for instance, the outline of the upper layer may be located inward or outward from the outline of the lower layer. In the case where the top-view shapes are the same or substantially the same, the positions in a plan view can be regarded as being the same or substantially the same, the end portions can be regarded as being aligned or substantially aligned with each other, or the side end portions can be regarded as being aligned or substantially aligned with each other.

In this specification and the like, the expression “level with” indicates a structure having the same level from a reference surface (e.g., a flat surface such as a substrate surface) in a cross-sectional view. For example, in a manufacturing process of a semiconductor device, planarization treatment (typically, CMP treatment) is performed, whereby the surface(s) of a single layer or a plurality of layers are exposed in some cases. In that case, the surfaces on which the CMP treatment is performed are at the same level from a reference surface. Note that a plurality of layers may be on different levels depending on a treatment apparatus, a treatment method, or a material of the treated surfaces, used for the CMP treatment. This case is also included in the scope of “level with” in this specification and the like. For example, the expression “level with” also includes the case where two layers (here, a first layer and a second layer) have different two levels with respect to a reference surface and the difference in the top-surface level between the first and second layers is less than or equal to 20 nm.

In general, it is difficult to clearly differentiate “completely aligned” from “substantially aligned”. Thus, in this specification and the like, the expression “aligned” includes both “completely aligned” and “substantially aligned”.

Examples of an opening include a groove and a slit. A region where the opening is formed may be referred to as an opening portion.

In the drawings used in embodiments, a sidewall of an insulating layer in an opening portion is substantially perpendicular to a substrate surface or a formation surface, but the sidewall may have a tapered shape.

In this specification and the like, a tapered shape refers to a shape such that at least part of a side surface of a component is inclined with respect to a substrate surface or a formation surface of the component. For example, a tapered shape includes a region where the angle between the inclined side surface and the substrate surface or formation surface (such an angle is also referred to as a taper angle) is greater than 0° and less than 90°. Note that the side surface of the component, the substrate surface, and the formation surface are not necessarily completely flat and may be substantially flat with a slight curvature or with slight unevenness.

In this specification and the like, when the expression “A is in contact with B” is used, at least part of A is in contact with B. In other words, A includes a region in contact with B, for example.

In this specification and the like, when the expression “A is positioned over B” is used, at least part of A is positioned over B. In other words, A includes a region positioned over B, for example.

In this specification and the like, when the expression “A covers B” is used, at least part of A covers B. In other words, A includes a region covering B, for example.

In this specification and the like, when the expression “A overlaps with B” is used, at least part of A overlaps with B. In other words, A includes a region overlapping with B, for example.

In this specification and the like, disconnection refers to a phenomenon in which a layer, a film, or an electrode is split because of the shape of its formation surface (e.g., a step).

### Embodiment 1

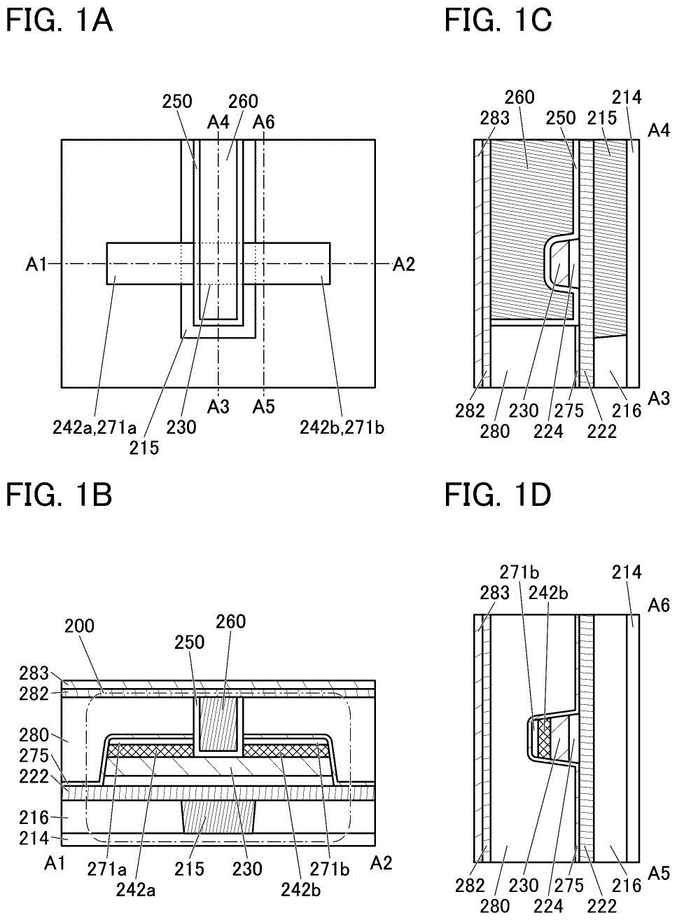

In this embodiment, a structure example of a semiconductor device of one embodiment of the present invention will be described with reference to FIGS. 1A to 1D, FIGS. 2A and 2B, FIG. 3, FIGS. 4A and 4B, FIGS. 5A and 5B, FIGS. 6A and 6B, and FIG. 7. The semiconductor device of one embodiment of the present invention includes a transistor.

### <Structure Example of Semiconductor Device>

A structure of a semiconductor device including a transistor 200 is described with reference to FIGS. 1A to 1D. FIGS. 1A to 1D are a plan view and cross-sectional views of the semiconductor device. FIG. 1B is a cross-sectional view taken along the dashed-dotted line A1-A2 in FIG. 1A, which corresponds to a cross-sectional view of the transistor 200 in the channel length direction. FIG. 1C is a cross-sectional view taken along the dashed-dotted line A3-A4 in FIG. 1A, which corresponds to a cross-sectional view of the transistor 200 in the channel width direction. FIG. 1D is a cross-sectional view taken along the dashed-dotted line A5-A6 in FIG. 1A. Note that for simplification, some components are not illustrated in the plan view of FIG. 1A.

The semiconductor device of one embodiment of the present invention includes an insulating layer 214 over a substrate (not illustrated), the transistor 200 over the insulating layer 214, an insulating layer 280 over the transistor 200, an insulating layer 282 over the insulating layer 280, and an insulating layer 283 over the insulating layer 282. The insulating layers 214, 280, 282, and 283 each function as an interlayer film.

As illustrated in FIGS. 1A to 1D, the transistor 200 includes an insulating layer 216 over the insulating layer 214, a conductive layer 215 provided to be embedded in the insulating layer 216, an insulating layer 222 over the insulating layer 216 and the conductive layer 215, an insulating layer 224 over the insulating layer 222, an oxide semiconductor layer 230 over the insulating layer 224, a conductive layer 242a and a conductive layer 242b over the oxide semiconductor layer 230, an insulating layer 271a over the conductive layer 242a, an insulating layer 271b over the conductive layer 242b, an insulating layer 250 over the oxide semiconductor layer 230, and a conductive layer 260 over the insulating layer 250. An insulating layer 275 is provided over the insulating layers 271a and 271b, and the insulating layer 280 is provided over the insulating layer 275.

Hereinafter, the conductive layers 242a and 242b are collectively referred to as a conductive layer 242 in some cases. The insulating layers 271a and 271b are collectively referred to as an insulating layer 271 in some cases.

An opening portion reaching the oxide semiconductor layer 230 is formed in the insulating layers 280 and 275. The insulating layer 250 and the conductive layer 260 are provided in the opening portion. The conductive layer 260 and the insulating layer 250 are provided between the conductive layers 242a and 242b and between the insulating layers 271a and 271b in the channel length direction of the transistor 200.

The conductive layer 260 is formed in a self-aligned manner to fill the opening portion formed in the insulating layers 280 and 275. In this manner, the conductive layer 260 can surely be provided in a region between the conductive layers 242a and 242b without alignment.

As illustrated in FIGS. 1B and 1C, the top surface of the conductive layer 260 is level with the top surface of the insulating layer 280.

In the transistor 200, the conductive layer 260 functions as a first gate (also referred to as a top gate) electrode, and the conductive layer 215 functions as a second gate (also referred to as a back gate) electrode. The insulating layer 250 functions as a first gate insulating layer, and the insulating layers 222 and 224 function as a second gate insulating layer. Note that the gate insulating layer is also referred to as a gate insulating film in some cases. The conductive layer 242a functions as one of a source electrode and a drain electrode, and the conductive layer 242b functions as the other of the source electrode and the drain electrode. A region of the oxide semiconductor layer 230 that overlaps with the conductive layer 260 at least partly functions as a channel formation region.

The conductive layer 215 is provided to overlap with the oxide semiconductor layer 230 and the conductive layer 260. Here, the conductive layer 215 is provided to fill an opening portion formed in the insulating layer 216. Note that part of the conductive layer 215 is embedded in the insulating layer 214 in some cases.

The conductive layer 215 functions as a second gate electrode in some cases. In that case, by changing a potential applied to the conductive layer 215 independently of a potential applied to the conductive layer 260, the threshold voltage Vₜₕ of the transistor 200 can be controlled. In particular, by applying a negative potential to the conductive layer 215, Vₜₕ of the transistor 200 can be higher, and its off-state current can be reduced. Thus, a drain current at the time when a potential applied to the conductive layer 260 is 0 V can be lower in the case where a negative potential is applied to the conductive layer 215 than in the case where the negative potential is not applied to the conductive layer 215.

As illustrated in FIG. 1A, the size of the conductive layer 215 is preferably larger than the size of a region of the oxide semiconductor layer 230 that does not overlap with the conductive layers 242a and 242b. As illustrated in FIG. 1C, it is particularly preferable that the conductive layer 215 extend beyond the end portion of the oxide semiconductor layer 230 in the channel width direction. That is, the conductive layers 215 and 260 preferably overlap with each other with the insulating layer positioned therebetween, in a region beyond the side surface of the oxide semiconductor layer 230 in the channel width direction. With such a structure, the channel formation region in the oxide semiconductor layer 230 can be electrically surrounded by the electric field of the conductive layer 260 functioning as a first gate electrode and the electric field of the conductive layer 215 functioning as a second gate electrode. In this specification, a transistor structure in which a channel formation region is electrically surrounded by at least the electric field of a first gate electrode is referred to as a surrounded channel (S-channel) structure.

In this specification and the like, the S-channel structure refers to a transistor structure in which a channel formation region is electrically surrounded by the electric fields of a pair of gate electrodes. The S-channel structure disclosed in this specification and the like is different from a Fin structure or a planar structure. The S-channel structure disclosed in this specification and the like can be regarded as a kind of the Fin structure. In this specification and the like, the Fin structure refers to a structure in which at least two surfaces (specifically, two surfaces, three surfaces, four surfaces, or the like) of a channel are covered with a gate electrode. With the use of the Fin structure or the S-channel structure, a transistor with high resistance to a short-channel effect, i.e., a transistor in which a short-channel effect is unlikely to occur, can be obtained.

When the transistor 200 has the above-described S-channel structure, the channel formation region can be electrically surrounded. Since the S-channel structure is a structure with the electrically surrounded channel formation region, the S-channel structure is, in a sense, equivalent to a gate all around (GAA) structure or a lateral gate all around (LGAA) structure. When the transistor 200 has any of the S-channel structure, the GAA structure, and the LGAA structure, the channel formation region formed at the interface between the oxide semiconductor layer 230 and the gate insulating layer or in the vicinity thereof can correspond to the whole of bulk in the oxide semiconductor layer 230. Consequently, the density of current flowing through the transistor can be improved, so that the on-state current or the field-effect mobility of the transistor can be increased.

As illustrated in FIG. 1C, the conductive layer 215 is extended to have a function of a wiring. However, without limitation to this structure, a structure in which a conductor functioning as a wiring is provided below the conductive layer 215 may be employed. In addition, the conductive layer 215 is not necessarily provided in each transistor. For example, the conductive layer 215 may be shared by a plurality of transistors.

In the channel width direction of the transistor 200 as illustrated in FIG. 1C, with the level of the insulating layer 222 as a reference, the level of a region of the bottom surface of the conductive layer 260 that does not overlap with the oxide semiconductor layer 230 is preferably lower than the level of the bottom surface of the oxide semiconductor layer 230. When the conductive layer 260 functioning as the gate electrode covers the side and top surfaces of the channel formation region of the oxide semiconductor layer 230, the electric field of the conductive layer 260 is likely to affect the entire channel formation region of the oxide semiconductor layer 230. Hence, the transistor 200 can have a higher on-state current and higher frequency characteristics.

As illustrated in FIG. 1C, the oxide semiconductor layer 230 may have a curved surface between the side and top surfaces in a cross-sectional view in the channel width direction of the transistor 200. Such a shape can improve the coverage of the oxide semiconductor layer 230 with the insulating layer 250 and the conductive layer 260.

The transistor 200 contains a metal oxide functioning as a semiconductor (also referred to as an oxide semiconductor) in the oxide semiconductor layer 230 including a channel formation region. That is, the transistor 200 can be regarded as an OS transistor.

The semiconductor device of this embodiment includes an OS transistor. The OS transistor has a low off-state current and thus can achieve a semiconductor device with low power consumption. The OS transistor also has excellent frequency characteristics and thus can achieve a semiconductor device with a high operation speed. With the use of the OS transistor, a semiconductor device with excellent electrical characteristics, a semiconductor device with a small variation in the electrical characteristics of transistors, a semiconductor device with a high on-state current, and a semiconductor device with high reliability can be achieved.

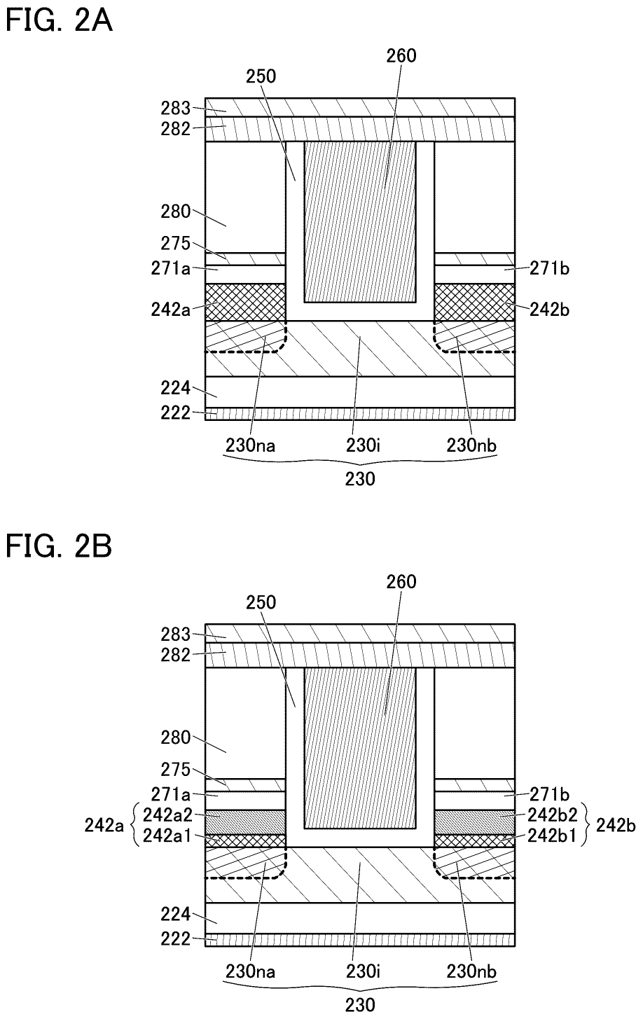

FIG. 2A is an enlarged view of the vicinity of the channel formation region in FIG. 1B. As illustrated in FIG. 2A, the oxide semiconductor layer 230 includes a region 230i functioning as a channel formation region and a region 230na and a region 230nb that are provided to sandwich the region 230i and function as a source region and a drain region. At least part of the region 230i overlaps with the conductive layer 260. In other words, the region 230i is provided between the conductive layers 242a and 242b. The region 230na is provided to overlap with the conductive layer 242a, and the region 230nb is provided to overlap with the conductive layer 242b.

When impurities and oxygen vacancies (V_{O}) are in a channel formation region of an oxide semiconductor in an OS transistor, the electrical characteristics of the OS transistor easily vary and the reliability thereof might worsen. In an oxide semiconductor, a defect that is an oxygen vacancy into which hydrogen enters (hereinafter, sometimes referred to as V_{O}H) generates an electron serving as a carrier in some cases. Formation of V_{O}H in the channel formation region may increase the donor concentration in the channel formation region. An increase in the donor concentration in the channel formation region may lead to a variation in threshold voltage. Thus, when the channel formation region in the oxide semiconductor includes oxygen vacancies, the OS transistor tends to be normally on. Therefore, the impurities, oxygen vacancies, and V_{O}H are preferably reduced as much as possible in the channel formation region in the oxide semiconductor. In other words, the oxide semiconductor preferably includes an i-type (intrinsic) or substantially i-type channel formation region with a low carrier concentration.

By contrast, when an insulator containing oxygen that is released by heating (hereinafter, sometimes referred to as excess oxygen) is provided in the vicinity of the oxide semiconductor and heat treatment is performed, oxygen can be supplied from the insulator to the oxide semiconductor so as to reduce oxygen vacancies and V_{O}H. Note that too much oxygen supplied to the source region or the drain region might cause a decrease in the on-state current or the field-effect mobility of the transistor 200. Furthermore, a variation in the amount of oxygen supplied to the source region or the drain region on the substrate plane leads to variable characteristics of the semiconductor device including the transistor.

Hence, the region 230i functioning as the channel formation region in the oxide semiconductor layer 230 is preferably an i-type or substantially i-type region with a low carrier concentration, whereas the regions 230na and 230nb functioning as the source and drain regions are preferably n-type regions with a high carrier concentration. That is, it is preferable that oxygen vacancies and V_{O}H in the region 230i be reduced and supply of too much oxygen to the regions 230na and 230nb be prevented.

In other words, in the oxide semiconductor layer 230, the regions 230na and 230nb are preferably n-type regions with a high carrier concentration, whereas the region 230i is preferably an i-type or substantially i-type region with a low carrier concentration. That is, it is preferable that the n-type regions not extend to the channel formation region.

For example, the amount of oxygen vacancies in the region 230i is set smaller or the concentration of an impurity such as hydrogen, nitrogen, or a metal element in the region 230i is set lower than those in the regions 230na and 230nb, so that the region 230i can be a high-resistance region with a low carrier concentration. At this time, the region 230i can be regarded as being i-type (intrinsic) or substantially i-type.

For another example, a reduction in the amount of oxygen vacancies or the impurity concentration in the regions 230na and 230nb is inhibited, so that the regions 230na and 230nb can each be a low-resistance region with a high carrier concentration. At this time, the regions 230na and 230nb are each an n-type region having a higher carrier concentration and a lower resistance than the region 230i.

A region having a carrier concentration lower than or equal to that of the region 230na and higher than or equal to that of the region 230i may be formed between the regions 230i and 230na. That is, the region functions as a junction region between the regions 230i and 230na. The hydrogen concentration in the junction region is sometimes lower than or equal to that in the region 230na and higher than or equal to that in the region 230i. The amount of oxygen vacancies in the junction region is sometimes smaller than or equal to that in the region 230na and larger than or equal to that in the region 230i. The same applies to a region between the regions 230i and 230nb.

Although FIG. 2A illustrates an example in which the bottom surfaces of the regions 230na and 230nb are positioned above the insulating layer 224, the present invention is not limited thereto. For example, the bottom surfaces of the regions 230na and 230nb may extend to the interface between the oxide semiconductor layer 230 and the insulating layer 224.

In the oxide semiconductor layer 230, it is sometimes difficult to clearly observe the boundaries between the regions. The concentration of a metal element and an impurity such as hydrogen or nitrogen, which is detected in each region, may be gradually changed not only between the regions but also in each region. That is, the region closer to the channel formation region preferably has a lower concentration of an impurity such as hydrogen or nitrogen.

The conductive layers 242a and 242b are in contact with the oxide semiconductor layer 230. Thus, the conductive layers 242a and 242b are each preferably formed using a conductive material that is not easily oxidized or a conductive material having a function of inhibiting oxygen diffusion. This can inhibit a decrease in conductivity of the conductive layers 242a and 242b. Furthermore, the conductive layers 242a and 242b are each preferably formed using a conductive material that maintains low electric resistance even when oxidized or an oxide conductive material. This can inhibit a decrease in conductivity of the conductive layers 242a and 242b even when the conductive layers 242a and 242b are oxidized. Examples of the conductive material include a conductive material containing nitrogen and a conductive material containing oxygen.

For the conductive layers 242a and 242b, a nitride containing tantalum, a nitride containing titanium, a nitride containing molybdenum, a nitride containing tungsten, a nitride containing tantalum and aluminum, or a nitride containing titanium and aluminum is preferably used, for example. For another example, ruthenium, ruthenium oxide, ruthenium nitride, an oxide containing strontium and ruthenium, or an oxide containing lanthanum and nickel may be used. These materials are preferable because they are conductive materials that are not easily oxidized or materials that maintain their conductivity even after absorbing oxygen.

In one embodiment of the present invention, it is preferable to use a tantalum compound for each of the conductive layers 242a and 242b. The tantalum compound preferably contains tantalum nitride. In that case, the conductive layers 242a and 242b each contain at least tantalum and nitrogen.

Tantalum nitride has a variety of crystal structures such as β-Ta₂N (a hexagonal structure), θ-TaN (a hexagonal structure), δ-TaN (a cubic structure), ε-TaN (a hexagonal structure), Ta₃N₅ (a tetragonal structure), Ta₄N₅ (a tetragonal structure), and Ta₅N₆ (a hexagonal structure) depending on its composition. A tantalum compound sometimes has two or more of these crystal structures. Furthermore, a tantalum compound sometimes contains tantalum metal depending on its composition. In the case where a tantalum compound contains oxygen, the tantalum compound sometimes contains tantalum nitride oxide, tantalum oxynitride, tantalum oxide, or the like.

In addition, tantalum in a tantalum compound has a variety of bonding states depending on its crystal structure. Examples of a tantalum bonding state include a bonding state of tantalum metal, a bonding state of tantalum nitride with stoichiometrically less nitrogen per tantalum, a bonding state of tantalum nitride with stoichiometrically equal nitrogen per tantalum, a bonding state of tantalum nitride with stoichiometrically more nitrogen per tantalum, a bonding state of tantalum nitride oxide, a bonding state of tantalum oxynitride, and a bonding state of tantalum oxide.

In this specification and the like, a bonding state of tantalum metal refers to metallic bonding between tantalum atoms. In addition, tantalum metal sometimes refers to an aggregate of tantalum atoms. Tantalum nitride with stoichiometrically less nitrogen per tantalum refers to tantalum nitride whose atomic ratio of nitrogen to tantalum is lower than that in tantalum nitride in the stoichiometric composition. Tantalum nitride with stoichiometrically equal nitrogen per tantalum refers to tantalum nitride in the stoichiometric composition. Tantalum nitride with stoichiometrically more nitrogen per tantalum refers to tantalum nitride whose atomic ratio of nitrogen to tantalum is higher than that in tantalum nitride in the stoichiometric composition. Tantalum nitride in the stoichiometric composition refers to tantalum nitride whose atomic ratio of Ta to N is 1:1.

In this specification and the like, a bonding state of tantalum metal and a bonding state of tantalum nitride with stoichiometrically less nitrogen per tantalum are each referred to as a first tantalum bonding state. A bonding state of tantalum nitride with stoichiometrically equal nitrogen per tantalum and a bonding state of tantalum nitride oxide are each referred to as a second tantalum bonding state. A bonding state of tantalum nitride with stoichiometrically more nitrogen per tantalum is referred to as a third tantalum bonding state. A bonding state of tantalum oxynitride is referred to as a fourth tantalum bonding state. A bonding state of tantalum oxide is referred to as a fifth tantalum bonding state.

The above-described tantalum bonding states can be evaluated by XPS narrow scanning, for example. Note that in analysis by XPS (also referred to as XPS analysis), a chemical shift value (also referred to as a binding energy value) varies depending on an element bonding state. Specifically, in the case where tantalum exists in a bonding state of tantalum metal, a Ta4f_{7/2} peak having a peak position in a chemical shift value range from 21.5 eV to 22 eV is observed in a spectrum obtained by XPS analysis (also referred to as an XPS spectrum) of tantalum 4f. In the case where tantalum exists in a bonding state of tantalum nitride with stoichiometrically equal nitrogen per tantalum, a Ta4f_{7/2} peak having a peak position at a chemical shift value of around 23 eV is observed. In the case where tantalum exists in a bonding state of tantalum oxide, a Ta4f_{7/2} peak having a peak position in a chemical shift value range from 26 eV to 27 eV is observed.

In this specification and the like, a peak in XPS analysis refers to a convex shape appearing in an XPS spectrum. Note that one peak is sometimes formed by an overlap of a plurality of peaks. A peak position in XPS analysis refers to a binding energy value at a local maximum value of a convex shape (peak) appearing in an XPS spectrum.

Since a chemical shift value varies depending on a bonding state as described above, the percentages of element bonding states can be calculated by waveform analysis of an XPS spectrum, for example. Specifically, the measured XPS spectrum of tantalum 4f is subjected to fitting with the synthesized spectrum of peaks set in accordance with the tantalum bonding states, whereby the percentages of the tantalum bonding states can be calculated.

In this specification and the like, the percentage of an element bonding state refers to the proportion of the peak area of an XPS spectrum corresponding to a certain element bonding state in the sum of the peak areas of XPS spectra corresponding to assumed element bonding states. For example, on the assumption of a first element bonding state, a second element bonding state, and a third element bonding state, the percentage of the first element bonding state is calculated from the proportion of the peak area of an XPS spectrum corresponding to the first element bonding state in the sum of the peak area of the XPS spectrum corresponding to the first element bonding state, the peak area of an XPS spectrum corresponding to the second element bonding state, and the peak area of an XPS spectrum corresponding to the third element bonding state.

The tantalum 5d orbital mainly contributes to the conduction band of tantalum nitride. Maintaining the conductivity of a tantalum compound requires inhibiting a reduction in the number of electrons in the tantalum 5d orbital. In order to inhibit a reduction in the number of electrons in the tantalum 5d orbital to maintain the conductivity of a tantalum compound, the sum of the percentage of the first tantalum bonding state and the percentage of the second tantalum bonding state is preferably high in each of the conductive layers 242a and 242b.

Meanwhile, the first tantalum bonding state has a high reducing ability (i.e., oxidation easily occurs in the first tantalum bonding state); thus, the use of a tantalum compound having a high percentage of the first tantalum bonding state for each of the conductive layers 242a and 242b might lead to formation of oxygen vacancies in the oxide semiconductor layer 230, resulting in normally-on of the transistor. The formation of the conductive layers 242a and 242b using a tantalum compound having a high percentage of the first tantalum bonding state might cause significant damage to the oxide semiconductor layer 230, which is a formation surface of the conductive layers 242a and 242b, decreasing the reliability of the transistor. Accordingly, the percentage of the first tantalum bonding state in each of the conductive layers 242a and 242b is preferably low.

In view of the above, in each of the conductive layers 242a and 242b, the percentage of the first tantalum bonding state is preferably lower than or equal to 10%, further preferably lower than or equal to 5%, still further preferably lower than or equal to 3%. In addition, in each of the conductive layers 242a and 242b, the percentage of the second tantalum bonding state is preferably higher than or equal to 5%, further preferably higher than or equal to 10%.

The conductive layers 242a and 242b preferably have a δ-TaN phase. For example, the conductive layers 242a and 242b preferably have a δ-TaN phase with a crystal orientation of <111> and a δ-TaN phase with a crystal orientation of <200>. The δ-TaN phase can inhibit a decrease in conductivity of a tantalum compound. Note that the crystal orientation in this specification and the like refers to a crystal orientation of crystal phases with respect to a formation surface.

The δ-TaN phase with a crystal orientation of <111> and the δ-TaN phase with a crystal orientation of <200> can be confirmed by, for example, analysis using XRD (referred to as XRD analysis). In XRD analysis, a peak derived from the δ-TaN phase with a crystal orientation of <111> has a peak position in the range of 2θ=35.5±1.0 deg. (in the range of 2θ from 34.5 deg. to 36.5 deg.). In addition, a peak derived from the δ-TaN phase with a crystal orientation of <200> has a peak position in the range of 2θ=41.2±2.0 deg. (in the range of 2θ from 39.2 deg. to 43.2 deg.). In this specification and the like, the peak having a peak position in the range of 2θ=35.5±1.0 deg. (in the range of 2θ from 34.5 deg. to 36.5 deg.) in an XRD spectrum is sometimes referred to as a first peak. Moreover, the peak having a peak position in the range of 2θ=41.2±2.0 deg. (in the range of 2θ from 39.2 deg. to 43.2 deg.) is sometimes referred to as a second peak.

In this specification and the like, a peak in XRD analysis refers to a convex shape appearing in an XRD spectrum. Note that one peak is sometimes formed by an overlap of a plurality of peaks. A peak level in XRD analysis refers to a local maximum value of a convex shape (peak) appearing in an XRD spectrum. A peak position in XRD analysis refers to the value of 2θ at a local maximum value of a convex shape (peak) appearing in an XRD spectrum.

For example, a diffraction peak from the (111) plane in the δ-TaN phase and a diffraction peak from the (200) plane in the δ-TaN phase are preferably observed in XRD analysis. In addition, each of the conductive layers 242a and 242b preferably has the first peak and the second peak in an XRD spectrum.

In each of the conductive layers 242a and 242b, the content of the δ-TaN phase with a crystal orientation of <111> is preferably higher than or equal to that of the δ-TaN phase with a crystal orientation of <200>. Alternatively, the ratio of the content of the δ-TaN phase with a crystal orientation of <200> to the content of the δ-TaN phase with a crystal orientation of <111> is preferably 1 or an approximate value of 1. With such a structure, the crystal grain boundary in a tantalum compound can be reduced to improve the reliability of the transistor.

Note that the content relationship between the δ-TaN phase with a crystal orientation of <111> and the δ-TaN phase with a crystal orientation of <200> can be evaluated by, for example, XRD analysis. For example, each of the conductive layers 242a and 242b preferably has the first peak and the second peak in an XRD spectrum. The peak level of the first peak is preferably higher than or equal to that of the second peak. For example, the ratio of the peak level of the second peak to the peak level of the first peak is preferably higher than or equal to 0.1 and lower than or equal to 1.0, further preferably higher than or equal to 0.2 and lower than or equal to 1.0. For another example, the ratio of the peak level of the second peak to the peak level of the first peak is preferably 1 or an approximate value of 1. In this specification and the like, an approximate value of a given value A refers to a value greater than or equal to 0.8×A and less than or equal to 1.2×A.

Note that the atomic ratio of nitrogen to tantalum is denoted as an N/Ta ratio. For example, the N/Ta ratio of each of the conductive layers 242a and 242b is preferably higher than or equal to 1.0 and lower than or equal to 2.0, further preferably higher than or equal to 1.1 and lower than or equal to 1.8, still further preferably higher than or equal to 1.2 and lower than or equal to 1.5. Increasing the N/Ta ratio can inhibit the oxidation of a tantalum compound, improve the oxidation resistance of a tantalum compound, and inhibit oxygen diffusion into a tantalum compound. Thus, formation of an oxide layer between the oxide semiconductor layer 230 and the conductive layers 242a and 242b can be prevented, or the thickness of the oxide layer can be reduced.

Note that the percentage of the first tantalum bonding state, the percentage of the second tantalum bonding state, the content of the δ-TaN phase with a crystal orientation of <111>, the content of the δ-TaN phase with a crystal orientation of <200>, the N/Ta ratio, and the like of each of the conductive layers 242a and 242b can be set as appropriate in accordance with the characteristics required for the transistor 200.

Note that hydrogen contained in the oxide semiconductor layer 230 or the like diffuses into the conductive layer 242a or the conductive layer 242b in some cases. In particular, when a nitride containing tantalum is used for the conductive layers 242a and 242b, hydrogen contained in the oxide semiconductor layer 230 or the like is likely to diffuse into the conductive layer 242a or the conductive layer 242b, and the diffused hydrogen is bonded to nitrogen contained in the conductive layer 242a or the conductive layer 242b in some cases. That is, hydrogen contained in the oxide semiconductor layer 230 or the like is sometimes absorbed by the conductive layer 242a or the conductive layer 242b.

In the case where heat treatment is performed with the conductive layer 242a and the oxide semiconductor layer 230 being in contact with each other, the sheet resistance of the oxide semiconductor layer 230 in a region overlapping with the conductive layer 242a is lowered and the carrier concentration thereof increases in some cases. Thus, the resistance of the oxide semiconductor layer 230 in the region overlapping with the conductive layer 242a can be lowered in a self-aligned manner. The same applies to the oxide semiconductor layer 230 in a region overlapping with the conductive layer 242b.

The conductive layer 242 is preferably formed using a conductive film having compressive stress. This can form distortion extended in the tensile direction (hereinafter, such distortion is sometimes referred to as tensile distortion) in the regions 230na and 230nb. When V_{O}H is stably formed by the tensile distortion, the regions 230na and 230nb can be stable n-type regions. The compressive stress of the conductive layer 242 refers to stress for relaxing the compressive shape of the conductive layer 242 that has a vector in a direction from a center portion to an end portion of the conductive layer 242.

The level of the compressive stress of the conductive layer 242 can be, for example, higher than or equal to 500 MPa, preferably higher than or equal to 1000 MPa, further preferably higher than or equal to 1500 MPa, still further preferably higher than or equal to 2000 MPa. The level of the stress of the conductive layer 242 may be determined from the measured stress of a sample formed by depositing a conductive film to be used for the conductive layer 242 on a substrate.

The conductive layers 242a and 242b may each have a single-layer structure or a stacked-layer structure. For example, as illustrated in FIG. 2B, the conductive layers 242a and 242b may each have a two-layer structure. In that case, the conductive layer 242a is a stack of a conductive layer 242a1 and a conductive layer 242a2 over the conductive layer 242a1, and the conductive layer 242b is a stack of a conductive layer 242b1 and a conductive layer 242b2 over the conductive layer 242b1. At this time, the conductive material that is not easily oxidized or the conductive material having a function of inhibiting oxygen diffusion described above is preferably used for layers (the conductive layers 242a1 and 242b1) in contact with the oxide semiconductor layer 230. This can inhibit excessive oxidation of the conductive layers 242a and 242b by oxygen contained in the oxide semiconductor layer 230. In addition, a decrease in the conductivity of the conductive layers 242a and 242b can be inhibited.

Hereinafter, the conductive layers 242a1 and 242b1 are collectively referred to as a conductive layer 242_1 in some cases. The conductive layers 242a2 and 242b2 are collectively referred to as a conductive layer 242_2 in some cases.

The conductivity of the conductive layer 242_2 is preferably higher than that of the conductive layer 242_1. In that case, at least part of the conductive layer 242_2 includes a region having higher conductivity than the conductive layer 242_1. For example, the thickness of the conductive layer 242_2 is preferably greater than that of the conductive layer 242_1. This can increase the operation speed of the transistor 200. Furthermore, a semiconductor device with reduced wiring delay can be fabricated.

Here, for the conductive layers 242_1 and 242_2, conductive materials that have the same constituent element and have different chemical compositions are preferably used. In that case, a conductive film to be the conductive layer 242_1 and a conductive film to be the conductive layer 242_2 can be successively deposited without exposure to the air. By the deposition without exposure to the air, impurities or moisture from the atmospheric environment can be prevented from being attached onto the surface of the conductive layer 242_1, so that the vicinity of the interface between the conductive layer 242_1 and the conductive layer 242_2 can be kept clean.

In the case where each of the conductive layers 242_1 and 242_2 contains a tantalum compound, the above-described tantalum compound can be used for the conductive layer 242_1 in contact with the oxide semiconductor layer 230.

For example, the percentage of the first tantalum bonding state in the conductive layer 242_2 is preferably higher than that in the conductive layer 242_1. Such a structure can increase the conductivity of the conductive layer 242_2. For another example, it is preferable that the conductive layer 242_2 have the first peak and the second peak in an XRD spectrum and that the peak level of the first peak be lower than that of the second peak. Such a structure can increase the conductivity of the conductive layer 242_2.

For another example, the N/Ta ratio in the conductive layer 242_2 is preferably lower than that in the conductive layer 242_1. For example, the N/Ta ratio in the conductive layer 242_2 is preferably higher than or equal to 0.3 and lower than 1.0, further preferably higher than or equal to 0.5 and lower than 1.0, still further preferably higher than or equal to 0.6 and lower than 1.0. Decreasing the N/Ta ratio can lower the resistivity of a tantalum compound. Thus, a semiconductor device with reduced wiring delay can be fabricated.

Note that the percentage of the first tantalum bonding state, the content of the δ-TaN phase with a crystal orientation of <111>, the content of the δ-TaN phase with a crystal orientation of <200>, the N/Ta ratio, and the like of the conductive layer 242_2 can be set as appropriate in accordance with the characteristics required for the transistor 200.

Note that it is sometimes difficult to clearly detect the boundary between the conductive layers 242_1 and 242_2. In the case where a tantalum compound is used for the conductive layer 242, the tantalum concentration and the nitrogen concentration detected in the layer may gradually change within the layer and may also change continuously (or in a gradation manner) in a region between the conductive layers 242_1 and 242_2. That is, the N/Ta ratio is higher in a region of the conductive layer 242 closer to the oxide semiconductor layer 230. Thus, the N/Ta ratio in the lower region of the conductive layer 242 is preferably higher than that in the upper region of the conductive layer 242.

The thickness of the conductive layer 242_1 is greater than or equal to 0.1 nm and less than or equal to 5.0 nm, preferably greater than or equal to 0.5 nm and less than or equal to 3.0 nm, further preferably greater than or equal to 1.0 nm and less than or equal to 3.0 nm. In that case, at least part of the conductive layer 242_1 includes a region having the above-described thickness. The thickness of the conductive layer 242_2 is preferably greater than that of the conductive layer 242_1. In that case, at least part of the conductive layer 242_2 includes a region having a thickness greater than that of the conductive layer 242_1.

In the example described above, conductive materials that have the same constituent element and have different chemical compositions are used for the conductive layers 242_1 and 242_2; however, one embodiment of the present invention is not limited thereto, and the conductive layers 242_1 and 242_2 may be formed using different conductive materials.

### <Materials for Semiconductor Device>

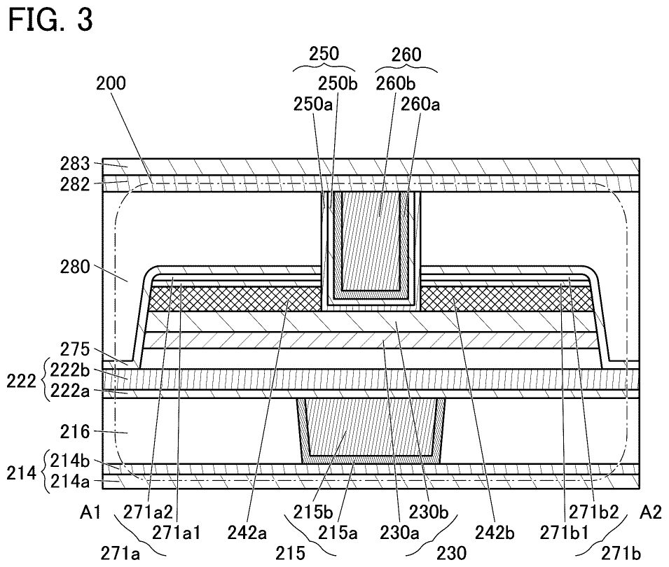

Materials that can be used for the semiconductor device of this embodiment will be described below. Note that the layers included in the semiconductor device of this embodiment may each have a single-layer structure or a stacked-layer structure. FIGS. 1B to 1D illustrate an example in which the insulating layer 214, the conductive layer 215, the insulating layer 222, the oxide semiconductor layer 230, the conductive layer 242a, the conductive layer 242b, the insulating layer 271a, the insulating layer 271b, the insulating layer 250, and the conductive layer 260 each have a single-layer structure. FIG. 3 illustrates an example in which the insulating layer 214, the conductive layer 215, the insulating layer 222, the oxide semiconductor layer 230, the conductive layer 242a, the conductive layer 242b, the insulating layer 271a, the insulating layer 271b, the insulating layer 250, and the conductive layer 260 each have a stacked-layer structure.

### [Oxide Semiconductor Layer 230]

As described above, the oxide semiconductor layer 230 includes a channel formation region. The channel formation region is an i-type (intrinsic) or substantially i-type region. The oxide semiconductor layer 230 further includes a source region and a drain region. The source region and the drain region are n-type regions (low-resistance regions) having a higher carrier concentration than the channel formation region.

There is no particular limitation on the crystallinity of the semiconductor material used for the oxide semiconductor layer 230, and any of an amorphous semiconductor, a single crystal semiconductor, and a semiconductor having other crystallinity than single crystal (a microcrystalline semiconductor, a polycrystalline semiconductor, or a semiconductor partly including crystal regions) may be used. A single crystal semiconductor or a semiconductor having crystallinity is preferably used, in which case deterioration of the transistor characteristics can be inhibited.

The band gap of a metal oxide functioning as a semiconductor is preferably greater than or equal to 2.0 eV, further preferably greater than or equal to 2.5 eV. The use of a metal oxide having a wide band gap can reduce the off-state current of the transistor. The off-state current of the OS transistor is low; thus, power consumption of the semiconductor device can be sufficiently reduced. The OS transistor has high frequency characteristics, which enables the semiconductor device to operate at high speed.

Examples of the metal oxide that can be used for the oxide semiconductor layer 230 include indium oxide, gallium oxide, and zinc oxide. The metal oxide preferably contains at least indium (In) or zinc (Zn). The metal oxide preferably contains two or three selected from indium, an element M, and zinc. Furthermore, the metal oxide preferably contains one or both of indium and zinc. The element M is a metal element or metalloid element that has a high bonding energy with oxygen, such as a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more of the above elements, further preferably one or more selected from aluminum, gallium, tin, and yttrium, and still further preferably gallium. In this specification and the like, a metal element and a metalloid element may be collectively referred to as a “metal element”, and a “metal element” in this specification and the like may refer to a metalloid element.

For example, the oxide semiconductor layer 230 can be formed using indium oxide (In oxide), indium zinc oxide (also referred to as In—Zn oxide or IZO (registered trademark)), indium tin oxide (In—Sn oxide), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (also referred to as Ga—Zn oxide or GZO), aluminum zinc oxide (also referred to as Al—Zn oxide or AZO), indium aluminum zinc oxide (also referred to as In—Al—Zn oxide or IAZO), indium tin zinc oxide (also referred to as In—Sn—Zn oxide or ITZO (registered trademark)), indium titanium zinc oxide (In—Ti—Zn oxide), indium gallium zinc oxide (also referred to as In—Ga—Zn oxide or IGZO), indium gallium tin zinc oxide (also referred to as In—Ga—Sn—Zn oxide or IGZTO), or indium gallium aluminum zinc oxide (also referred to as In—Ga—Al—Zn oxide, IGAZO, IGZAO, or IAGZO). Alternatively, indium tin oxide containing silicon, gallium tin oxide (Ga—Sn oxide), aluminum tin oxide (Al—Sn oxide), or the like can be used.

By increasing the proportion of the number of indium atoms in the total number of atoms of all the metal elements contained in the metal oxide, the field-effect mobility of the transistor can be increased. In addition, the transistor can have a high on-state current.

Instead of indium or in addition to indium, the metal oxide may contain one or more kinds of metal elements whose period number in the periodic table is large. The larger the overlap between orbits of metal elements is, the more likely it is that the metal oxide will have high carrier conductivity. Thus, when a metal element with a large period number in the periodic table is contained in the metal oxide, the field-effect mobility of the transistor can be increased in some cases. Examples of the metal element with a large period number in the periodic table include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds selected from nonmetallic elements. By containing a non-metallic element, the metal oxide sometimes has an increased carrier concentration, a reduced band gap, or the like, in which case the transistor can have increased field-effect mobility. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, changes in the electrical characteristics of the transistor can be reduced to improve the reliability of the transistor.

By increasing the proportion of the number of element M atoms in the total number of atoms of all the metal elements contained in the metal oxide, the metal oxide can have a wide band gap. In addition, formation of oxygen vacancies in the metal oxide can be inhibited. Thus, generation of carriers due to oxygen vacancies is inhibited, which makes the off-state current of the transistor low. Moreover, the threshold voltage shift of the transistor can be inhibited. Furthermore, changes in the electrical characteristics of the transistor can be reduced to improve the reliability of the transistor.

The composition of the metal oxide used for the oxide semiconductor layer 230 affects the electrical characteristics and reliability of the transistor. Therefore, by determining the composition of the metal oxide in accordance with the electrical characteristics and reliability required for the transistor, the semiconductor device can have both excellent electrical characteristics and high reliability.

When the metal oxide is an In-M-Zn oxide, the proportion of the number of In atoms is preferably higher than or equal to that of the number of M atoms in the In-M-Zn oxide. Examples of the atomic ratio of the metal elements of such an In-M-Zn oxide include In:M:Zn=1:1:0.5, In:M:Zn=1:1:1, In:M:Zn=1:1:1.2, In:M:Zn=1:1:2, In:M:Zn=2:1:3, In:M:Zn=3:1:1, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the neighborhood of any of the above atomic ratios. Note that a composition in the neighborhood of an atomic ratio includes ±30% of an intended atomic ratio. By increasing the proportion of the number of indium atoms in the metal oxide, the on-state current, field-effect mobility, or the like of the transistor can be improved.

The proportion of the number of In atoms may be less than that of the number of M atoms in the In-M-Zn oxide. Examples of the atomic ratio of the metal elements of such an In-M-Zn oxide include In:M:Zn=1:3:2, In:M:Zn=1:3:3, and In:M:Zn=1:3:4 and a composition in the neighborhood of any of these atomic ratios. By increasing the proportion of the number of M atoms in the metal oxide, generation of oxygen vacancies can be inhibited.

In the case where a plurality of metal elements are contained as the element M, the sum of the proportions of the numbers of atoms of these metal elements can be used as the proportion of the number of element M atoms.

In this specification and the like, the proportion of the number of indium atoms in the total number of atoms of all the metal elements contained is sometimes referred to as indium content percentage. The same applies to other metal elements.

In the case where the metal oxide is an In—Zn oxide, examples of the atomic ratio of metal elements in the In—Zn oxide include In:Zn=1:1, In:Zn=2:1, In:Zn=4:1, and compositions in the neighborhood thereof. The In—Zn oxide may contain a slight amount of element M. For example, in the case where Sn is contained as the element M, examples of the atomic ratio of the metal elements in the metal oxide include In:Sn:Zn=2:0.1:1, In:Sn:Zn=4:0.1:1, and compositions in the neighborhood thereof.

Analysis of the composition of the metal oxide used for the oxide semiconductor layer 230 can be performed by energy dispersive X-ray spectrometry (EDX), XPS, inductively coupled plasma-mass spectrometry (ICP-MS), or inductively coupled plasma-atomic emission spectrometry (ICP-AES). Alternatively, these methods may be combined to be employed for analysis. As for an element whose content is low, the actual content may be different from the content obtained by analysis because of the influence of the analysis accuracy. In the case where the content of the element M is low, for example, the content of the element M obtained by analysis may be lower than the actual content.

A sputtering method or an atomic layer deposition (ALD) method can be suitably used for forming the metal oxide. In the case where the metal oxide is formed by a sputtering method, the composition of the formed metal oxide may be different from the composition of a target. In particular, the zinc content of the formed metal oxide may be reduced to approximately 50% of that of the target. The metal oxide may be formed by a chemical vapor deposition (CVD) method, a molecular beam epitaxy (MBE) method, a pulsed laser deposition (PLD) method, or the like.

The oxide semiconductor layer 230 may have a stacked-layer structure including two or more metal oxide layers. The two or more metal oxide layers included in the oxide semiconductor layer 230 may have the same composition or substantially the same compositions. Employing a stacked-layer structure of metal oxide layers having the same composition can reduce the manufacturing cost because the metal oxide layers can be formed using the same sputtering target.

The two or more metal oxide layers included in the oxide semiconductor layer 230 may have different compositions.

FIG. 3 illustrates an example in which the oxide semiconductor layer 230 has a two-layer structure of an oxide semiconductor layer 230a and an oxide semiconductor layer 230b over the oxide semiconductor layer 230a.

The oxide semiconductor layer 230b is preferably formed using a material having higher conductivity than a material for the oxide semiconductor layer 230a, for example. The use of the material having high conductivity for the oxide semiconductor layer 230b that is in contact with the source and drain electrodes (the conductive layers 242a and 242b) can reduce the contact resistance between the oxide semiconductor layer 230 and each of the conductive layers 242a and 242b, so that the transistor can have a high on-state current.

The oxide semiconductor layer 230b preferably has a higher carrier concentration than the oxide semiconductor layer 230a. Increasing the carrier concentration of the oxide semiconductor layer 230b results in higher conductivity thereof, which can reduce the contact resistance between the oxide semiconductor layer 230 and each of the conductive layers 242a and 242b, so that the transistor can have a high on-state current.

Note that the structure of the oxide semiconductor layer 230 is not limited to the above structure, and the oxide semiconductor layer 230b may be formed using a material having lower conductivity than the material for the oxide semiconductor layer 230a. In addition, the oxide semiconductor layer 230b may have a lower carrier concentration than the oxide semiconductor layer 230a.

A first metal oxide used for the oxide semiconductor layer 230a and a second metal oxide used for the oxide semiconductor layer 230b preferably have different band gaps. For example, a band gap difference between the first metal oxide and the second metal oxide is preferably greater than or equal to 0.1 eV, further preferably greater than or equal to 0.2 eV, still further preferably greater than or equal to 0.3 eV.

The band gap of the second metal oxide used for the oxide semiconductor layer 230b is preferably narrower than that of the first metal oxide used for the oxide semiconductor layer 230a. Thus, the contact resistance between the oxide semiconductor layer 230 and each of the conductive layers 242a and 242b can be reduced, so that the transistor can have a high on-state current.

For example, the element M content in the second metal oxide is preferably lower than that in the first metal oxide. Specifically, for example, it is preferable to use a metal oxide having an atomic ratio of In:M:Zn=1:3:2 or a composition in the neighborhood thereof for the oxide semiconductor layer 230a and a metal oxide having an atomic ratio of In:M:Zn=1:1:1 or a composition in the neighborhood thereof for the oxide semiconductor layer 230b. In that case, it is particularly preferable to use one or more of gallium, aluminum, and tin as the element M.

Note that the structure of the oxide semiconductor layer 230 is not limited to the above structure, and the band gap of the second metal oxide may be wider than that of the first metal oxide.

The element M content in the second metal oxide is preferably lower than that in the first metal oxide. For example, the gallium content in the second metal oxide is preferably lower than that in the first metal oxide. The second metal oxide may contain a slight amount of element M or no element M. For example, the second metal oxide may contain a slight amount of tin. For example, it is preferable that the second metal oxide used for the oxide semiconductor layer 230b be an In—Zn oxide and that the first metal oxide used for the oxide semiconductor layer 230a be an In-M-Zn oxide. Specifically, the second metal oxide can be an In—Zn oxide, and the first metal oxide can be an In—Ga—Zn oxide.

For example, it is preferable to use, for the oxide semiconductor layer 230b, a metal oxide having an atomic ratio of In:Zn=1:1 or a composition in the neighborhood thereof, a metal oxide having an atomic ratio of In:Zn=2:1 or a composition in the neighborhood thereof, a metal oxide having an atomic ratio of In:Sn:Zn=2:0.1:1 or a composition in the neighborhood thereof, a metal oxide having an atomic ratio of In:Zn=4:1 or a composition in the neighborhood thereof, a metal oxide having an atomic ratio of In:Sn:Zn=4:0.1:1 or a composition in the neighborhood thereof, or an indium oxide. It is preferable to use, for the oxide semiconductor layer 230a, a metal oxide having an atomic ratio of In:Ga:Zn=1:1:1 or a composition in the neighborhood thereof, a metal oxide having an atomic ratio of In:Ga:Zn=1:3:2 or a composition in the neighborhood thereof, or a metal oxide having an atomic ratio of In:Ga:Zn=1:3:4 or a composition in the neighborhood thereof. With this structure, the on-state current of the transistor 200 can be increased, and the transistor can have high reliability with small variations.

Note that the structure of the oxide semiconductor layer 230 is not limited to the above structure, and the element M content in the second metal oxide may be higher than that in the first metal oxide.

It is preferable that the oxide semiconductor layer 230 contain a metal oxide layer having crystallinity. Examples of the structure of a metal oxide having crystallinity include a c-axis aligned crystalline (CAAC) structure, a polycrystalline structure, and a nano-crystal (nc) structure. By using a metal oxide layer having crystallinity as the oxide semiconductor layer 230, the density of defect states in the oxide semiconductor layer 230 can be reduced, which enables the semiconductor device to have high reliability.

In a CAAC-OS, a reduction in electron mobility due to a crystal grain boundary is unlikely to occur because it is difficult to observe a clear crystal grain boundary. Thus, a metal oxide including the CAAC-OS is physically stable. Accordingly, the metal oxide including the CAAC-OS is resistant to heat and has high reliability. Note that the CAAC-OS is an oxide semiconductor having the CAAC structure.

There is no regularity of crystal orientation between different nanocrystals in an nc-OS; thus, the orientation of the whole film is not observed. That is, in the case where the nc-OS is used for the oxide semiconductor layer 230, the oxide semiconductor layer 230 has uniform film characteristics regardless of the direction of carriers flowing in the oxide semiconductor layer 230; thus, the transistor has stable electrical characteristics. Note that the nc-OS is an oxide semiconductor having the nc structure.

Note that an oxide semiconductor has any of various structures that show different properties. The oxide semiconductor layer 230b may include two or more of the CAAC-OS, the nc-OS, an amorphous-like oxide semiconductor (a-like OS), an amorphous oxide semiconductor, a polycrystalline oxide semiconductor, and a cloud-aligned composite oxide semiconductor (CAC-OS).

The higher the crystallinity of the metal oxide layer used as the oxide semiconductor layer 230 is, the lower the density of defect states in the oxide semiconductor layer 230 can be. By contrast, with the use of a metal oxide layer having low crystallinity, a high current can flow through the transistor.

In the case where the metal oxide layer is formed by a sputtering method, the higher the substrate temperature (the stage temperature) in the formation is, the higher the crystallinity of the metal oxide layer can be. Furthermore, the higher the proportion of the flow rate of an oxygen gas to the total flow rate of the film formation gas (hereinafter, also referred to as an oxygen flow rate ratio) used in the formation is, the higher the crystallinity of the metal oxide layer can be.

The crystallinity of the oxide semiconductor layer 230 can be analyzed with XRD, a transmission electron microscope (TEM), or electron diffraction (ED), for example. Alternatively, these methods may be combined to be employed for analysis.

The oxide semiconductor layer 230 may have a stacked-layer structure of two or more metal oxide layers having different crystallinities. For example, a stacked-layer structure of a first metal oxide layer and a second metal oxide layer over the first metal oxide layer can be employed; the second metal oxide layer can include a region having higher crystallinity than the first metal oxide layer. Alternatively, the second metal oxide layer can include a region having lower crystallinity than the first metal oxide layer. In that case, the composition of the first metal oxide layer may be different from, the same as, or substantially the same as that of the second metal oxide layer.

For example, it is preferable that the oxide semiconductor layer 230a be formed using a metal oxide having an atomic ratio of In:M:Zn=1:3:2 or a composition in the neighborhood thereof or a metal oxide having an atomic ratio of In:M:Zn=1:3:4 or a composition in the neighborhood thereof, and that the oxide semiconductor layer 230b be formed using a metal oxide having an atomic ratio of In:M:Zn=1:1:1 or a composition in the neighborhood thereof. The use of a metal oxide in which the ratio of Zn to In is high for the oxide semiconductor layer 230a can increase the crystallinity of the oxide semiconductor layer 230a. Furthermore, forming the oxide semiconductor layer 230b over the oxide semiconductor layer 230a with high crystallinity facilitates increasing the crystallinity of the oxide semiconductor layer 230b. This is preferable because the crystallinity of the whole oxide semiconductor layer 230 can be increased. In that case, it is particularly preferable to use gallium, aluminum, or tin as the element M. For example, two IGZO layers having different compositions may be stacked. For another example, a stacked-layer structure of one selected from indium oxide, indium gallium oxide, and IGZO, and one selected from IAZO, IAGZO, and ITZO (registered trademark) may be employed.

The thickness of the oxide semiconductor layer 230 is preferably greater than or equal to 5 nm and less than or equal to 100 nm, further preferably greater than or equal to 5 nm and less than or equal to 50 nm, still further preferably greater than or equal to 10 nm and less than or equal to 50 nm.

In the case where the oxide semiconductor layer 230 has a two-layer structure of the oxide semiconductor layer 230a and the oxide semiconductor layer 230b over the oxide semiconductor layer 230a, the sum of the thicknesses of the oxide semiconductor layers 230a and 230b preferably falls within any of the above ranges. The thickness of the oxide semiconductor layer 230b is preferably greater than that of the oxide semiconductor layer 230a.

Hydrogen contained in an oxide semiconductor reacts with oxygen bonded to a metal atom to be water, and thus sometimes forms an oxygen vacancy (V_{O}) in the oxide semiconductor. Furthermore, V_{O}H functions as a donor and generates an electron serving as a carrier in some cases. In other cases, bonding of part of hydrogen to oxygen bonded to a metal atom generates an electron serving as a carrier. Thus, a transistor containing an oxide semiconductor that contains a large amount of hydrogen tends to be normally on. Moreover, hydrogen in an oxide semiconductor is easily transferred by a stress such as heat or an electric field; thus, a large amount of hydrogen in an oxide semiconductor might reduce the reliability of a transistor.

The amount of V_{O}H in the oxide semiconductor layer 230 is preferably reduced as much as possible so that the oxide semiconductor layer 230 becomes a highly purified intrinsic or substantially highly purified intrinsic oxide semiconductor layer. In sufficiently reducing the amount of V_{O}H in an oxide semiconductor, it is important to remove impurities such as water and hydrogen in the oxide semiconductor (which is sometimes described as dehydration or dehydrogenation treatment) and to repair oxygen vacancies by supplying oxygen to the oxide semiconductor. When an oxide semiconductor with a sufficiently reduced amount of impurities such as V_{O}H is used for the channel formation region of the transistor, the transistor can have stable electrical characteristics. Note that repairing oxygen vacancies by supplying oxygen to an oxide semiconductor is sometimes referred to as oxygen adding treatment.

The carrier concentration of the oxide semiconductor in the region functioning as the channel formation region is preferably lower than or equal to 1×10¹⁸ cm⁻³, further preferably lower than 1×10¹⁷ cm⁻³, still further preferably lower than 1×10¹⁶ cm⁻³, yet further preferably lower than 1×10¹³ cm⁻³, yet still further preferably lower than 1×10¹² cm⁻³. The minimum carrier concentration of the oxide semiconductor in the region functioning as the channel formation region is not particularly limited and can be 1×10⁻⁹ cm⁻³, for example.

The influence of impurities in the metal oxide (oxide semiconductor) will be described here.

When an oxide semiconductor contains silicon or carbon, which is a Group 14 element, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

Furthermore, when the oxide semiconductor contains nitrogen, the oxide semiconductor easily becomes n-type by generation of electrons serving as carriers and an increase in carrier concentration. As a result, a transistor containing, as a semiconductor, an oxide semiconductor that contains nitrogen tends to be normally on. When nitrogen is contained in the oxide semiconductor, a trap state is sometimes formed. This might make the electrical characteristics of the transistor unstable. Thus, the nitrogen concentration in the channel formation region of the oxide semiconductor, which is measured by SIMS, is lower than or equal to 1×10²¹ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus forms an oxygen vacancy in some cases. Entry of hydrogen into the oxygen vacancy generates an electron serving as a carrier in some cases. In other cases, bonding of part of hydrogen to oxygen bonded to a metal atom generates an electron serving as a carrier. Thus, a transistor containing an oxide semiconductor that contains hydrogen tends to be normally on. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet still further preferably lower than 1×10¹⁸ atoms/cm³.

When the oxide semiconductor contains an alkali metal or an alkaline earth metal, defect states are formed and carriers are generated in some cases. Thus, a transistor containing an oxide semiconductor that contains an alkali metal or an alkaline earth metal tends to be normally on. Accordingly, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for a channel formation region in a transistor, the transistor can have stable electrical characteristics.

### [Insulating Layer]

An inorganic insulating film is preferably used as each of the insulating layers included in the semiconductor device (e.g., the insulating layers 214, 216, 222, 224, 250, 271, 275, 280, 282, and 283). Examples of the inorganic insulating film include an oxide insulating film, a nitride insulating film, an oxynitride insulating film, and a nitride oxide insulating film. Examples of the oxide insulating film include a silicon oxide film, an aluminum oxide film, a magnesium oxide film, a gallium oxide film, a germanium oxide film, an yttrium oxide film, a zirconium oxide film, a lanthanum oxide film, a neodymium oxide film, a hafnium oxide film, a tantalum oxide film, a cerium oxide film, a gallium zinc oxide film, and a hafnium aluminate film. Examples of the nitride insulating film include a silicon nitride film and an aluminum nitride film. Examples of the oxynitride insulating film include a silicon oxynitride film, an aluminum oxynitride film, a gallium oxynitride film, an yttrium oxynitride film, and a hafnium oxynitride film. Examples of the nitride oxide insulating film include a silicon nitride oxide film and an aluminum nitride oxide film. An organic insulating film may be used as each of the insulating layers included in the semiconductor device.

With scaling down and higher integration of transistors, for example, a problem such as generation of leakage current may arise because of a thinner gate insulating layer. When a high-dielectric-constant (high-k) material is used for the gate insulating layer, the voltage at the time of operation of the transistor can be reduced while the physical thickness is maintained. Furthermore, the equivalent oxide thickness (EOT) of the gate insulating layer can be reduced. By contrast, when a low-dielectric-constant material is used for an insulating layer functioning as an interlayer film, parasitic capacitance generated between wirings can be reduced. Thus, a material can be selected depending on the function of an insulating layer. Note that a low-dielectric-constant material is a material with high dielectric strength.

Examples of a high-k material include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of a low-dielectric-constant material include inorganic insulating materials such as silicon oxide, silicon oxynitride, and silicon nitride oxide, and resins such as polyester, polyolefin, polyamide (e.g., nylon and aramid), polyimide, polycarbonate, and an acrylic resin. Other examples of a low-dielectric-constant inorganic insulating material include silicon oxide to which fluorine is added, silicon oxide to which carbon is added, and silicon oxide to which carbon and nitrogen are added. Another example is porous silicon oxide. Note that these silicon oxides can contain nitrogen.

A material that can show ferroelectricity may be used for each of the insulating layers included in the semiconductor device. Examples of the material that can show ferroelectricity include metal oxides such as hafnium oxide, zirconium oxide, and hafnium zirconium oxide. Examples of the material that can show ferroelectricity also include a material in which an element J1 (the element J1 here is one or more of zirconium, silicon, aluminum, gadolinium, yttrium, lanthanum, strontium, and the like) is added to hafnium oxide. Here, the atomic ratio of hafnium to the element J1 can be set as appropriate; the atomic ratio of hafnium to the element J1 can be, for example, 1:1 or the neighborhood thereof. Examples of the material that can show ferroelectricity also include a material in which an element J2 (the element J2 here is one or more of hafnium, silicon, aluminum, gadolinium, yttrium, lanthanum, strontium, and the like) is added to zirconium oxide. The atomic ratio of zirconium to the element J2 can be set as appropriate; the atomic ratio of zirconium to the element J2 can be, for example, 1:1 or the neighborhood thereof. As the material that can show ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can show ferroelectricity also include a metal nitride containing an element M1, an element M2, and nitrogen. Here, the element M1 is one or more of aluminum, gallium, indium, and the like. The element M2 is one or more of boron, scandium, yttrium, lanthanum, cerium, neodymium, europium, titanium, zirconium, hafnium, vanadium, niobium, tantalum, chromium, and the like. Note that the atomic ratio of the element M1 to the element M2 can be set as appropriate. A metal oxide containing the element M1 and nitrogen shows ferroelectricity in some cases even though the metal oxide does not contain the element M2. Examples of the material that can show ferroelectricity also include the above metal nitride to which an element M3 is added. Note that the element M3 is one or more of magnesium, calcium, strontium, zinc, cadmium, and the like. Here, the atomic ratio between the element M1, the element M2, and the element M3 can be set as appropriate.

Examples of the material that can show ferroelectricity also include perovskite-type oxynitrides such as SrTaO₂N and BaTaO₂N, and GaFeO₃ with a κ-alumina-type structure.

Although metal oxides and metal nitrides are described above as examples, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can show ferroelectricity, a mixture or compound containing a plurality of materials selected from the above-listed materials can be used, for example. Alternatively, the insulating layers can each have a stacked-layer structure of a plurality of materials selected from the above-listed materials. Since the above-listed materials and the like may change their crystal structures (characteristics) according to a variety of processes and the like as well as deposition conditions, a material that exhibits ferroelectricity is referred to not only as a ferroelectric but also as a material that can show ferroelectricity in this specification and the like.

A metal oxide containing one or both of hafnium and zirconium can show ferroelectricity even when being processed into a thin film of several nanometers. In addition, a metal oxide containing one or both of hafnium and zirconium can show ferroelectricity even with a minute area. Thus, the use of a metal oxide containing one or both of hafnium and zirconium can scale down the semiconductor device.

Note that in this specification and the like, the material that can show ferroelectricity processed into a layered shape is referred to as a ferroelectric layer, a metal oxide film, or a metal nitride film in some cases. Furthermore, a device including such a ferroelectric layer, metal oxide film, or metal nitride film is sometimes referred to as a ferroelectric device in this specification and the like.

Note that ferroelectricity is exhibited by displacement of oxygen or nitrogen of a crystal included in a ferroelectric layer due to an external electric field. Ferroelectricity is presumably exhibited depending on a crystal structure of a crystal included in a ferroelectric layer. Thus, in order that an insulating layer can exhibit ferroelectricity, the insulating layer needs to include a crystal. It is particularly preferable that the insulating layer include a crystal having an orthorhombic crystal structure to exhibit ferroelectricity. A crystal included in the insulating layer may have one or more of crystal structures selected from tetragonal, orthorhombic, monoclinic, and hexagonal crystal structures. Alternatively, the insulating layer may have an amorphous structure. In that case, the insulating layer may have a composite structure including an amorphous structure and a crystal structure.

A transistor containing a metal oxide can have stable electrical characteristics when surrounded by an insulating layer having a function of inhibiting transmission of oxygen and impurities. The insulating layer having a function of inhibiting transmission of oxygen and impurities can have, for example, a single-layer structure or a stacked-layer structure of an insulating layer containing one or more of boron, carbon, nitrogen, oxygen, fluorine, magnesium, aluminum, silicon, phosphorus, chlorine, argon, gallium, germanium, yttrium, zirconium, lanthanum, neodymium, hafnium, and tantalum. Specifically, as a material for the insulating layer having a function of inhibiting transmission of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide or a metal nitride such as aluminum nitride, silicon nitride oxide, or silicon nitride can be used.

Specific examples of the insulating layer having a function of inhibiting transmission of oxygen and impurities such as water and hydrogen include metal oxides such as aluminum oxide, magnesium oxide, gallium oxide, germanium oxide, yttrium oxide, zirconium oxide, lanthanum oxide, neodymium oxide, hafnium oxide, and tantalum oxide. Other examples of the insulating layer having a function of inhibiting transmission of oxygen and impurities such as water and hydrogen include oxides containing aluminum and hafnium (hafnium aluminate). Other examples of the insulating layer having a function of inhibiting transmission of oxygen and impurities such as water and hydrogen include metal nitrides such as aluminum nitride, aluminum titanium nitride, titanium nitride, silicon nitride oxide, and silicon nitride.

An insulating layer that is in contact with an oxide semiconductor layer or provided in the vicinity of the oxide semiconductor layer, such as a gate insulating layer, preferably includes a region containing excess oxygen. For example, when an insulating layer including a region containing excess oxygen is in contact with an oxide semiconductor layer or positioned in the vicinity of the oxide semiconductor layer, the amount of oxygen vacancies in the oxide semiconductor layer can be reduced. Examples of an insulating layer in which a region containing excess oxygen is easily formed include silicon oxide, silicon oxynitride, and porous silicon oxide.

At least one of the insulating layers 214, 275, 282, and 283 preferably functions as a barrier insulating film that inhibits diffusion of impurities from the substrate side or from above the transistor 200 into the transistor 200. Thus, at least one of the insulating layers 214, 275, 282, and 283 is preferably formed using an insulating material having a function of inhibiting diffusion of impurities. Alternatively, an insulating material having a function of inhibiting diffusion of oxygen is preferably used.

In this specification and the like, a barrier insulating film refers to an insulating film having a barrier property. A barrier property refers to a property of hardly diffusing a particular substance (also referred to as a property of hardly transmitting a particular substance, a low permeability of a particular substance, or a function of inhibiting diffusion of a particular substance). Alternatively, a barrier property refers to a function of capturing or fixing (also referred to as gettering) a particular substance. Hydrogen in the expression of “diffusion of hydrogen” or “entry of hydrogen” refers to, for example, at least one of a hydrogen atom, a hydrogen molecule, substances bonded to hydrogen, such as a water molecule and OH⁻, and the like. An impurity in the expression of “diffusion of an impurity” or “entry of an impurity” refers to, for example, at least one of a hydrogen atom, a hydrogen molecule, a water molecule, a nitrogen atom, a nitrogen molecule, a nitrogen oxide molecule (e.g., N₂O, NO, and NO₂), a copper atom, and the like. Oxygen in the expression of “diffusion of oxygen” refers to, for example, at least one of an oxygen atom, an oxygen molecule, and the like.

An insulator having a function of inhibiting diffusion of oxygen and impurities is preferably used as the insulating layers 214, 275, 282, and 283, and examples of the insulator include aluminum oxide, magnesium oxide, hafnium oxide, gallium oxide, indium gallium zinc oxide, silicon nitride, and silicon nitride oxide. For example, silicon nitride, which has a high hydrogen barrier property, is preferably used for the insulating layers 214, 275, and 283. For example, an insulator having a function of capturing or fixing hydrogen is preferably used as the insulating layers 214 and 282. Accordingly, impurities can be inhibited from diffusing into the transistor 200 from the substrate side through the insulating layer 214. Furthermore, impurities can be inhibited from diffusing to the transistor 200 side from an interlayer insulating film and the like positioned outward from the insulating layer 283. In addition, oxygen contained in the insulating layer 224 and the like can be inhibited from diffusing to the substrate side through the insulating layer 214. Oxygen contained in the insulating layer 280 and the like can be inhibited from diffusing to above the transistor 200 through the insulating layer 282 and the like. In this manner, the transistor 200 is preferably surrounded by the insulating layers 214, 275, 282, and 283, which have a function of inhibiting diffusion of oxygen and impurities.

Examples of an insulator having a function of capturing or fixing hydrogen include a metal oxide having an amorphous structure. As the insulating layers 214 and 282, a metal oxide such as magnesium oxide or an oxide containing one or both of aluminum and hafnium is preferably used, for example. In such a metal oxide having an amorphous structure, an oxygen atom has a dangling bond, and the metal oxide has a property of capturing or fixing hydrogen with the dangling bond in some cases. That is, the metal oxide having an amorphous structure is highly capable of capturing or fixing hydrogen. When such a metal oxide having an amorphous structure is used as the component of the transistor 200 or provided in the vicinity of the transistor 200, hydrogen contained in the transistor 200 or hydrogen in the vicinity of the transistor 200 can be captured or fixed. In particular, hydrogen contained in the channel formation region of the transistor 200 is preferably captured or fixed. With such a structure, the transistor 200 and the semiconductor device with excellent characteristics and high reliability can be fabricated.

Each of the insulating layers 214 and 282 preferably has an amorphous structure but may partly have a crystal region. The insulating layers 214 and 282 may each have a multilayer structure in which a layer having an amorphous structure and a layer having a crystal region are stacked. For example, a stacked-layer structure in which a layer having a crystal region, typically, a layer having a polycrystalline structure, is formed over a layer having an amorphous structure may be employed.

The insulating layers 214, 275, 282, and 283 can be formed by a sputtering method, for example. A deposition gas in a sputtering method need not include molecules containing hydrogen; thus, the hydrogen concentrations in the insulating layers 214, 275, 282, and 283 can be reduced. Note that the deposition method is not limited to a sputtering method, and a CVD method, an MBE method, a PLD method, an ALD method, or the like may be used as appropriate.

FIG. 3 illustrates an example in which the insulating layer 214 has a two-layer structure of an insulating layer 214a and an insulating layer 214b over the insulating layer 214a.

In the case where the insulating layer 214 has a stacked-layer structure, the above-described barrier insulating layer against hydrogen is preferably used as the insulating layer 214a. The insulating layer 214b preferably has a function of capturing or fixing hydrogen. Such a structure can inhibit diffusion of hydrogen into a region surrounded by the insulating layers 214a and 283. Since the transistor 200 is included in the region, hydrogen in the transistor 200 can be captured or fixed.

The insulating layers 216 and 280 are preferably formed using a material with a lower dielectric constant than the material for the insulating layer 214. In the case where a low-dielectric-constant material is used for an interlayer film, the parasitic capacitance between wirings can be reduced. For example, silicon oxide, silicon oxynitride, or silicon nitride oxide can be used for the insulating layers 216 and 280. For another example, silicon oxide to which fluorine is added, silicon oxide to which carbon is added, or silicon oxide to which carbon and nitrogen are added can be used. For another example, porous silicon oxide or the like can be used. These silicon oxides can contain nitrogen. Silicon oxide and silicon oxynitride are particularly preferable because of their thermal stability. In particular, materials such as silicon oxide, silicon oxynitride, and porous silicon oxide are preferably used, in which case a region containing excess oxygen can be easily formed.

The concentration of an impurity such as water or hydrogen in the insulating layer 280 is preferably reduced. For example, an oxide containing silicon, such as silicon oxide or silicon oxynitride, can be used for the insulating layer 280 as appropriate. The top surface of the insulating layer 280 may be planarized.

The insulating layer 250 preferably has a function of capturing or fixing hydrogen. This can reduce the hydrogen concentration in the oxide semiconductor layer 230 (the hydrogen concentration especially in the channel formation region of the transistor). Accordingly, V_{O}H in the channel formation region can be reduced, so that the channel formation region can be an i-type or substantially i-type region.

Examples of a material for the insulating layer having a function of capturing or fixing hydrogen include metal oxides such as an oxide containing hafnium, an oxide containing magnesium, an oxide containing aluminum, and an oxide containing aluminum and hafnium (hafnium aluminate). These metal oxides may further contain zirconium; examples include an oxide containing hafnium and zirconium. Note that some oxygen atoms in a metal oxide having an amorphous structure have dangling bonds; thus, the metal oxide has a high capability of capturing or fixing hydrogen. Thus, the above metal oxides preferably have an amorphous structure. For example, the above metal oxides may have an amorphous structure by containing silicon. For example, an oxide containing hafnium and silicon (hafnium silicate) is preferably used. Note that a metal oxide may partly have one or both of a crystal region and a crystal grain boundary.

Note that a function of capturing or fixing a particular substance can also be referred to as a property of hardly diffusing a particular substance. Thus, a function of capturing or fixing a particular substance can be rephrased as a barrier property.

Since the insulating layer 250 is in contact with the oxide semiconductor layer 230, the insulating layer 250 preferably includes a region containing excess oxygen. The insulating layer 250 including the region containing excess oxygen can reduce oxygen vacancies in the oxide semiconductor layer 230. Examples of an insulating layer in which a region containing excess oxygen is easily formed include silicon oxide, silicon oxynitride, and porous silicon oxide.

FIG. 3 illustrates an example in which the insulating layer 250 has a two-layer structure of an insulating layer 250a and an insulating layer 250b over the insulating layer 250a.

In the case where the insulating layer 250 has a stacked-layer structure, a layer in contact with the oxide semiconductor layer 230 preferably has a function of capturing or fixing hydrogen. That is, in FIG. 3, the insulating layer 250a preferably has a function of capturing or fixing hydrogen. As the insulating layer 250b, the above-described barrier insulating layer against hydrogen is preferably used.

When the insulating layer 250a has a function of capturing or fixing hydrogen, hydrogen contained in the oxide semiconductor layer 230 can be captured or fixed more effectively. Thus, the hydrogen concentration in the oxide semiconductor layer 230 can be reduced. For the insulating layer 250a, for example, hafnium silicate or the like is preferably used. The insulating layer 250a preferably has an amorphous structure.

The insulating layer 250a having an amorphous structure can inhibit formation of a crystal grain boundary. Inhibiting the formation of a crystal grain boundary results in higher film planarity of the insulating layer 250a. This makes the thickness distribution of the insulating layer 250a uniform and eliminates an extremely thin portion, so that the withstand voltage of the insulating layer 250a can be improved. In addition, the thickness distribution of a film provided on the insulating layer 250a can be uniform.

Moreover, inhibiting the formation of a crystal grain boundary in the insulating layer 250a can reduce leakage current due to the defect states in the crystal grain boundary. Thus, the insulating layer 250a can function as an insulating film with little leakage current.

Hafnium oxide is a high-k material; thus, depending on the silicon content, hafnium silicate is also a high-k material. Accordingly, in the case where the insulating layer 250a is used as a gate insulating layer, a gate potential applied during the operation of the transistor can be reduced while the physical thickness of the gate insulating layer is maintained. In addition, the equivalent oxide thickness (EOT) of the gate insulating layer can be reduced.

The use of the barrier insulating layer against hydrogen as the insulating layer 250b can inhibit diffusion of impurities contained in the conductive layer 260 into the oxide semiconductor layer 230. Silicon nitride is suitable for the insulating layer 250b because of its high hydrogen barrier property.

With such a structure, a semiconductor device having excellent electrical characteristics can be provided. A highly reliable semiconductor device can be provided. A semiconductor device with a small variation in electrical characteristics of transistors can be provided. A semiconductor device with a high on-state current can be provided.

A high-k material is preferably used for the insulating layer 250. An example of the high-k material is an oxide containing one or both of aluminum and hafnium. With the use of the high-k material for the insulating layer 250, a gate potential applied during the operation of the transistor can be reduced while the physical thickness of the gate insulating layer is maintained. In addition, the equivalent oxide thickness (EOT) of the insulating layer functioning as the gate insulating layer can be reduced.

As described above, for the insulating layer 250a, an oxide containing one or both of aluminum and hafnium is preferably used, an oxide having an amorphous structure and containing one or both of aluminum and hafnium is further preferably used, and aluminum oxide having an amorphous structure is still further preferably used.

Furthermore, the insulating layer 250 may include a thermally stable insulating layer such as silicon oxide or silicon oxynitride.

The insulating layer 250 preferably includes a barrier insulating layer against oxygen. This can inhibit the oxidation of the conductive layers 242a, 242b, and 260, for example. In the case where the insulating layer 250 has a stacked-layer structure, a layer in contact with the conductive layers 242a and 242b and a layer in contact with the conductive layer 260 are each preferably a barrier insulating layer against oxygen.

The use of a barrier insulating layer against hydrogen and oxygen as the insulating layer 250b can inhibit the oxidation of the conductive layer 260, for example. In addition, it is possible to inhibit formation of oxygen vacancies in the oxide semiconductor layer 230 caused by diffusion of oxygen contained in the oxide semiconductor layer 230 into the conductive layer 260.

Examples of a barrier insulating layer against oxygen include an oxide containing one or both of aluminum and hafnium, magnesium oxide, gallium oxide, gallium zinc oxide, indium gallium zinc oxide, silicon nitride, and silicon nitride oxide. Examples of the oxide containing one or both of aluminum and hafnium include aluminum oxide, hafnium oxide, an oxide containing aluminum and hafnium (hafnium aluminate), and an oxide containing hafnium and silicon (hafnium silicate).

The thickness of the insulating layer 250 is preferably greater than or equal to 0.1 nm and less than or equal to 30 nm, further preferably greater than or equal to 0.1 nm and less than or equal to 20 nm, still further preferably greater than or equal to 0.1 nm and less than or equal to 10 nm, yet further preferably greater than or equal to 0.1 nm and less than or equal to 5.0 nm, yet still further preferably greater than or equal to 0.5 nm and less than or equal to 5.0 nm, yet still further preferably greater than or equal to 1.0 nm and less than 5.0 nm, yet still further preferably greater than or equal to 1.0 nm and less than or equal to 3.0 nm.

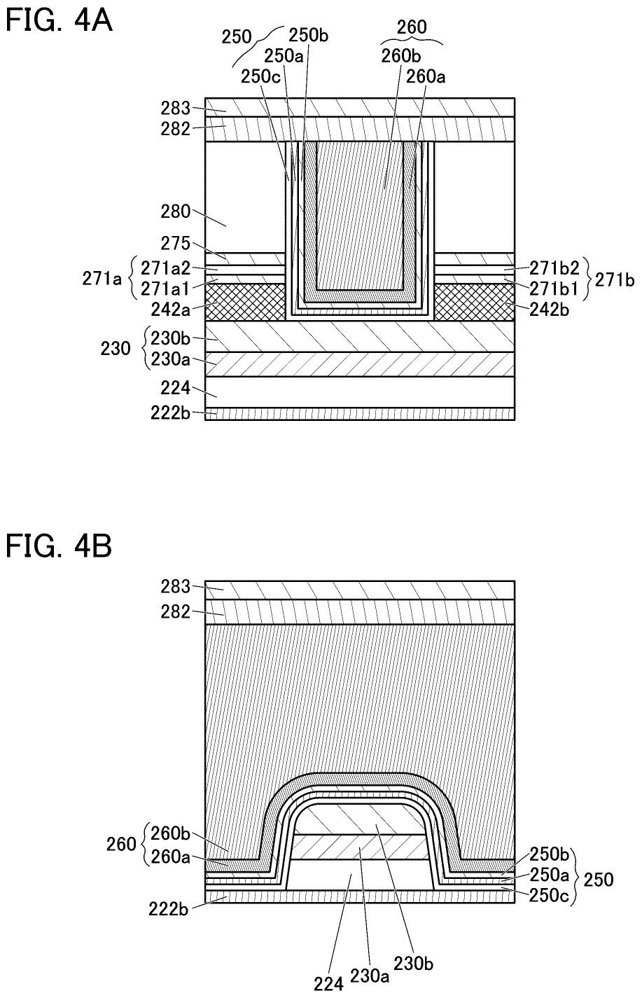

FIGS. 4A and 4B illustrate an example in which the insulating layer 250 has a three-layer structure of an insulating layer 250c, the insulating layer 250a over the insulating layer 250c, and the insulating layer 250b over the insulating layer 250a.

The insulating layers 250a and 250b can have the above-described structures.

The insulating layer 250c is preferably formed using a low-dielectric-constant material. As the low-dielectric-constant material, silicon oxide or silicon oxynitride is preferably used. The insulating layer 250c is in contact with the oxide semiconductor layer 230. When an oxide insulating layer is used as the insulating layer 250c, oxygen can be supplied to the oxide semiconductor layer 230. Providing the insulating layer 250b can inhibit diffusion of oxygen contained in the insulating layer 250c into the conductive layer 260 to inhibit the oxidation of the conductive layer 260. In addition, a reduction in the amount of oxygen supplied to the oxide semiconductor layer 230 from the insulating layer 250c can be inhibited.

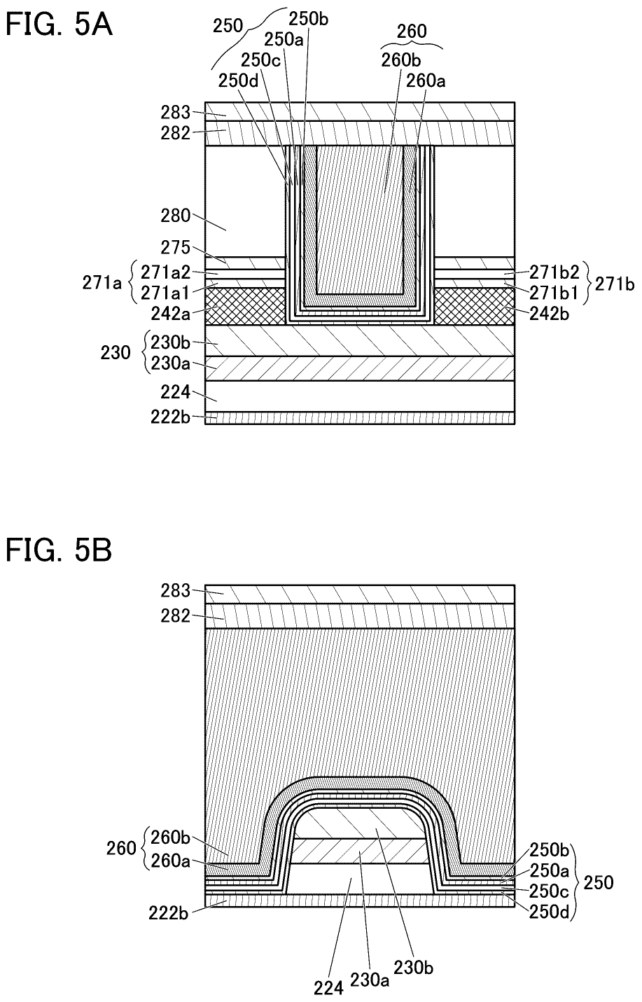

FIGS. 5A and 5B illustrate an example in which the insulating layer 250 has a four-layer structure of an insulating layer 250d, the insulating layer 250c over the insulating layer 250d, the insulating layer 250a over the insulating layer 250c, and the insulating layer 250b over the insulating layer 250a.

The insulating layers 250a to 250c can have the above-described structures.

The insulating layer 250d preferably has a barrier property against oxygen. The insulating layer 250d is in contact with the oxide semiconductor layer 230. The insulating layer 250d having a barrier property against oxygen can inhibit release of oxygen from the oxide semiconductor layer 230. Aluminum oxide is preferably used for the insulating layer 250d, for example. Aluminum oxide has a function of capturing or fixing hydrogen and is thus suitable for the insulating layer 250d in contact with the oxide semiconductor layer 230.

The thicknesses of the insulating layers 250a to 250d are preferably small for scaling down of the transistor. The thicknesses of the insulating layers 250a to 250d are each preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet further preferably greater than or equal to 1 nm and less than 5 nm, yet still further preferably greater than or equal to 1 nm and less than or equal to 3 nm. Note that each of the insulating layers 250a to 250d at least partly has a region with the above thickness.

Typically, the thicknesses of the insulating layer 250d, the insulating layer 250c, the insulating layer 250a, and the insulating layer 250b are 1 nm, 2 nm, 2 nm, and 1 nm, respectively. Such a structure can offer excellent electrical characteristics even when transistors are scaled down or highly integrated.

To reduce the thicknesses of the insulating layers 250a to 250d as described above, an ALD method is preferably used for deposition. As the ALD method, a thermal ALD method, in which a precursor and a reactant react with each other only by a thermal energy, a plasma-enhanced ALD (PEALD) method, in which a reactant excited by plasma is used, and the like can be used. The use of plasma is sometimes preferable because deposition at a lower temperature is possible in a PEALD method.

An ALD method enables a single atomic layer to be formed at a time, and has various advantages such as deposition of an extremely thin film, deposition on a component with a high aspect ratio, deposition of a film with a small number of defects such as pinholes, deposition with excellent coverage, and low-temperature deposition. Thus, the insulating layer 250 can be formed on the side surface of the opening formed in the insulating layer 280 and the like to have a small thickness as described above and to have excellent coverage.

Although the insulating layer 250 has the three-layer structure of the insulating layers 250a to 250c or the four-layer structure of the insulating layers 250a to 250d in the above description, the present invention is not limited thereto. The insulating layer 250 can have a structure including at least one of the insulating layers 250a to 250d. For example, the insulating layer 250 may have a three-layer structure of the insulating layer 250d, the insulating layer 250c over the insulating layer 250d, and the insulating layer 250b over the insulating layer 250c. When the insulating layer 250 is formed of one, two, or three of the insulating layers 250a to 250d, the fabrication process of the semiconductor device can be simplified and the productivity can be improved.

The insulating layer 222 preferably has a function of inhibiting diffusion of hydrogen. Moreover, the insulating layer 222 preferably has a function of inhibiting diffusion of oxygen. For example, the insulating layer 222 preferably has a function of inhibiting diffusion of much hydrogen and/or oxygen compared to the insulating layer 224.

As the insulating layer 222, an insulator containing an oxide of one or both of aluminum and hafnium, which is an insulating material, is preferably used. Alternatively, an oxide containing hafnium and zirconium, e.g., a hafnium zirconium oxide, is preferably used. The insulating layer 222 formed of such a material functions as a layer that inhibits release of oxygen from the oxide semiconductor layer 230 to the substrate side or diffusion of impurities from the periphery of the transistor 200 into the oxide semiconductor layer 230. Thus, providing the insulating layer 222 can inhibit diffusion of impurities into the transistor 200 and inhibit generation of oxygen vacancies in the oxide semiconductor layer 230. Moreover, the conductive layer 215 can be inhibited from reacting with oxygen contained in the insulating layer 224 and the oxide semiconductor layer 230.

Alternatively, aluminum oxide, bismuth oxide, germanium oxide, niobium oxide, silicon oxide, titanium oxide, tungsten oxide, yttrium oxide, or zirconium oxide may be added to the above insulator, for example. Alternatively, the insulator may be subjected to nitriding treatment. The insulating layer 222 may have a stacked-layer structure including silicon oxide, silicon oxynitride, or silicon nitride over any of these insulators.

The insulating layer 222 includes a region functioning as the second gate insulating layer and thus may be formed to have a single-layer structure or a stacked-layer structure including an insulator containing a high-k material described later. The insulating layer 222 can sometimes be formed using a high-dielectric-constant substance such as lead zirconate titanate (PZT), strontium titanate (SrTiO₃), or (Ba,Sr)TiO₃ (BST).

As illustrated in FIG. 3, the insulating layer 222 may have a stacked-layer structure of an insulating layer 222a over the insulating layer 216 and the conductive layer 215 and an insulating layer 222b over the insulating layer 222a.

Any of the insulating layers that can be used as the insulating layer 222 is used as the insulating layer 222b.

The insulating layer 222a is provided between the insulating layer 222b and each of the insulating layer 216 and the conductive layer 215. The insulating layer 222a preferably has a function of inhibiting diffusion of hydrogen. This can inhibit diffusion of hydrogen into the transistor 200 from below the insulating layer 222a.

For the insulating layer 222a, for example, silicon nitride deposited by an ALD method (especially, a PEALD method) is preferably used. The insulating layer 222a deposited by an ALD method can have excellent coverage even when unevenness is formed by the insulating layer 216 and the conductive layer 215. Thus, formation of a pinhole, disconnection, or the like on the insulating layer 222b formed over the insulating layer 222a can be inhibited.

The insulating layer 224 is in contact with the oxide semiconductor layer 230 and thus is formed using silicon oxide, silicon oxynitride, or the like as appropriate, for example.

Note that the insulating layer 222 and/or the insulating layer 224 may have a stacked-layer structure of two or more layers. In those cases, without limitation to a stacked-layer structure formed of the same material, a stacked-layer structure formed of different materials may be employed. The insulating layer 224 may be formed into an island shape overlapping with the oxide semiconductor layer 230. In that case, the insulating layer 275 is in contact with the side surface of the insulating layer 224 and the top surface of the insulating layer 222. In this specification and the like, the term “island shape” refers to a state where two or more layers formed using the same material in the same step are physically separated from each other.

The insulating layer 271 preferably functions as at least a barrier insulating film against oxygen. For example, the insulating layer 271 preferably has a function of inhibiting oxygen diffusion more than the insulating layer 280.

Since the insulating layers 271a and 271b are respectively in contact with the conductive layers 242a and 242b, the insulating layers 271a and 271b are each preferably an inorganic insulator that is unlikely to oxidize the conductive layers 242a and 242b. For example, the insulating layers 271a and 271b are each preferably formed using a nitride insulating layer that can be used as the insulating layer 250b. For example, silicon nitride can be used for the insulating layers 271a and 271b.

The insulating layers 271a and 271b function as an etching stopper at the time of processing the conductive layers 242a and 242b, and are inorganic insulators that protect the conductive layers 242a and 242b. For example, as illustrated in FIG. 3, it is preferable that the insulating layer 271a have a stacked-layer structure of an insulating layer 271a1 and an insulating layer 271a2 over the insulating layer 271a1 and that the insulating layer 271b have a stacked-layer structure of an insulating layer 271b1 and an insulating layer 271b2 over the insulating layer 271b1. Here, the insulating layers 271a1 and 271b1 are each preferably formed using a nitride insulating layer that can be used as the insulating layer 250b. An oxide insulating layer that can be used as the insulating layer 250c is preferably used as the insulating layers 271a2 and 271b2 so that the insulating layers 271a2 and 271b2 function as an etching stopper. For example, silicon nitride can be used for the insulating layers 271a1 and 271b1, and silicon oxide can be used for the insulating layers 271a2 and 271b2.

An insulating layer to be the insulating layers 271a and 271b functions as a mask for a conductive layer to be the conductive layers 242a and 242b; thus, the conductive layers 242a and 242b do not have curved surfaces between the side surfaces and the top surfaces. Thus, an end portion at the intersection of the side surface and the top surface of the conductive layer 242a is angular. The cross-sectional area of the conductive layer 242a is larger in the case where the end portion at the intersection of the side surface and the top surface of the conductive layer 242a is angular than in the case where the end portion is rounded. The same applies to the conductive layer 242b. The use of a nitride insulating layer that is unlikely to oxidize a metal as the insulating layers 271a and 271b can inhibit excessive oxidation of the conductive layers 242a and 242b. Accordingly, the resistances of the conductive layers 242a and 242b are reduced, so that the on-state current of the transistor 200 can be increased.

The insulating layer 275 is provided to cover the insulating layer 224, the oxide semiconductor layer 230, the conductive layer 242, and the insulating layer 271. The insulating layer 275 preferably has a function of capturing or fixing hydrogen. In that case, the insulating layer 275 preferably includes silicon nitride or a metal oxide having an amorphous structure, for example, an insulator such as aluminum oxide or magnesium oxide. Alternatively, for example, a stacked-layer film of aluminum oxide and silicon nitride over the aluminum oxide may be used as the insulating layer 275.

When the above insulating layers 271 and 275 are provided, the conductive layer 242 can be covered with the barrier insulating films against oxygen. With such a structure, the conductive layer 242 can be inhibited from being directly oxidized by oxygen contained in the insulating layer 280, so that an increase in the resistivity and a reduction in the on-state current can be inhibited.

The insulating layer 282 preferably has a function of inhibiting diffusion of impurities into the insulating layer 280 from above and a function of capturing or fixing impurities such as hydrogen. The insulating layer 282 preferably functions also as a barrier insulating film against oxygen. As the insulating layer 282, a metal oxide having an amorphous structure, e.g., an insulator such as aluminum oxide, is used. In that case, the insulating layer 282 contains at least oxygen and aluminum. The insulating layer 282, which has a function of capturing or fixing impurities such as hydrogen, is provided in contact with the insulating layer 280 in a region sandwiched between the insulating layers 214 and 283, whereby impurities such as hydrogen contained in the insulating layer 280 and the like can be captured or fixed and the amount of hydrogen in the region can be kept constant. Accordingly, the transistor 200 and the semiconductor device with excellent characteristics and high reliability can be fabricated.

As the insulating layer 282, aluminum oxide is further preferably deposited by a sputtering method using an aluminum target in an atmosphere containing an oxygen gas. In the sputtering method, the amount of oxygen implanted into the layers below the insulating layer 282 can be controlled by the amount of radio frequency (RF) power applied to the substrate. For example, the amount of oxygen implanted into the layers below the insulating layer 282 is smaller as the RF power is lower, and the amount of oxygen is easily saturated even when the insulating layer 282 has a small thickness. Moreover, the amount of oxygen implanted into the layers below the insulating layer 282 is larger as the RF power is higher.

As the insulating layer 283, a barrier insulating layer against hydrogen is preferably used. This can inhibit diffusion of hydrogen into the oxide semiconductor layer 230 from above the insulating layer 283. A silicon nitride film and a silicon nitride oxide film can be suitably used for the insulating layer 283 because they release few impurities (e.g., water and hydrogen) and are unlikely to transmit oxygen and hydrogen.

It is particularly preferable to use silicon nitride deposited by a sputtering method for the insulating layer 283. A deposition gas in a sputtering method need not include molecules containing hydrogen; thus, the hydrogen concentration in the insulating layer 283 can be reduced. When the insulating layer 283 is formed by a sputtering method, high-density silicon nitride can be obtained.

### [Conductive Layer]

For each of the conductive layers included in the semiconductor device (e.g., the conductive layers 215, 242, and 260), it is preferable to use a metal element selected from aluminum, chromium, copper, silver, gold, platinum, zinc, tantalum, nickel, titanium, iron, cobalt, molybdenum, tungsten, hafnium, vanadium, niobium, manganese, magnesium, zirconium, beryllium, indium, ruthenium, iridium, strontium, lanthanum, and the like; an alloy containing any of the above metal elements; an alloy containing a combination of the above metal elements; or the like. As an alloy containing any of the above metal elements, a nitride of the alloy or an oxide of the alloy may be used. For example, tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like is preferably used. Alternatively, a semiconductor having high electric conductivity, typified by polycrystalline silicon containing an impurity element such as phosphorus, or silicide such as nickel silicide may be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting oxygen diffusion, or a material maintaining its conductivity even after absorbing oxygen. Examples of the conductive material containing oxygen include indium oxide containing tungsten oxide, indium oxide containing titanium oxide, indium tin oxide (also referred to as ITO), indium tin oxide containing titanium oxide, indium tin oxide to which silicon is added (also referred to as ITSO), indium zinc oxide (also referred to as IZO (registered trademark)), and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because of its high conductivity.

Conductive layers formed using any of the above materials may be stacked. For example, a stacked-layer structure combining a material containing the above metal element and a conductive material containing oxygen may be employed. Alternatively, a stacked-layer structure combining a material containing the above metal element and a conductive material containing nitrogen may be employed. Further alternatively, a stacked-layer structure combining a material containing the above metal element, a conductive material containing oxygen, and a conductive material containing nitrogen may be employed.

When a metal oxide is used for the channel formation region of the transistor, a conductive layer functioning as the gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

The conductive layer 260 is preferably formed using a material with high conductivity. For the conductive layer 260, a conductive material that is not easily oxidized, a conductive material having a function of inhibiting oxygen diffusion, or the like is preferably used. Examples of the conductive material include a conductive material containing nitrogen (e.g., titanium nitride or tantalum nitride) and a conductive material containing oxygen (e.g., ruthenium oxide) as described above. Thus, a decrease in conductivity of the conductive layer 260 can be inhibited.

For the conductive layer 260, a conductive material containing oxygen and a metal element contained in a metal oxide where a channel is formed may be used. The above-described conductive material containing a metal element and nitrogen (e.g., titanium nitride or tantalum nitride) may be used. One or more of indium tin oxide, indium oxide containing tungsten oxide, indium zinc oxide containing tungsten oxide, indium oxide containing titanium oxide, indium tin oxide containing titanium oxide, indium zinc oxide, and indium tin oxide to which silicon is added may be used. Indium gallium zinc oxide containing nitrogen may be used. With the use of such a material, hydrogen contained in the metal oxide where the channel is formed can be captured in some cases. Alternatively, hydrogen entering from a surrounding insulating layer or the like can be captured in some cases.

FIG. 3 illustrates an example in which the conductive layer 260 has a two-layer structure of a conductive layer 260a and a conductive layer 260b over the conductive layer 260a. In that case, it is preferable to use titanium nitride for the conductive layer 260a and tungsten for the conductive layer 260b, for example. This can increase the conductivity of the conductive layer 260.

The conductive layer 260a is preferably formed using a conductive material having a function of inhibiting diffusion of impurities. Alternatively, the conductive layer 260a is preferably formed using a conductive material having a function of inhibiting diffusion of oxygen. When the conductive layer 260a has a function of inhibiting diffusion of oxygen, a decrease in the conductivity of the conductive layer 260b due to oxidation caused by oxygen contained in the insulating layer 250 can be inhibited. As the conductive material having a function of inhibiting diffusion of oxygen, for example, titanium, titanium nitride, tantalum, tantalum nitride, ruthenium, or ruthenium oxide is preferably used. Thus, the conductive layer 260a may be a single layer or a stacked layer of the above conductive materials. For example, titanium nitride may be used for the conductive layer 260a.

The conductive layer 260 also functions as a wiring and thus is preferably formed using a conductor having high conductivity. For example, a conductive material containing tungsten, copper, or aluminum as its main component can be used for the conductive layer 260b. The conductive layer 260b may have a stacked-layer structure, for example, a stacked-layer structure of titanium or titanium nitride and the above conductive material.

The conductive layer 215 is preferably formed using a material with high conductivity. For the conductive layer 215, tungsten or aluminum is preferably used. A conductive material containing nitrogen, such as tantalum nitride or titanium nitride, may be used for the conductive layer 215. The conductive material containing nitrogen is hardly oxidized or has a function of inhibiting oxygen diffusion and thus can be suitably used when an oxide insulating layer is used as one or both of the insulating layers 214 and 216.

FIG. 3 illustrates an example in which the conductive layer 215 has a two-layer structure of a conductive layer 215a and a conductive layer 215b over the conductive layer 215a. The conductive layer 215a is provided in contact with the bottom surface and sidewall of the opening portion formed in the insulating layer 216. The conductive layer 215b is provided to be embedded in a depression formed in the conductive layer 215a. Here, the top surface of the conductive layer 215b is level with the top surfaces of the conductive layer 215a and the insulating layer 216.

Note that the conductive layer 215a is preferably formed using a conductive material having a function of inhibiting diffusion of impurities. Alternatively, the conductive layer 215a is preferably formed using a conductive material having a function of inhibiting diffusion of oxygen.

When the conductive layer 215a is formed using a conductive material having a function of inhibiting diffusion of impurities, impurities contained in the conductive layer 215b can be inhibited from diffusing into the oxide semiconductor layer 230 through the insulating layer 216 and the like. When the conductive layer 215a is formed using a conductive material having a function of inhibiting diffusion of oxygen, a decrease in the conductivity of the conductive layer 215b due to oxidation can be inhibited.

As the conductive layer 215a, any of the conductive layers that can be used as the conductive layer 260a is used. A conductive material containing tungsten, copper, or aluminum as its main component is preferably used for the conductive layer 215b. For example, tungsten may be used for the conductive layer 215b.

Although the conductive layers 215a and 215b are stacked in FIG. 3, the present invention is not limited thereto. For example, the conductive layer 215 may have a single-layer structure or a stacked-layer structure of three or more layers.

### [Substrate]

As a substrate where a transistor is formed, an insulator substrate, a semiconductor substrate, or a conductor substrate can be used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate of silicon or germanium and a compound semiconductor substrate of silicon carbide, silicon germanium, gallium arsenide, indium phosphide, zinc oxide, or gallium oxide. Another example includes a semiconductor substrate in which an insulator region is provided in the above semiconductor substrate, such as a silicon on insulator (SOI) substrate. Examples of the conductor substrate include a graphite substrate, a metal substrate, an alloy substrate, and a conductive resin substrate. Other examples include a substrate containing a nitride of a metal and a substrate containing an oxide of a metal. An insulator substrate provided with a conductor or a semiconductor, a semiconductor substrate provided with a conductor or an insulator, a conductor substrate provided with a semiconductor or an insulator, or the like may be used. Alternatively, these substrates provided with elements may be used. Examples of the element provided over the substrate include a capacitor, a resistor, a switching element, a light-emitting element, and a memory element.

According to one embodiment of the present invention, a novel transistor can be provided. A semiconductor device having excellent electrical characteristics can be provided. A highly reliable semiconductor device can be provided. A semiconductor device with a small variation in transistor characteristics can be provided. A semiconductor device with a high on-state current can be provided. A semiconductor device with high field-effect mobility can be provided. A semiconductor device with excellent frequency characteristics can be provided. A semiconductor device that can be scaled down or highly integrated can be provided. A semiconductor device with low power consumption can be provided.

### <Structure Example of Semiconductor Device Including Transistor 200 and Capacitor 100>

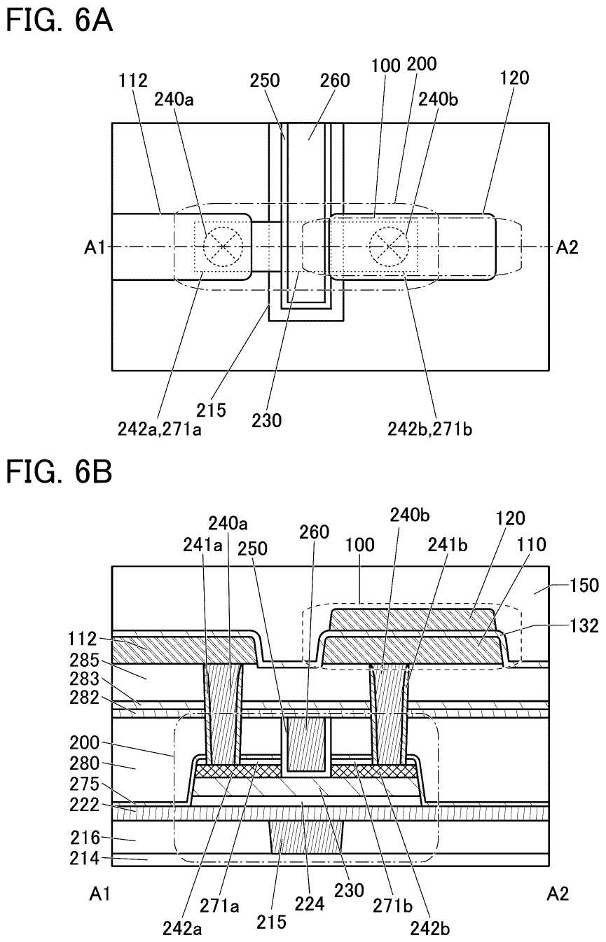

FIGS. 6A and 6B illustrate a semiconductor device including the above transistor 200 and a capacitor 100. FIG. 6A is a plan view of the semiconductor device. FIG. 6B is a cross-sectional view taken along the dashed-dotted line A1-A2 in FIG. 6A, which corresponds to a cross-sectional view of the transistor 200 in the channel length direction. Note that for simplification, some components are not illustrated in the plan view of FIG. 6A.

In the semiconductor device illustrated in FIGS. 6A and 6B, the capacitor 100 and a conductive layer 112 are provided over the transistor 200. Here, the area where the capacitor 100 and the transistor 200 overlap with each other is preferably large in the plan view. Such a structure can reduce the area occupied by the semiconductor device including the capacitor 100 and the transistor 200. Accordingly, scaling down or high integration of the semiconductor device can be achieved.

The semiconductor device includes a conductive layer 240a and a conductive layer 240b that function as plugs. The conductive layer 240a is provided in an opening portion formed in the insulating layers 285, 283, 282, 280, 275, and 271a, and the conductive layer 240b is provided in an opening portion formed in the insulating layers 285, 283, 282, 280, 275, and 271b.

As illustrated in FIG. 6B, the conductive layer 240a includes a region in contact with the conductive layer 242a and a region in contact with at least part of the bottom surface of the conductive layer 112. The conductive layer 240b includes a region in contact with the conductive layer 242b and a region in contact with at least part of the bottom surface of a conductive layer 110 included in the capacitor 100. That is, the conductive layer 240a is electrically connected to one of the source electrode and the drain electrode of the transistor 200, and the conductive layer 240b is electrically connected to the other of the source electrode and the drain electrode of the transistor 200.

The conductive layers 240a and 240b are preferably formed using a conductive material containing tungsten, copper, or aluminum as its main component, for example.

Although FIG. 6B illustrates an example in which the conductive layers 240a and 240b each have a single-layer structure, the present invention is not limited thereto. For example, the conductive layers 240a and 240b may each have a stacked-layer structure of two or more layers.

The conductive layers 240a and 240b may each have a stacked-layer structure of a first conductive layer provided along the side and bottom surfaces of the opening portion and a second conductive layer over the first conductive layer, for example. In the case where the conductive layers 240a and 240b each have a stacked-layer structure, a conductive material having a function of inhibiting transmission of impurities is preferably used for the first conductive layer provided in the vicinity of the insulating layers 285 and 280. For example, tantalum, tantalum nitride, titanium, titanium nitride, ruthenium, or ruthenium oxide is preferably used. The conductive material having a function of inhibiting transmission of impurities can be used as a single layer or stacked layers. With such a structure, impurities contained in the components above the insulating layer 283 can be inhibited from entering the oxide semiconductor layer 230 through the conductive layers 240a and 240b. The second conductive layer also functions as a wiring and thus is preferably formed using a conductor having high conductivity. For the second conductive layer, for example, a conductive material containing tungsten, copper, or aluminum as its main component is used.

An insulating layer 241a is provided in contact with an inner wall of the opening portion formed in the insulating layers 285, 283, 282, 280, 275, and 271a and the side surface of the conductive layer 240a. An insulating layer 241b is provided in contact with an inner wall of the opening portion formed in the insulating layers 285, 283, 282, 280, 275, and 271b and the side surface of the conductive layer 240b.

Each of the insulating layers 241a and 241b preferably functions as a barrier insulating film against hydrogen and/or oxygen. For example, silicon nitride, silicon nitride oxide, aluminum oxide, hafnium oxide, or the like is preferably used for the insulating layers 241a and 241b. Alternatively, for example, a metal oxide such as magnesium oxide, gallium oxide, germanium oxide, yttrium oxide, zirconium oxide, lanthanum oxide, neodymium oxide, or tantalum oxide can be used. Since the insulating layers 241a and 241b are provided in contact with the insulating layers 283, 282, and 275, impurities contained in the insulating layer 280 and the like can be inhibited from entering the oxide semiconductor layer 230 through the conductive layers 240a and 240b. Silicon nitride is particularly preferable because of its high barrier property against hydrogen.

The insulating layer 241a is provided between the insulating layer 280 and the conductive layer 240a, and the insulating layer 241b is provided between the insulating layer 280 and the conductive layer 240b. The insulating layer 280 contains excess oxygen and is provided in the vicinity of the oxide semiconductor layer 230. The insulating layers 241a and 241b having a barrier property against oxygen can inhibit oxygen contained in the insulating layer 280 from being absorbed by the conductive layers 240a and 240b.

Although FIG. 6B illustrates an example in which the insulating layers 241a and 241b each have a single-layer structure, the present invention is not limited thereto. For example, the insulating layers 241a and 241b may each have a stacked-layer structure of two or more layers.

The insulating layers 241a and 241b may each have a structure in which a first insulating layer is provided in contact with the inner wall of the opening portion and a second insulating layer is located inward from the first insulating layer, for example. When the insulating layers 241a and 241b each have a stacked-layer structure, the first insulating layer in contact with the inner wall of the opening portion formed in the insulating layer 280 and the like and the second insulating layer located inward from the first insulating layer are preferably formed using a combination of a barrier insulating layer against oxygen and a barrier insulating layer against hydrogen. For example, aluminum oxide deposited by an ALD method can be used for the first insulating layer and silicon nitride deposited by a PEALD method can be used for the second insulating layer. Such a structure can inhibit oxidation of the conductive layers 240a and 240b and inhibit entry of hydrogen into the conductive layers 240a and 240b.

### <Capacitor 100>

The capacitor 100 is provided above the transistor 200. The capacitor 100 includes the conductive layer 110 functioning as a first electrode (also referred to as a lower electrode), a conductive layer 120 functioning as a second electrode (also referred to as an upper electrode), and an insulating layer 132 functioning as a dielectric. The first electrode and the second electrode serve as a pair of electrodes of the capacitor 100.

For the conductive layers 110 and 120, any of the materials described above in [Conductive layer] can be used in a single-layer structure or a stacked-layer structure.

For example, the conductive layer 112 provided over the conductive layer 240a and the conductive layer 110 provided over the conductive layer 240b can be formed at the same time. In that case, the conductive layers 112 and 110 are formed using the same conductive material. Note that the conductive layer 112 functions as a plug or a wiring that is electrically connected to the capacitor 100 or the transistor 200.

The conductive layers 112 and 110 each have a single-layer structure in FIG. 6B; however, the present invention is not limited thereto. For example, the conductive layers 112 and 110 may each have a stacked-layer structure of two or more layers. For example, between a conductor having a barrier property and a conductor having high conductivity, a conductor that is highly adhesive to the conductor having a barrier property and the conductor having high conductivity may be formed.

The insulating layer 132 can be formed to have a single-layer structure or a stacked-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like. For example, as the insulating layer 132, an insulator in which zirconium oxide, aluminum oxide, and zirconium oxide are stacked in this order can be used.

For example, the insulating layer 132 preferably has a stacked-layer structure of an insulator containing a material with high dielectric strength (a low-dielectric-constant material) and an insulator containing a high-dielectric-constant (high-k) material. In the capacitor 100 having such a structure, a sufficient capacitance can be provided owing to the insulator containing a high-k material, and the dielectric strength can be increased owing to the insulator containing a material with high dielectric strength, so that the electrostatic breakdown of the capacitor 100 can be inhibited.

An insulating layer 150 is provided over the conductive layer 120 and the insulating layer 132. The insulating layer 150 functions as an interlayer film.

For example, the insulating layer 150 preferably contains the low-dielectric-constant material. Alternatively, the insulating layer 150 preferably has a stacked-layer structure of an insulating layer containing a low-dielectric-constant inorganic insulating material and an insulating layer containing a low-dielectric-constant resin. Since silicon oxide and silicon oxynitride have thermal stability, a combination of silicon oxide or silicon oxynitride with a resin allows the stacked-layer structure to be thermally stable and have a low dielectric constant. The use of the low-dielectric-constant material for the insulating layer 150 can reduce the parasitic capacitance between wirings.

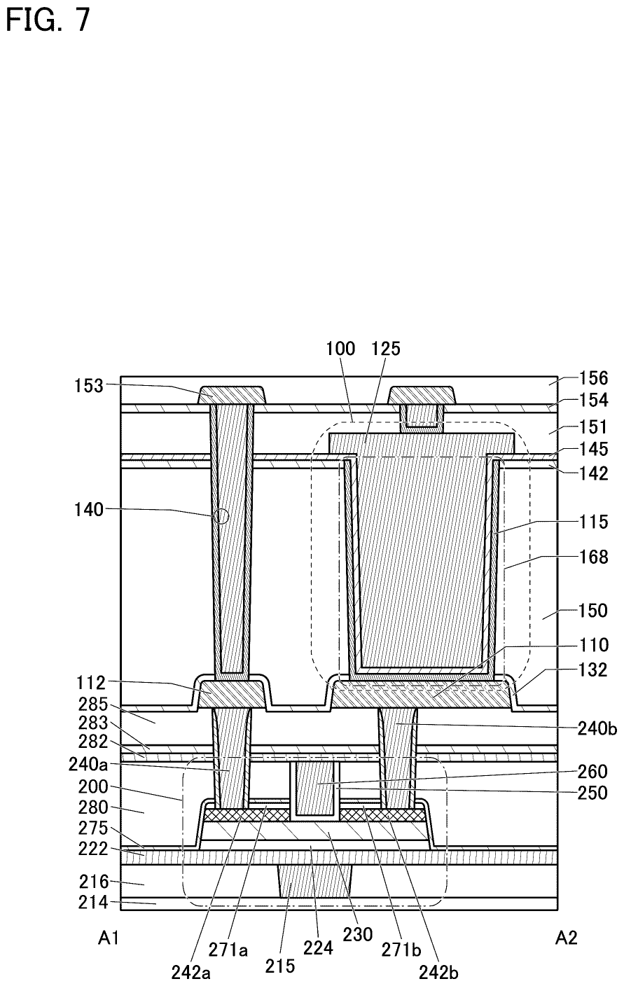

Although the capacitor 100 of the semiconductor device illustrated in FIGS. 6A and 6B has a planar shape, the present invention is not limited thereto. For example, the capacitor 100 may have a cylindrical shape as illustrated in FIG. 7. Note that the structure below and including the insulating layer 150 of the semiconductor device illustrated in FIG. 7 is similar to that of the semiconductor device illustrated in FIGS. 6A and 6B.

In the semiconductor device illustrated in FIG. 7, the insulating layer 150 is provided over the insulating layer 132, and an insulating layer 142 is provided over the insulating layer 150. An opening portion 168 reaching the conductive layer 110 is formed in the insulating layers 132, 150, and 142.

The capacitor 100 illustrated in FIG. 7 includes a conductive layer 115, an insulating layer 145 over the conductive layer 115 and the insulating layer 142, and a conductive layer 125 over the insulating layer 145. Note that at least parts of the conductive layer 115, the insulating layer 145, and the conductive layer 125 are positioned in the opening portion 168.

An insulating layer 151 is provided over the conductive layer 125 and the insulating layer 145, an insulating layer 154 is provided over the insulating layer 151, and a conductive layer 153 and an insulating layer 156 are provided over the insulating layer 154. A conductive layer 140 is provided in an opening portion formed in the insulating layers 132, 150, 142, 145, 151, and 154.

The conductive layer 115 functions as the first electrode of the capacitor 100, the conductive layer 125 functions as the second electrode of the capacitor 100, and the insulating layer 145 functions as the dielectric of the capacitor 100. The first electrode and the second electrode of the capacitor 100 face each other with the dielectric positioned therebetween, along the side surface of the opening portion 168 as well as the bottom surface thereof; thus, the capacitance per unit area can be larger. Accordingly, the deeper the opening portion 168 is, the larger the capacitance of the capacitor 100 can be. Increasing the capacitance per unit area of the capacitor 100 in this manner enhances scaling down and integration of the semiconductor device.

Any of the insulating layers that can be used as the insulating layer 150 is used as the insulating layer 151. Any of the insulating layers that can be used as the insulating layer 282 is used as the insulating layer 142.

The shape of the opening portion 168 when seen from above may be a quadrangular shape, a polygonal shape other than a quadrangular shape, a polygonal shape with rounded corners, or a circular shape such as an elliptical shape. Here, the area where the opening portion 168 and the transistor 200 overlap with each other is preferably larger in the plan view. Such a structure can reduce the area occupied by the semiconductor device including the capacitor 100 and the transistor 200.

The conductive layer 115 is provided in contact with the side surfaces of the insulating layers 150 and 142 in the opening portion 168. The top surface of the conductive layer 115 is preferably level with the top surface of the insulating layer 142. The bottom surface of the conductive layer 115 is in contact with the conductive layer 110 through the opening portion 168. The conductive layer 115 is preferably formed by an ALD method, a CVD method, or the like and is formed using any of the conductive layers that can be used as the conductive layer 215, for example.

The insulating layer 145 is provided to cover the conductive layer 115 and the insulating layer 142. The insulating layer 145 is preferably formed by an ALD method, a CVD method, or the like. Any of the insulating layers that can be used as the insulating layer 132 can be used as the insulating layer 145.

The conductive layer 125 is provided to fill the opening portion 168. The conductive layer 125 is preferably formed by an ALD method, a CVD method, or the like, and any of the conductive layers that can be used as the conductive layer 215 is used, for example.

The conductive layer 153 is provided over the insulating layer 154 and covered with the insulating layer 156. As the conductive layer 153, any of the conductive layers that can be used as the conductive layer 112 is used. As the insulating layer 156, any of the insulating layers that can be used as the insulating layer 150 is used. Here, the conductive layer 153 is in contact with the top surface of the conductive layer 140 and functions as a terminal of the capacitor 100 or the transistor 200.

This embodiment can be combined with any of the other embodiments as appropriate. In this specification, in the case where a plurality of structure examples are shown in one embodiment, the structure examples can be combined as appropriate.

### Embodiment 2

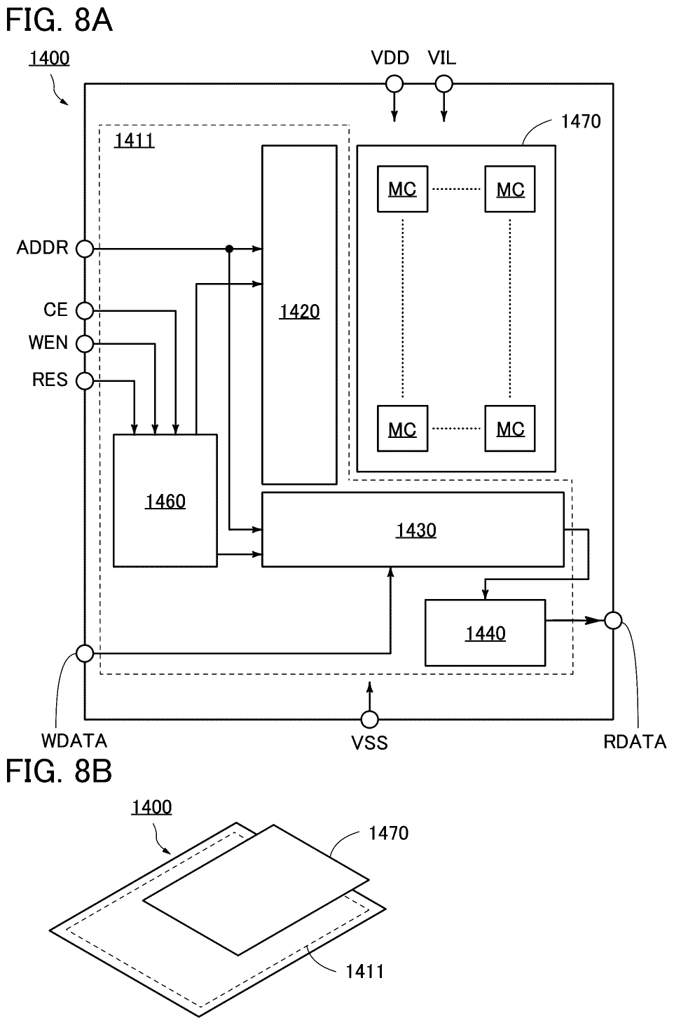

In this embodiment, a memory device of one embodiment of the present invention that includes an OS transistor and a capacitor (hereinafter, such a memory device is sometimes referred to as an OS memory device) will be described with reference to FIGS. 8A and 8B, FIGS. 9A to 9I, FIG. 10, and FIG. 11. The OS memory device includes at least a capacitor and an OS transistor that controls the charging and discharging of the capacitor. Since the OS transistor has an extremely low off-state current, the OS memory device has excellent retention characteristics and can function as a nonvolatile memory.

### <Structure Example of Memory Device>

FIG. 8A illustrates a structure example of an OS memory device. A memory device 1400 includes a peripheral circuit 1411 and a memory cell array 1470. The peripheral circuit 1411 includes a row circuit 1420, a column circuit 1430, an output circuit 1440, and a control logic circuit 1460.

The column circuit 1430 includes a column decoder, a precharge circuit, a sense amplifier, and a write circuit, for example. The precharge circuit has a function of precharging wirings. The sense amplifier has a function of amplifying a data signal read from a memory cell. The wirings mentioned above are connected to memory cells included in the memory cell array 1470, which will be described later in detail. The amplified data signal is output as a data signal RDATA to the outside of the memory device 1400 through the output circuit 1440. The row circuit 1420 includes a row decoder and a word line driver circuit, for example, and can select a row to be accessed.

As power supply voltages from the outside, a low power supply voltage (VSS), a high power supply voltage (VDD) for the peripheral circuit 1411, and a high power supply voltage (VIL) for the memory cell array 1470 are supplied to the memory device 1400. Control signals (CE, WEN, and RES), an address signal ADDR, and a data signal WDATA are also input to the memory device 1400 from the outside. The address signal ADDR is input to the row decoder and the column decoder, and the data signal WDATA is input to the write circuit.

The control logic circuit 1460 processes the control signals (CE, WEN, and RES) input from the outside, and generates control signals for the row decoder and the column decoder. The control signal CE is a chip enable signal, the control signal WEN is a write enable signal, and the control signal RES is a read enable signal. Signals processed by the control logic circuit 1460 are not limited thereto and other control signals can be input as necessary.

The memory cell array 1470 includes a plurality of memory cells MC arranged in a matrix and a plurality of wirings. The number of wirings that connect the memory cell array 1470 and the row circuit 1420 depends on the configuration of the memory cell MC, the number of memory cells MC in one column, and the like. The number of wirings that connect the memory cell array 1470 and the column circuit 1430 depends on the configuration of the memory cell MC, the number of memory cells MC in one row, and the like.

FIG. 8A illustrates an example in which the peripheral circuit 1411 and the memory cell array 1470 are formed on the same plane; however, this embodiment is not limited thereto. For example, as illustrated in FIG. 8B, the memory cell array 1470 may be provided over the peripheral circuit 1411 to partly overlap with the peripheral circuit 1411. For example, the sense amplifier may be provided below the memory cell array 1470 such that they overlap with each other. The OS transistor can be formed in a back end of line (BEOL) process for forming a wiring of a memory device. Thus, in the case where the OS transistor is used in the memory cell array 1470 and a transistor containing silicon in its channel formation region (hereinafter, sometimes referred to as a Si transistor) is used in the peripheral circuit 1411 that is below and overlaps with the memory cell array 1470, a technique by which the OS transistor is formed directly above the Si transistor (such a technique is referred to as a BEOL-Tr technique) can be employed.

A plurality of the memory cell arrays 1470 may be stacked. By stacking the plurality of memory cell arrays 1470, the memory cells can be integrated without an increase in the area occupied by the memory cell arrays 1470. That is, a 3D cell array can be formed. A high integration of memory cells is thus possible and a semiconductor device with high storage capacity can be provided. Note that layers including the OS transistors can be monolithically stacked and are thus suitable.

Note that the configurations of the peripheral circuit 1411, the memory cell array 1470, and the like described in this embodiment are not limited to those described above. The arrangement and functions of these circuits and the wirings, circuit components, and the like connected to the circuits can be changed, removed, or added as needed. The memory device of one embodiment of the present invention operates fast and can retain data for a long time.

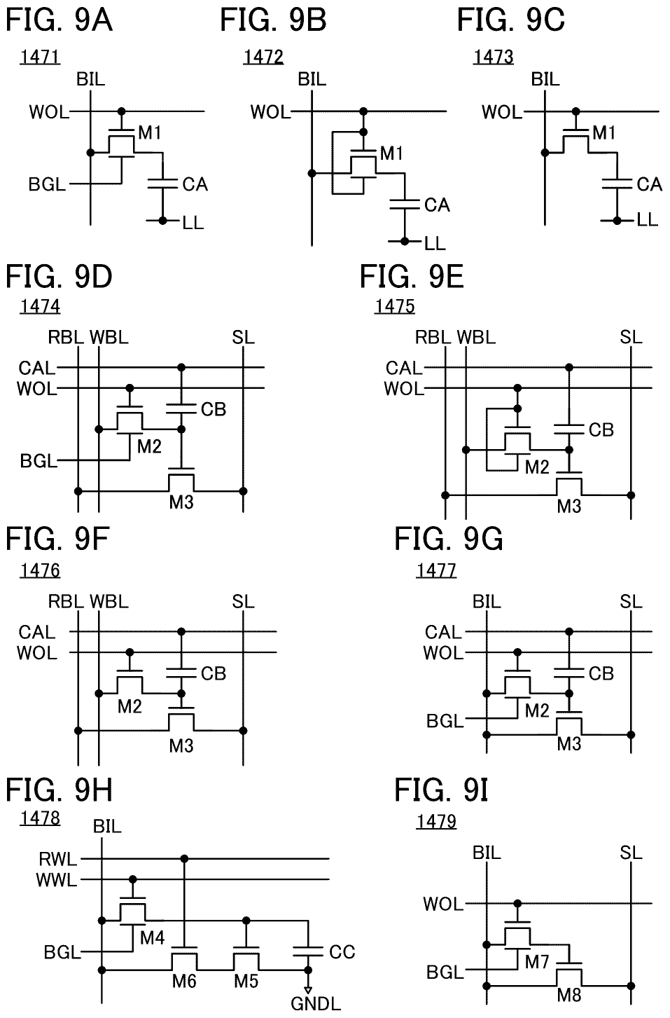

FIGS. 9A to 9I illustrate configuration examples of memory cells that can be used as the memory cell MC.

### [DOSRAM]

FIGS. 9A to 9C each illustrate a circuit configuration example of a memory cell of a DRAM. In this specification and the like, a DRAM using a memory cell including one OS transistor and one capacitor is sometimes referred to as a dynamic oxide semiconductor random access memory (DOSRAM (registered trademark)). A memory cell 1471 illustrated in FIG. 9A includes a transistor M1 and a capacitor CA. The transistor M1 includes a gate (sometimes referred to as a top gate) and a back gate.

A first terminal of the transistor M1 is connected to a first terminal of the capacitor CA. A second terminal of the transistor M1 is connected to a wiring BIL. The gate of the transistor M1 is connected to a wiring WOL. The back gate of the transistor M1 is connected to a wiring BGL. A second terminal of the capacitor CA is connected to a wiring LL.

The wiring BIL functions as a bit line, and the wiring WOL functions as a word line. The wiring LL functions as a wiring for applying a predetermined potential to the second terminal of the capacitor CA. In data writing and data reading, the wiring LL may be set at a ground potential or a low-level potential. The wiring BGL functions as a wiring for applying a potential to the back gate of the transistor M1. The threshold voltage of the transistor M1 can be increased or decreased by applying a given potential to the wiring BGL.

The memory cell MC is not limited to the memory cell 1471 and can have a different circuit configuration. For example, in the memory cell MC, the back gate of the transistor M1 may be connected to the wiring WOL instead of the wiring BGL as in a memory cell 1472 illustrated in FIG. 9B. As another example of the memory cell MC, the transistor M1 may be a single-gate transistor, that is, a transistor without a back gate as in a memory cell 1473 illustrated in FIG. 9C.

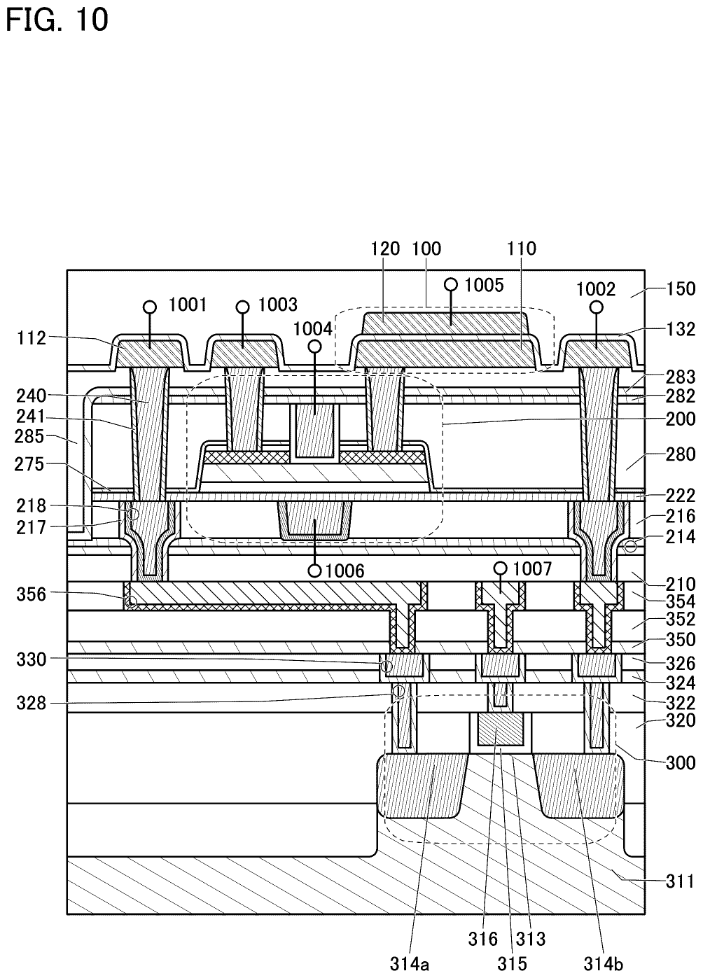

FIG. 10 illustrates a structure example of a memory device including a DOSRAM. In the memory device illustrated in FIG. 10, the transistor 200 is provided above a transistor 300, and the capacitor 100 is provided above the transistors 300 and 200. The transistor 200 and the capacitor 100 described in the above embodiment can be respectively used as the transistor 200 and the capacitor 100.

When the memory device illustrated in FIG. 10 is used in the memory cell 1471, the transistor 200 can be used as the transistor M1 and the capacitor 100 can be used as the capacitor CA. When an OS transistor is used as the transistor M1, the off-state current of the transistor M1 can be extremely low. That is, with the use of the transistor M1, written data can be retained for a long time, and thus the frequency of refresh operation for the memory cell can be decreased. Alternatively, refresh operation for the memory cell can be omitted. In addition, since the transistor M1 has an extremely low off-state current, multi-level data or analog data can be retained in the memory cell 1471. The same applies to the memory cells 1472 and 1473.

In the DOSRAM, when the sense amplifier is provided below the memory cell array 1470 such that they overlap with each other as described above, the bit line can be shortened. This can reduce bit line capacitance, which enables high-speed driving of the memory device.

In the memory device illustrated in FIG. 10, a wiring 1001 is electrically connected to a source of the transistor 300. A wiring 1002 is electrically connected to a drain of the transistor 300. A wiring 1007 is electrically connected to a gate of the transistor 300. A wiring 1003 is electrically connected to one of the source and the drain of the transistor 200. A wiring 1004 is electrically connected to the first gate of the transistor 200. A wiring 1006 is electrically connected to the second gate of the transistor 200. The other of the source and the drain of the transistor 200 is electrically connected to one electrode of the capacitor 100. A wiring 1005 is electrically connected to the other electrode of the capacitor 100.

### <Transistor 300>

The transistor 300 is provided in and on a substrate 311 and includes a conductive layer 316 functioning as a gate, an insulating layer 315 functioning as a gate insulating layer, a semiconductor region 313 that is a part of the substrate 311, and a low-resistance region 314a and a low-resistance region 314b functioning as a source region and a drain region. The transistor 300 may be either a p-channel transistor or an n-channel transistor.

In the transistor 300 illustrated in FIG. 10, the semiconductor region 313 (part of the substrate 311) in which a channel is formed has a projecting portion. The conductive layer 316 is provided to cover the top and side surfaces of the semiconductor region 313 with the insulating layer 315 positioned therebetween. Note that the conductive layer 316 may be formed using a material for adjusting the work function. The transistor 300 having such a structure is also referred to as a FIN transistor because the projecting portion of the semiconductor substrate is utilized. An insulator functioning as a mask for forming the projecting portion may be provided in contact with the top surface of the projecting portion. Although the case where the projecting portion is formed by processing part of the semiconductor substrate is described here, a semiconductor film having a projecting shape may be formed by processing an SOI substrate.

Note that the transistor 300 illustrated in FIG. 10 is just an example and is not limited to the structure illustrated therein; an appropriate transistor may be used in accordance with a circuit configuration or a driving method.

### <Wiring Layer>

Wiring layers provided with an interlayer film, a wiring, a plug, and the like may be provided between the components. A plurality of wiring layers can be provided in accordance with the design. Here, a plurality of conductors functioning as plugs or wirings are collectively denoted by the same reference numeral in some cases. Furthermore, in this specification and the like, a wiring and a plug electrically connected to the wiring may be a single component. That is, part of a conductor functions as a wiring in some cases, and part of a conductor functions as a plug in other cases.

For example, an insulating layer 320, an insulating layer 322, an insulating layer 324, and an insulating layer 326 are stacked over the transistor 300 in this order as interlayer films. A conductive layer 328 is embedded in the insulating layers 320 and 322, and a conductive layer 330 is embedded in the insulating layers 324 and 326. Note that the conductive layers 328 and 330 each function as a plug or a wiring.

The insulator functioning as an interlayer film may function as a planarization film that covers a roughness thereunder. For example, the top surface of the insulating layer 322 may be planarized by planarization treatment using a CMP method or the like to increase the level of planarity.

A wiring layer may be provided over the insulating layer 326 and the conductive layer 330. For example, in FIG. 10, an insulating layer 350, an insulating layer 352, and an insulating layer 354 are stacked in this order. Furthermore, a conductive layer 356 is formed in the insulating layers 350, 352, and 354. The conductive layer 356 functions as a plug or a wiring.

Similarly, a conductive layer 218 and a conductor forming the transistor 200 are embedded in an insulating layer 210, the insulating layer 214, and the insulating layer 216. The conductive layer 218 functions as a plug or a wiring that is electrically connected to the transistor 300.

Here, like the insulating layers 241a and 241b described in the above embodiment, an insulating layer 217 is provided in contact with the side surface of the conductive layer 218. The insulating layer 217 is provided in contact with the inner wall of the opening portion formed in the insulating layers 210, 214, and 216. That is, the insulating layer 217 is provided between the conductive layer 218 and the insulating layers 210, 214, and 216. Note that the conductive layers 215 and 218 can be formed in parallel; thus, the insulating layer 217 is sometimes formed in contact with the side surface of the conductive layer 215.

As the insulating layer 217, any of the insulating layers that can be used as the insulating layers 241a and 241b is used, for example. The insulating layer 217 is provided in contact with the insulating layers 210, 214, and 222; thus, impurities contained in the insulating layer 210, the insulating layer 216, or the like can be inhibited from entering the oxide semiconductor layer 230 through the conductive layer 218. Silicon nitride is particularly preferable because of its high barrier property against hydrogen. Furthermore, oxygen contained in the insulating layer 210 or the insulating layer 216 can be inhibited from being absorbed by the conductive layer 218.

The insulating layer 217 can be formed by a method similar to the method for forming the insulating layers 241a and 241b. For example, silicon nitride can be deposited by a PEALD method and an opening portion reaching the conductive layer 356 can be formed by anisotropic etching.

Any of the insulating layers that can be used as the insulating layer 150 is used as the insulating layers 210, 352, and 354 that function as interlayer films, for example.

When an OS transistor is surrounded by an insulator having a function of inhibiting transmission of oxygen and impurities, the transistor can have stable electrical characteristics. Thus, the insulator having a function of inhibiting transmission of oxygen and impurities that is described above in [Insulating layer] is used as each of the insulating layers 214, 350, and the like.

Any of the conductive layers described above in [Conductive layer] can be used as the conductive layers 328, 330, 356, 218, and 112 that function as plugs or wirings, for example. It is preferable to use a high-melting-point material that has both heat resistance and conductivity, such as tungsten or molybdenum, and it is particularly preferable to use tungsten. Alternatively, a low-resistance conductive material such as aluminum or copper is preferably used. The use of a low-resistance conductive material can reduce wiring resistance.

### <Wiring or Plug in Layer Including Oxide Semiconductor>

As described in the above embodiment, the transistor 200 may be sealed with the insulating layers 214 and 283. Such a structure can inhibit entry of hydrogen contained in the insulating layers 285, 150, and the like into the insulating layer 280 or the like.

The conductive layer 240 penetrates the insulating layer 283 and the conductive layer 218 penetrates the insulating layer 214; however, as illustrated in FIG. 10, the insulating layer 241 is provided in contact with the conductive layer 240 and the insulating layer 217 is provided in contact with the conductive layer 218. The use of a barrier insulating film against hydrogen for each of the insulating layers 241 and 217 can inhibit entry of hydrogen into the insulating layers 214 and 283 through the conductive layers 240 and 218. In this manner, the transistor 200 is sealed with the insulating layers 214, 283, 241, and 217, so that entry of impurities contained in the insulating layer 285 or the like from the outside can be inhibited.

### [NOSRAM]

FIGS. 9D to 9G each illustrate a circuit configuration example of a gain-cell memory cell including two transistors and one capacitor. A memory cell 1474 illustrated in FIG. 9D includes a transistor M2, a transistor M3, and a capacitor CB. The transistor M2 includes a gate and a back gate. In this specification and the like, a memory device including a gain-cell memory cell using an OS transistor as the transistor M2 is sometimes referred to as a nonvolatile oxide semiconductor RAM (NOSRAM (registered trademark)).

A first terminal of the transistor M2 is connected to a first terminal of the capacitor CB. A second terminal of the transistor M2 is connected to a wiring WBL. The gate of the transistor M2 is connected to the wiring WOL. The back gate of the transistor M2 is connected to the wiring BGL. A second terminal of the capacitor CB is connected to a wiring CAL. A first terminal of the transistor M3 is connected to a wiring RBL. A second terminal of the transistor M3 is connected to a wiring SL. A gate of the transistor M3 is connected to the first terminal of the capacitor CB.

The wiring WBL functions as a write bit line, the wiring RBL functions as a read bit line, and the wiring WOL functions as a word line. The wiring CAL functions as a wiring for applying a predetermined potential to the second terminal of the capacitor CB. A high-level potential is preferably applied to the wiring CAL at the time of data writing and data reading. In the data retention, a low-level potential is preferably applied to the wiring CAL. The wiring BGL functions as a wiring for applying a potential to the back gate of the transistor M2. The threshold voltage of the transistor M2 can be increased or decreased by applying a given potential to the wiring BGL.

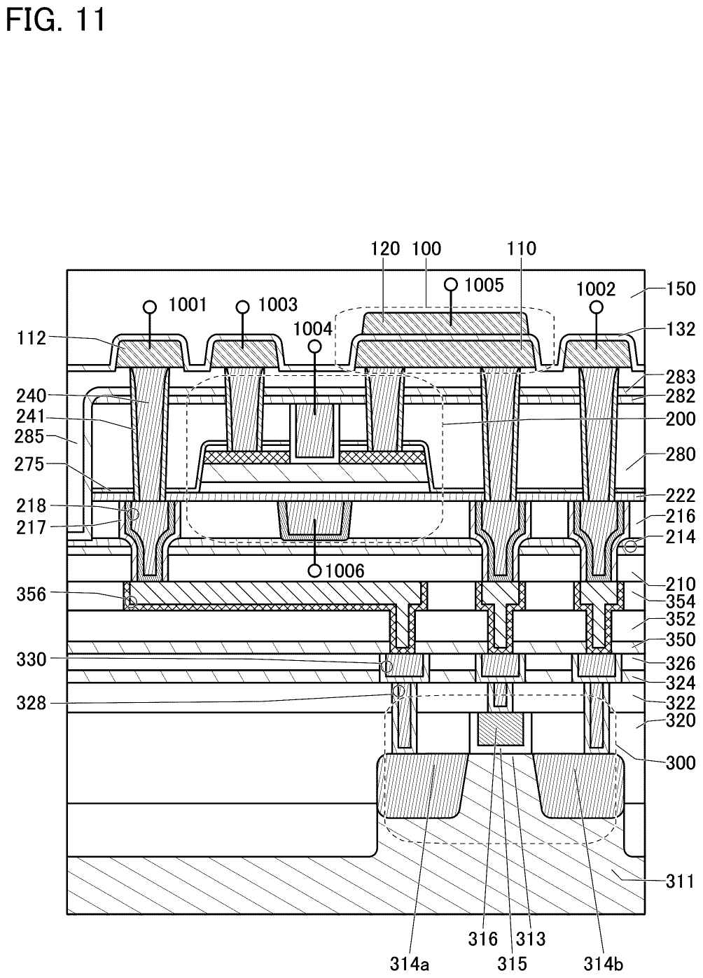

FIG. 11 illustrates an example of a memory device including a NOSRAM. Note that in the memory device described below, components having the same functions as those in the memory device illustrated in FIG. 10 are denoted by the same reference numerals. Differences from the above-described memory device will be mainly described below, and the description of portions similar to those described above is omitted.

FIG. 11 is a cross-sectional view of a memory device. The memory device illustrated in FIG. 11 is different from the memory device illustrated in FIG. 10 in that the wiring 1007 is not provided and the gate of the transistor 300 is electrically connected to the other of the source and the drain of the transistor 200 and the one electrode of the capacitor 100.

In the memory device illustrated in FIG. 11, the gate of the transistor 300 and the other of the source and the drain of the transistor 200 are electrically connected to the one electrode of the capacitor 100. The conductive layer 316 is electrically connected to the capacitor 100 or the transistor 200 through the conductive layers 328, 330, 356, 218, and 240.

In the case where the memory device illustrated in FIG. 11 is used in the memory cell 1474 and the like, the transistor 200 can be used as the transistor M2, the transistor 300 can be used as the transistor M3, and the capacitor 100 can be used as the capacitor CB. The wiring 1003, the wiring 1004, the wiring 1006, the wiring 1005, the wiring 1002, and the wiring 1001 can be used as the wiring WBL, the wiring WOL, the wiring BGL, the wiring CAL, the wiring RBL, and the wiring SL, respectively.

The memory cell MC is not limited to the memory cell 1474, and the circuit configuration can be changed as appropriate. For example, as in a memory cell 1475 illustrated in FIG. 9E, the back gate of the transistor M2 may be connected not to the wiring BGL but to the wiring WOL in the memory cell MC. Alternatively, for example, the transistor M2 may be a single-gate transistor, that is, a transistor without a back gate in the memory cell MC as in a memory cell 1476 illustrated in FIG. 9F. Alternatively, for example, the memory cell MC may have a structure in which the wirings WBL and RBL are combined into one wiring BIL as in a memory cell 1477 illustrated in FIG. 9G.

When an OS transistor is used as the transistor M2, the off-state current of the transistor M2 can be extremely low. Thus, with the use of the transistor M2, written data can be retained for a long time, and thus the frequency of refresh operation for the memory cell can be decreased. Alternatively, refresh operation for the memory cell can be omitted. In addition, since the transistor M2 has an extremely low off-state current, multi-level data or analog data can be retained in the memory cell 1474. The same applies to the memory cells 1475 to 1477.

Note that the transistor M3 may be a Si transistor. The Si transistor may be either an n-channel transistor or a p-channel transistor. The Si transistor has higher field-effect mobility than the OS transistor in some cases. Thus, the Si transistor may be used as the transistor M3 functioning as a read transistor. Furthermore, the transistor M2 can be formed over the transistor M3 when the Si transistor is used as the transistor M3, in which case the area occupied by the memory cell can be reduced, leading to high integration of the memory device.

Alternatively, the transistor M3 may be an OS transistor. When an OS transistor is used as each of the transistors M2 and M3, the memory cell array 1470 can be formed using only n-channel transistors.

FIG. 9H illustrates an example of a gain-cell memory cell including three transistors and one capacitor. A memory cell 1478 illustrated in FIG. 9H includes transistors M4 to M6 and a capacitor CC. The capacitor CC is provided as appropriate. The memory cell 1478 is electrically connected to the wiring BIL, a wiring RWL, a wiring WWL, the wiring BGL, and a wiring GNDL. The wiring GNDL is a wiring for supplying a low-level potential. Note that the memory cell 1478 may be electrically connected to the wirings RBL and WBL instead of the wiring BIL.

The transistor M4 is an OS transistor with a back gate that is electrically connected to the wiring BGL. Note that the back gate and the gate of the transistor M4 may be electrically connected to each other. Alternatively, the transistor M4 does not necessarily include the back gate.

Note that each of the transistors M5 and M6 may be either an n-channel Si transistor or a p-channel Si transistor. Alternatively, the transistors M4 to M6 may be OS transistors. In that case, the circuit of the memory cell array 1470 can be formed using only n-channel transistors.

When the semiconductor device described in the above embodiment is used in the memory cell 1478, the transistor 200 can be used as the transistor M4, the transistor 300 can be used as each of the transistors M5 and M6, and the capacitor 100 can be used as the capacitor CC. When an OS transistor is used as the transistor M4, the off-state current of the transistor M4 can be extremely low.

FIG. 9I illustrates an example of a gain-cell memory cell including two transistors. A memory cell 1479 illustrated in FIG. 9I includes a transistor M7 and a transistor M8. The memory cell 1479 is electrically connected to the wirings BIL, WWL, BGL, and SL.

The transistor M7 is an OS transistor with a back gate that is electrically connected to the wiring BGL. Note that the back gate and the gate of the transistor M7 may be electrically connected to each other. Alternatively, the transistor M7 does not necessarily include the back gate.

In the memory cell 1479 illustrated in FIG. 9I, the gate capacitance of the transistor M8 is used as storage capacitance. That is, the memory cell 1479 can be regarded as a capacitor-less memory cell. The memory cell 1479 corresponds to the memory cell 1477 illustrated in FIG. 9G from which the capacitor CB is omitted, and can be regarded as a gain-cell memory cell with two transistors and no capacitor.

When the OS transistor is used as the transistor M7 and the transistor M7 is turned off, charge at a node where one of a source electrode and a drain electrode of the transistor M7 is electrically connected to a gate electrode of the transistor M8 can be retained for an extremely long time. Thus, a nonvolatile memory cell can be obtained.

The transistor M8 may be either an n-channel Si transistor or a p-channel Si transistor.

In the case where the semiconductor device described in the above embodiment is used in the memory cell 1479, the transistor 200 can be used as the transistor M7 and the transistor 300 can be used as the transistor M8.

Alternatively, the transistor M8 may be an OS transistor. In that case, the circuit of the memory cell array 1470 can be formed using only n-channel transistors.

When the semiconductor device described in the above embodiment is used in the memory cell 1479, the transistor 200 can be used as each of the transistors M7 and M8. With this structure, the transistors M7 and M8 can be formed in the same layer. This structure can simplify a step of stacking layers each including the memory cell 1479 and improve the productivity as compared with a structure in which the transistors M7 and M8 are formed in different layers.

In the case where the transistor 200 is used as each of the transistors M7 and M8, the design matters (including a channel length, a channel width, a cross-sectional shape, and the like) of the transistor can be determined as appropriate in accordance with the characteristics required for the transistors M7 and M8.

There is no particular limitation on the structures of the transistors M1 to M8, regardless of the semiconductor materials used for the transistors M1 to M8. For example, a planar transistor, a staggered transistor, an inverted staggered transistor, or a vertical-channel transistor can be used. Either a top-gate transistor or a bottom-gate transistor may be used. Gates may be provided above and below a semiconductor layer where a channel is formed.

As described above, the plurality of memory cell arrays 1470 may be stacked. By stacking the plurality of memory cell arrays 1470, the memory cells can be integrated without an increase in the area occupied by the memory cell arrays 1470. That is, a 3D cell array can be formed.

The structures, methods, and the like described in this embodiment can be combined as appropriate with any of the other structures, methods, and the like described in this embodiment or any of the structures, methods, and the like described in the other embodiments.

### Embodiment 3

In this embodiment, an OS transistor will be described. In the description of the OS transistor, comparison with the Si transistor will also be briefly described.

An oxide semiconductor having a low carrier concentration is preferably used for the OS transistor. For example, the carrier concentration in a channel formation region of an oxide semiconductor is lower than or equal to 1×10¹⁸ cm⁻³, preferably lower than 1×10¹⁷ cm⁻³, further preferably lower than 1×10¹⁶ cm⁻³, still further preferably lower than 1×10¹³ cm⁻³, yet further preferably lower than 1×10¹⁰ cm⁻³, and higher than or equal to 1×10⁻⁹ cm⁻³. In order to reduce the carrier concentration of an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor has a low density of defect states and accordingly has a low density of trap states in some cases. Charge trapped by the trap states in the oxide semiconductor takes a long time to disappear and might behave like fixed charge. Thus, a transistor whose channel formation region is formed in an oxide semiconductor having a high density of trap states has unstable electrical characteristics in some cases.

Accordingly, in order to obtain stable electrical characteristics of the transistor, reducing the impurity concentration in the oxide semiconductor is effective. In order to reduce the impurity concentration in the oxide semiconductor, the impurity concentration in a film that is adjacent to the oxide semiconductor is preferably reduced. Examples of the impurity include hydrogen and nitrogen. Note that an impurity in an oxide semiconductor refers to, for example, elements other than the main components of the oxide semiconductor. For example, an element with a concentration lower than 0.1 atomic % is regarded as an impurity.

The band gap of the oxide semiconductor is preferably wider than the band gap of silicon (typically 1.1 eV), further preferably greater than or equal to 2 eV, still further preferably greater than or equal to 2.5 eV, yet still further preferably greater than or equal to 3.0 eV. With the use of an oxide semiconductor having a wider band gap than silicon, the off-state current (also referred to as Ioff) of the transistor can be reduced.

In a Si transistor, a short-channel effect (also referred to as SCE) appears as scaling down of the transistor proceeds. Thus, it is difficult to scale down the Si transistor. One factor in causing the short-channel effect is a narrow band gap of silicon. By contrast, the OS transistor includes an oxide semiconductor that is a semiconductor material having a wide band gap, and thus can suppress the short-channel effect. In other words, the short-channel effect does not appear or hardly appears in the OS transistor.

The short-channel effect refers to degradation of electrical characteristics that becomes obvious along with scaling down (a decrease in channel length) of a transistor. Specific examples of the short-channel effect include a decrease in threshold voltage, an increase in subthreshold swing (sometimes referred to as S value), and an increase in leakage current. Here, the S value refers to the amount of change in gate voltage in a subthreshold region, which is required for changing drain current by one digit at a constant drain voltage.

The characteristic length is widely used as an indicator of resistance to a short-channel effect. The characteristic length is an indicator of curving of potential in a channel formation region. As the characteristic length is shorter, the potential rises more sharply, which means that the resistance to a short-channel effect is high.

The OS transistor is an accumulation-type transistor and the Si transistor is an inversion-type transistor. Thus, the OS transistor has a shorter characteristic length between the channel formation region and each of the source region and the drain region than the Si transistor. Accordingly, the OS transistor has higher resistance to a short-channel effect than the Si transistor. That is, the OS transistor is more suitable than the Si transistor in the case where a short-channel transistor is to be formed.

Even in the case where the carrier concentration in the oxide semiconductor is reduced until the channel formation region becomes an i-type or substantially i-type region, the conduction band minimum of the channel formation region in a short-channel transistor decreases because of the conduction band lowering (CBL) effect; thus, there is a possibility that a difference in energy of the conduction band minimum between the channel formation region and the source region or the drain region is as small as 0.1 eV or more and 0.2 eV or less. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source region and the drain region become n⁺-type regions in the OS transistor.

The above-described structure enables the OS transistor to have excellent electrical characteristics even when the OS transistors are scaled down or highly integrated. For example, excellent electrical characteristics can be obtained even when the gate length of the OS transistor is less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of a short-channel effect. Thus, the OS transistor can be more suitably used as a short-channel transistor than the Si transistor. Note that the gate length refers to a length of a gate electrode in the direction in which carriers flow through a channel formation region when a transistor operates.

Scaling down of the OS transistor can improve the frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz at room temperature, for example.

The above comparison of the OS transistor with the Si transistor demonstrates that the OS transistor is advantageous over the Si transistor in that the off-state current is low and a short-channel transistor can be formed.

The configurations, structures, methods, and the like described in this embodiment can be used in an appropriate combination with any of the configurations, structures, methods, and the like described in the other embodiments and the like.

### Embodiment 4

In this embodiment, electronic components, electronic devices, a large computer, space equipment, and a data center (also referred to as DC) in which the semiconductor device described in the above embodiment can be used will be described. Electronic components, electronic devices, a large computer, space equipment, and a data center in which the semiconductor device of one embodiment of the present invention is used are effective in improving performance, e.g., reducing power consumption.

### [Electronic Component]

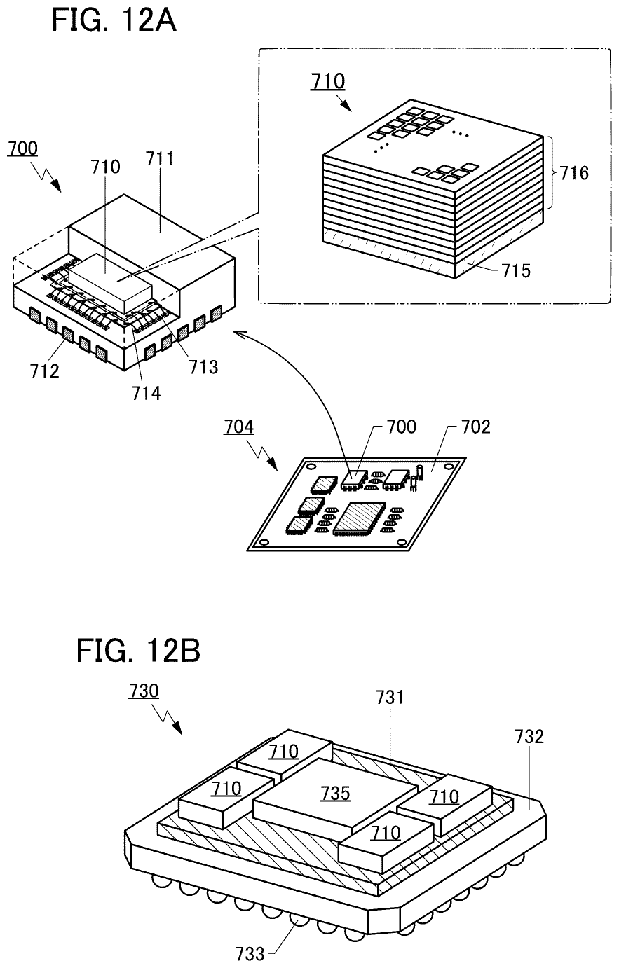

FIG. 12A is a perspective view of a substrate (a circuit board 704) on which an electronic component 700 is mounted. The electronic component 700 illustrated in FIG. 12A includes a semiconductor device 710 in a mold 711. Some components are omitted in FIG. 12A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. Note that the memory layer 716 may include one layer including one or more memory cell arrays. A stacked-layer structure of the driver circuit layer 715 and the memory layer 716 can be a monolithic stacked-layer structure. In the monolithic stacked-layer structure, layers can be connected to each other without using a through electrode technique such as a through silicon via (TSV) technique and a bonding technique such as Cu-to-Cu direct bonding. When the driver circuit layer 715 and the memory layer 716 are monolithically stacked, for example, a structure in which a memory is directly formed on a processor, what is called an on-chip memory structure, can be obtained. The on-chip memory structure allows an interface portion between the processor and the memory to operate at high speed.

With the on-chip memory structure, the sizes of a connection wiring and the like can be smaller than those in the case where the through electrode technique such as TSV is employed; thus, the number of connection pins can be increased. An increase in the number of connection pins enables parallel operations, which can increase a memory bandwidth.

It is preferable that the plurality of memory cell arrays included in the memory layer 716 be formed using the OS transistors and be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using the Si transistors, it is difficult to obtain the monolithic stacked-layer structure as compared with the case where the memory layer 716 is formed using the OS transistors. Thus, the OS transistor is superior to the Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the formation process of a semiconductor chip, for example. Examples of a semiconductor material that can be used for a die include silicon (Si), silicon carbide (SiC), and gallium nitride (GaN). A die obtained from a silicon substrate (also referred to as a silicon wafer) may be referred to as a silicon die, for example.

FIG. 12B is a perspective view of an electronic component 730. The electronic component 730 is an example of a system in package (SiP) or a multi-chip module (MCM). In the electronic component 730, an interposer 731 is provided over a package substrate 732 (printed circuit board), and a semiconductor device 735 and a plurality of the semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU, a GPU, or a field programmable gate array (FPGA).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. Moreover, in the case of using a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, or the like using a silicon interposer, a decrease in reliability due to a difference in the coefficient of expansion between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, TSV, and the like, a space for the width of the terminal pitches and the like is needed. Thus, in the case where the size of the electronic component 730 is to be reduced, the width of the terminal pitches causes a problem, which sometimes makes it difficult to provide a large number of wirings for a wide memory bandwidth. For this reason, the monolithic stacked-layer structure using the OS transistors is suitable. A composite structure combining memory cell arrays stacked using TSV and monolithically stacked memory cell arrays may be employed.

In addition, a heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 12B illustrates an example in which the electrode 733 is formed of a solder ball. Solder balls are provided in a matrix on the bottom portion of the package substrate 732, so that ball grid array (BGA) mounting can be achieved. Alternatively, the electrode 733 may be formed of a conductive pin. When conductive pins are provided in a matrix on the bottom portion of the package substrate 732, pin grid array (PGA) mounting can be achieved.

The electronic component 730 can be mounted on another substrate by various mounting methods other than BGA and PGA. Examples of a mounting method include a staggered pin grid array (SPGA), a land grid array (LGA), a quad flat package (QFP), a quad flat J-leaded package (QFJ), and a quad flat non-leaded package (QFN).

### [Electronic Device]

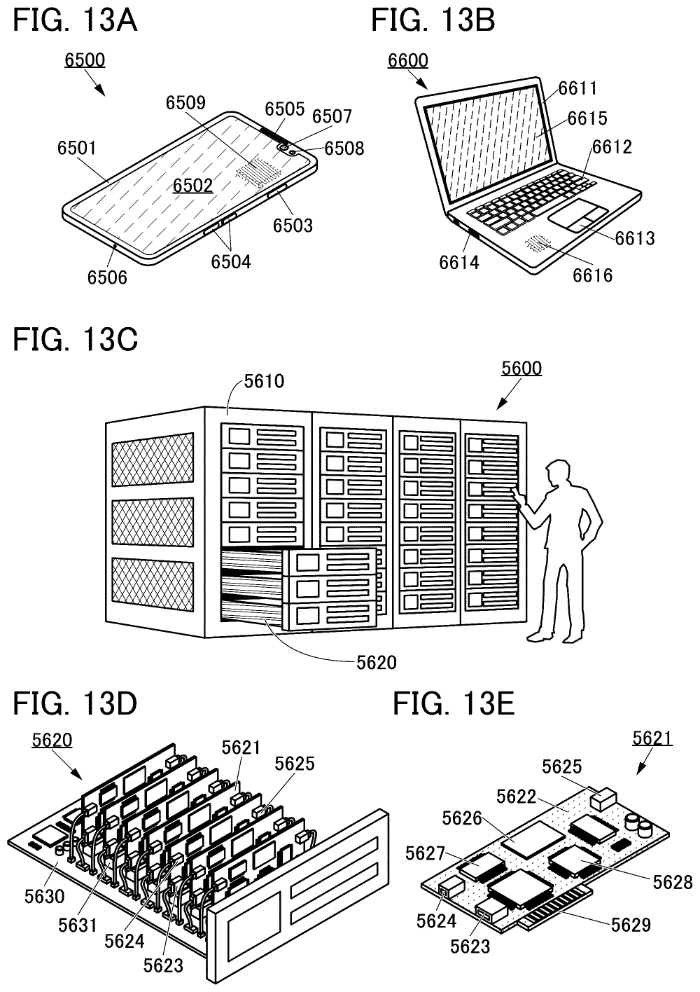

FIG. 13A is a perspective view of an electronic device 6500. The electronic device 6500 illustrated in FIG. 13A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are used as the control device 6509, for example. The semiconductor device of one embodiment of the present invention can be used for the display portion 6502, the control device 6509, and the like.

An electronic device 6600 illustrated in FIG. 13B is an information terminal that can be used as a laptop computer. The electronic device 6600 includes a housing 6611, a keyboard 6612, a pointing device 6613, an external connection port 6614, a display portion 6615, a control device 6616, and the like. One or more selected from a CPU, a GPU, and a memory device are used as the control device 6616, for example. The semiconductor device of one embodiment of the present invention can be used for the display portion 6615, the control device 6616, and the like. Note that the semiconductor device of one embodiment of the present invention is preferably used for the control devices 6509 and 6616, in which case power consumption can be reduced.

### [Large Computer]

FIG. 13C is a perspective view of a large computer 5600. In the large computer 5600 illustrated in FIG. 13C, a plurality of rack mount computers 5620 are stored in a rack 5610. Note that the large computer 5600 may be referred to as a supercomputer.

The computer 5620 can have a structure in a perspective view of FIG. 13D, for example. In FIG. 13D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 13E is an example of a processing board provided with a CPU, a GPU, a memory device, and the like. The PC card 5621 includes a board 5622. The board 5622 includes the connection terminals 5623, 5624, and 5625, a semiconductor device 5626, a semiconductor device 5627, a semiconductor device 5628, and a connection terminal 5629. Although FIG. 13E also illustrates semiconductor devices other than the semiconductor devices 5626, 5627, and 5628, the following description of the semiconductor devices 5626, 5627, and 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCI Express (registered trademark).

The connection terminals 5623, 5624, and 5625 can serve as, for example, an interface for performing power supply, signal input, or the like to the PC card 5621. For another example, they can serve as an interface for outputting a signal calculated by the PC card 5621. Examples of the standard for each of the connection terminals 5623, 5624, and 5625 include Universal Serial Bus (USB), Serial ATA (SATA), and Small Computer System Interface (SCSI). In the case where video signals are output from the connection terminals 5623, 5624, and 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used even in an environment where radiation can enter. For example, the OS transistor can be suitably used in outer space.

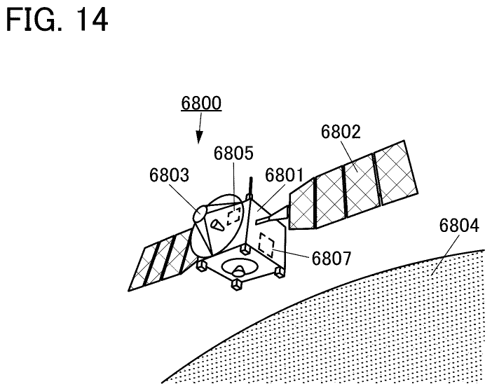

FIG. 14 illustrates an artificial satellite 6800 as an example of space equipment. The artificial satellite 6800 includes a body 6801, a solar panel 6802, an antenna 6803, a secondary battery 6805, and a control device 6807. FIG. 14 illustrates a planet 6804 in outer space, for example. Note that outer space refers to, for example, space at an altitude greater than or equal to 100 km, and outer space in this specification can also include thermosphere, mesosphere, and stratosphere.

Although not illustrated in FIG. 14, a battery management system (also referred to as BMS) or a battery control circuit may be provided in the secondary battery 6805. The OS transistor is preferably used in the battery management system or the battery control circuit because of its low power consumption and high reliability even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is irradiated with sunlight, electric power required for operation of the artificial satellite 6800 is generated. However, for example, in the situation where the solar panel is not irradiated with sunlight or the amount of sunlight with which the solar panel is irradiated is small, the amount of generated electric power is small. Accordingly, a sufficient amount of electric power required for operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and can be received by a ground-based receiver or another artificial satellite, for example. When the signal transmitted by the artificial satellite 6800 is received, the position of a receiver that receives the signal can be measured. Thus, the artificial satellite 6800 can construct a satellite positioning system.

The control device 6807 has a function of controlling the artificial satellite 6800. One or more selected from a CPU, a GPU, and a memory device are used as the control device 6807, for example. Note that the OS transistor of one embodiment of the present invention is preferably used for the control device 6807. A change in electrical characteristics of the OS transistor due to radiation irradiation is smaller than a change in electrical characteristics of a Si transistor. That is, the OS transistor has high reliability even in an environment where radiation can enter; thus, the OS transistor can be suitably used in such an environment.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. The semiconductor device of one embodiment of the present invention can be suitably used for space equipment such as a spacecraft, a space capsule, or a space probe, for example.

As described above, the OS transistor has advantageous effects over the Si transistor, such as a wide memory bandwidth and high radiation resistance.

### [Data Center]

The semiconductor device of one embodiment of the present invention can be suitably used for a storage system in a data center, for example. Long-term management of data, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, and the like.

With the use of the semiconductor device of one embodiment of the present invention for the storage system in the data center, electric power required for data retention and the size of a semiconductor device retaining data can be reduced. Thus, the size of the storage system, the amount of electric power for data retention, the size of the cooling equipment, and the like can be reduced. This can reduce the scale of the data center.

Since the semiconductor device of one embodiment of the present invention has low power consumption, heat generation from a circuit can be reduced. Accordingly, adverse effects of the heat generation on the circuit itself, the peripheral circuit, and the module can be reduced. Furthermore, the use of the semiconductor device of one embodiment of the present invention can achieve a data center that operates stably even in a high temperature environment. Thus, the reliability of the data center can be increased.

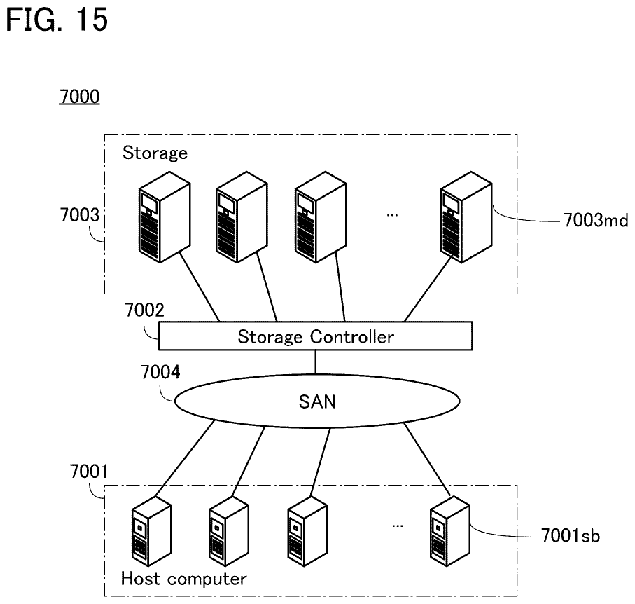

FIG. 15 illustrates a storage system that can be used in a data center. A storage system 7000 illustrated in FIG. 15 includes a plurality of servers 7001sb as a host 7001 (indicated as “Host Computer” in the diagram). The storage system 7000 includes a plurality of memory devices 7003md as a storage 7003 (indicated as “Storage” in the diagram). In the illustrated example, the host 7001 and the storage 7003 are connected to each other through a storage area network 7004 (indicated as “SAN” in the diagram) and a storage control circuit 7002 (indicated as “Storage Controller” in the diagram).

The host 7001 corresponds to a computer that accesses data stored in the storage 7003. The host 7001 may be connected to another host 7001 through a network.

The data access speed, i.e., the time taken for storing and outputting data, of the storage 7003 is shortened by using a flash memory, but is still considerably longer than the data access speed of a DRAM that can be used as a cache memory in a storage. In the storage system, in order to solve the problem of low access speed of the storage 7003, a cache memory is normally provided in a storage to shorten the time taken for data storage and output.

The above-described cache memory is used in the storage control circuit 7002 and the storage 7003. The data transmitted between the host 7001 and the storage 7003 is stored in the cache memories in the storage control circuit 7002 and the storage 7003 and then output to the host 7001 or the storage 7003.

The use of an OS transistor as a transistor for storing data in the cache memory to retain a potential based on data can reduce the frequency of refreshing, so that power consumption can be reduced. Furthermore, downscaling is possible by stacking memory cell arrays.

The use of the semiconductor device of one embodiment of the present invention for one or more selected from an electronic component, an electronic device, a large computer, space equipment, and a data center will produce an effect of reducing power consumption. Although demand for energy will increase with increasing performance and integration degree of semiconductor devices, the use of the semiconductor device of one embodiment of the present invention can thus reduce the emission amount of greenhouse gas typified by carbon dioxide (CO₂). The semiconductor device of one embodiment of the present invention can be effectively used as one of the global warming countermeasures because of its low power consumption.

The configurations, structures, methods, and the like described in this embodiment can be used in an appropriate combination with any of the configurations, structures, methods, and the like described in the other embodiments and the like.

### Example

In this example, samples containing tantalum nitride were fabricated, and the dependence of tantalum nitride on deposition conditions was evaluated. Specifically, the composition, conductivity, resistivity, and the like of tantalum nitride were obtained. In addition, transistors containing tantalum nitride were fabricated, and the electrical characteristics of the transistors were evaluated. Specifically, the Id-Vg curves of the transistors were obtained. Note that tantalum nitride described in this example can be rephrased as a tantalum compound.

### <Dependence of Tantalum Nitride on Deposition Condition>

In this section, the dependence of tantalum nitride on deposition conditions will be described.

### [Sample Fabrication 1]

In this example, samples 1A to 11A, samples 1B to 11B, samples 1C to 11C, and samples 1D to 11D were fabricated. Hereinafter, the samples 1A to 11A are sometimes collectively referred to as a sample group A. The samples 1B to 11B are sometimes collectively referred to as a sample group B. The samples 1C to 11C are sometimes collectively referred to as a sample group C. The samples 1D to 11D are sometimes collectively referred to as a sample group D.

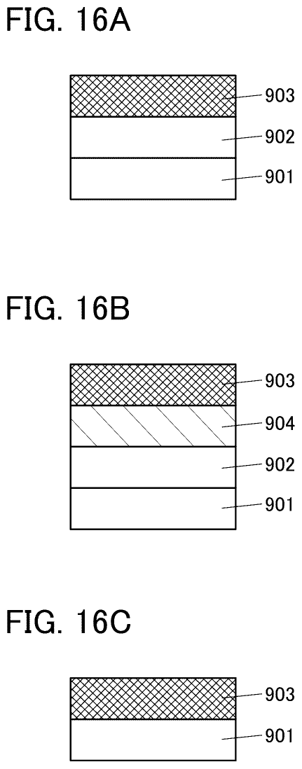

FIG. 16A is a schematic cross-sectional view of each of the sample groups A and B. As illustrated in FIG. 16A, the sample groups A and B each include a layer 901, a layer 902 over the layer 901, and a layer 903 over the layer 902.

FIG. 16B is a schematic cross-sectional view of each of the sample groups C and D. As illustrated in FIG. 16B, the sample groups C and D each include the layer 901, the layer 902 over the layer 901, a layer 904 over the layer 902, and the layer 903 over the layer 904.

First, a method for fabricating the sample group A will be described. The samples of the sample group A were fabricated in the same manner except for the deposition conditions of the layer 903.

First, a silicon substrate was prepared as the layer 901. Next, a 100-nm-thick silicon oxide film was deposited as the layer 902. The silicon oxide film is sometimes referred to as SiO₂.

Then, as the layer 903, a 50-nm-thick tantalum nitride film was deposited by a reactive sputtering method using a tantalum target and a nitrogen (N₂) gas. For each of the samples 1A to 11A, the tantalum nitride film was deposited under the conditions where the target-substrate distance was 286 mm and the substrate temperature was room temperature. The tantalum nitride film is sometimes referred to as SiNx.

The other deposition conditions of the tantalum nitride film are shown in Table 1. In Table 1, “Sample name” represents the name of the sample, “N₂/(N₂+Ar)” represents a nitrogen flow rate ratio, “Plasma power” represents DC power, and “Pressure” represents deposition pressure. Table 1 also shows the XPS analysis results of the tantalum nitride films included in the sample group A. In Table 1, “N/Ta ratio” represents the atomic ratio of nitrogen to tantalum. The details of the XPS analysis will be described later.

TABLE 1

| Sample name | 1A | 2A | 3A | 4A | 5A | 6A | 7A | 8A | 9A | 10A | 11A |
|---|---|---|---|---|---|---|---|---|---|---|---|
| N₂/(N₂ + Ar) [%] | 80% | 60% | 40% | 25% | 25% | 25% | 25% | 25% | 25% | 25% | 25% |
| N₂ flow rate [sccm] | 67 | 52 | 33 | 19 | 19 | 19 | 19 | 19 | 19 | 19 | 19 |
| Ar flow rate [sccm] | 9 | 27 | 42 | 50 | 50 | 50 | 50 | 50 | 50 | 50 | 50 |
| Plasma power [kW] | 0.5 | 0.5 | 0.5 | 0.5 | 0.7 | 1.0 | 1.3 | 1.5 | 1.7 | 2.0 | 4.0 |
| Pressure [Pa] | 0.5 | 0.5 | 0.5 | 0.5 | 0.5 | 0.5 | 0.5 | 0.5 | 0.5 | 0.5 | 0.5 |
| N/Ta ratio | 1.62 | 1.56 | 1.54 | 1.31 | 1.32 | 1.34 | 1.18 | 0.91 | 0.84 | 0.64 | 0.37 |

In this manner, the sample group A was fabricated.

Next, a method for fabricating the sample group B will be described. Note that the steps up to the deposition of the tantalum nitride film in the method for fabricating the sample group B are the same as those in the method for fabricating the sample group A; thus, refer to the above description of the method for fabricating the sample group A for these steps. For the deposition conditions of the tantalum nitride films in the samples 1B to 11B, Table 1 can be referred to by replacing the samples 1A to 11A with the samples 1B to 11B.

After the tantalum nitride film was deposited as the layer 903, heat treatment was performed at 400° C. in a nitrogen atmosphere for one hour.

In this manner, the sample group B was fabricated.

Next, a method for fabricating the sample group C will be described. The sample group C differs from the sample group A in including the layer 904 between the layer 902 and the layer 903. For the methods for forming the layers 901, 902, and 903 in the sample group C, refer to the above description of the method for fabricating the sample group A. For the deposition conditions of the tantalum nitride films in the samples 1C to 11C, Table 1 can be referred to by replacing the samples 1A to 11A with the samples 1C to 11C.

As the layer 904, a 50-nm-thick In—Ga—Zn oxide film was deposited by a sputtering method. Note that the In—Ga—Zn oxide film has a CAAC structure; thus, the In—Ga—Zn oxide film is sometimes referred to as CAAC-IGZO.

In this manner, the sample group C was fabricated.

Next, a method for fabricating the sample group D will be described. Note that the steps up to the deposition of the tantalum nitride film in the method for fabricating the sample group D are the same as those in the method for fabricating the sample group C; thus, refer to the above description of the method for fabricating the sample group C for these steps. For the deposition conditions of the tantalum nitride films in the samples 1D to 11D, Table 1 can be referred to by replacing the samples 1A to 11A with the samples 1D to 11D.

After the tantalum nitride film was deposited as the layer 903, heat treatment was performed at 400° C. in a nitrogen atmosphere for one hour.

In this manner, the sample group D was fabricated.

As described above, since the tantalum nitride films in the samples 1A, 1B, 1C, and 1D were deposited under the same conditions, these samples are sometimes collectively referred to as an index 1. Similarly, the samples 2A, 2B, 2C, and 2D are sometimes collectively referred to as an index 2. The same applies to indexes 3 to 11.

### [Composition]

The tantalum nitride films included in the sample group A were subjected to XPS analysis. The XPS analysis was performed using Quantera SXM and Quantera II produced by PHI, inc. A monochromatic Al Kα ray (1486.6 eV) was used for an X-ray source. A detection area was set to 100 pmb. A take-off angle was set to 90°. The detection depth was estimated to be approximately 8 nm.

Table 1 shows the XPS analysis results of the tantalum nitride films included in the sample group A.

Table 1 reveals that a lower nitrogen flow rate ratio results in a lower N/Ta ratio, and a higher DC power leads to a lower N/Ta ratio. Note that the samples 4A to 6A have almost the same N/Ta ratio though DC powers for the samples 4A to 6A differ from each other.

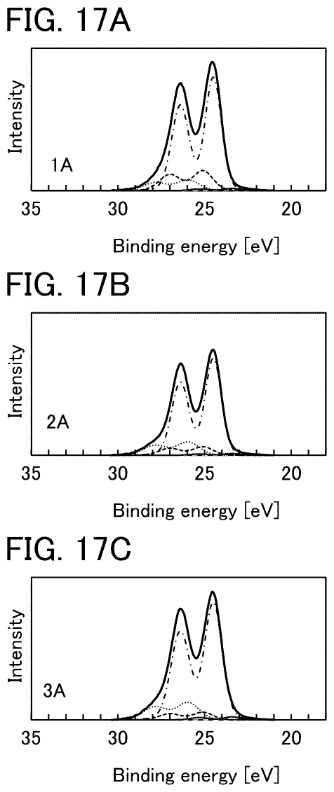

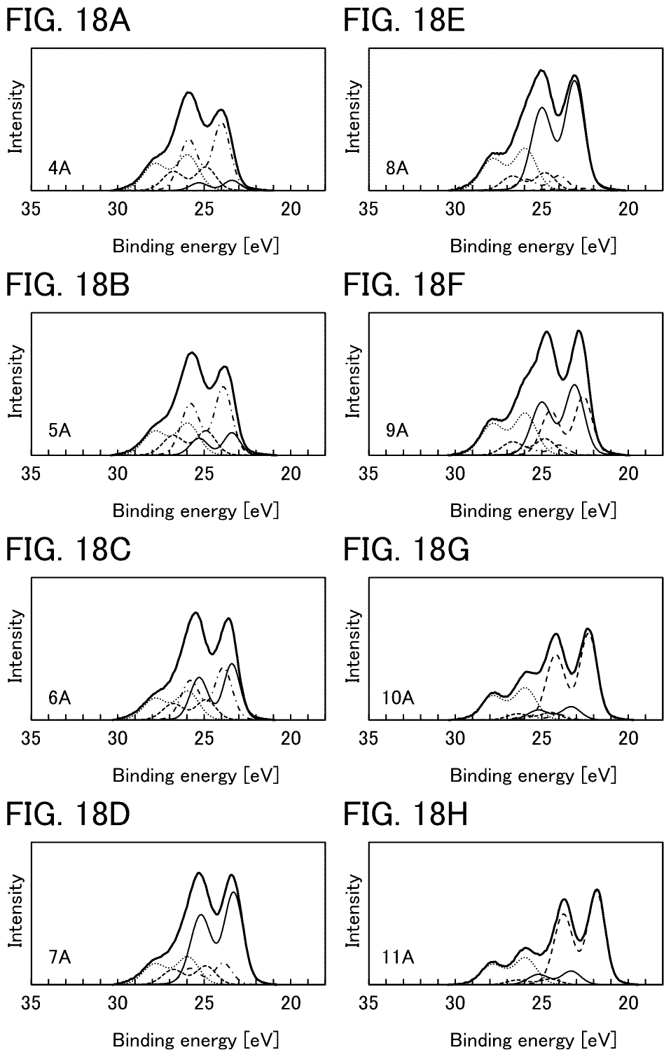

FIGS. 17A to 17C and FIGS. 18A to 18H show tantalum 4f XPS spectra of the samples obtained by the XPS analysis. FIG. 17A, FIG. 17B, and FIG. 17C show the tantalum 4f XPS spectra of the sample 1A, the sample 2A, and the sample 3A, respectively. FIG. 18A, FIG. 18B, FIG. 18C, and FIG. 18D show the tantalum 4f XPS spectra of the sample 4A, the sample 5A, the sample 6A, and the sample 7A, respectively. FIG. 18E, FIG. 18F, FIG. 18G, and FIG. 18H show the tantalum 4f XPS spectra of the sample 8A, the sample 9A, the sample 10A, and the sample 11A, respectively. The tantalum bonding states were evaluated using the tantalum 4f XPS spectra shown in FIGS. 17A to 17C and FIGS. 18A to 18H.

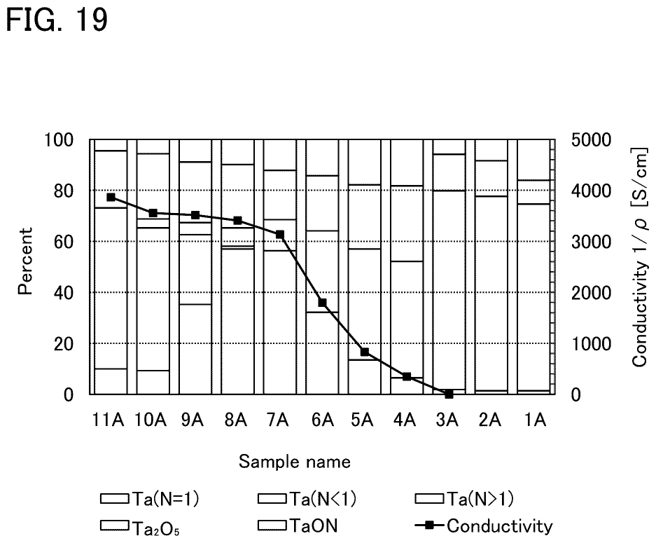

FIG. 19 shows the XPS analysis results of the tantalum nitride films included in the sample group A. In FIG. 19, the horizontal axis represents the sample name, the first vertical axis on the left represents the percentage of the tantalum bonding state (Percent in the graph), and the bar chart shows the percentages of the tantalum bonding states. FIG. 19 also shows the measurement results of the sheet resistances of the tantalum nitride films included in the sample group A. In FIG. 19, the second vertical axis on the right represents the conductivity 1/ρ [S/cm] of the tantalum nitride film, and the line chart represents the conductivity of the tantalum nitride films. Note that the sheet resistance measurement will be described in detail later.

FIG. 19 shows the percentages of the tantalum bonding states. For a calculation method of the percentages of the tantalum bonding states, refer to the description in Embodiment 1. Specifically, the percentages of the tantalum bonding states were calculated using waveform separation of the tantalum 4f orbital bonding states. In FIG. 19, Ta(N<1) represents a bonding state of tantalum metal and a bonding state of tantalum nitride with stoichiometrically less nitrogen per tantalum, and corresponds to the first tantalum bonding state described in Embodiment 1. In FIG. 19, Ta(N=1) represents a bonding state of tantalum nitride with stoichiometrically equal nitrogen per tantalum and a bonding state of tantalum oxynitride with a low oxygen content (a bonding state of tantalum nitride oxide), and corresponds to the second tantalum bonding state described in Embodiment 1. In FIG. 19, Ta(N>1) represents a bonding state of tantalum nitride with stoichiometrically more nitrogen per tantalum, and corresponds to the third tantalum bonding state described in Embodiment 1. In FIG. 19, TaON represents a bonding state of tantalum oxynitride and corresponds to the fourth tantalum bonding state described in Embodiment 1. In FIG. 19, Ta₂O₅ represents a bonding state of tantalum oxide and corresponds to the fifth tantalum bonding state described in Embodiment 1.

The sum of the percentage of Ta(N<1) and the percentage of Ta(N=1) was 1.4% in the samples 1A and 2A, 1.9% in the sample 3A, 6.5% in the sample 4A, 13.5% in the sample 5A, 32.2% in the sample 6A, 56.3% in the sample 7A, 58.1% in the sample 8A, 62.6% in the sample 9A, 65.3% in the sample 10A, and 73.1% in the sample 11A. The percentage of Ta(N<1) was 0% in the samples 1A to 7A, 1.1% in the sample 8A, 27.3% in the sample 9A, 56% in the sample 10A, and 63.1% in the sample 11A.

According to FIG. 19, DC power adjustment changes the percentages of the tantalum bonding states. Specifically, the percentages of the tantalum bonding states tend to change as follows: as the DC power becomes lower, the tantalum bonding state changes from Ta(N<1) to Ta(N=1) and then to Ta(N>1).

As shown in FIG. 19, the main tantalum bonding state in each of the samples 1A to 3A is Ta(N>1). Note that the percentage of Ta(N>1) was 73.2% in the sample 1A, 76.2% in the sample 2A, and 77.9% in the sample 3A.

### [Resistivity and Conductivity]

The sheet resistances of the tantalum nitride films included in the sample group A were measured using a sheet resistance measuring instrument. Note that the upper measurement limit of the sheet resistance measuring instrument was 90 MΩ/sq. The sheet resistance was multiplied by the thickness of the tantalum nitride film (50 nm), whereby the sheet resistance was converted into resistivity ρ. Thus, the upper measurement limit of the resistivity in this example was 4.5×10² Ωcm. The resistivity ρ was converted into a reciprocal so that the conductivity was calculated from the resistivity ρ.

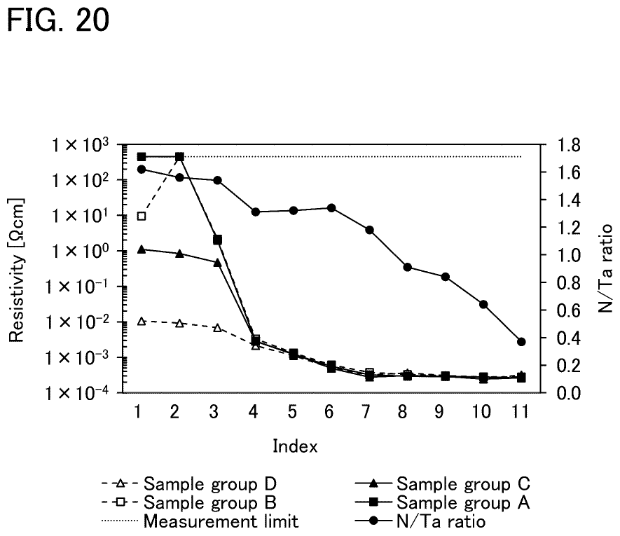

Table 2, FIG. 19, and FIG. 20 show the measurement results of the sheet resistances of the tantalum nitride films included in the sample groups A, B, C, and D.

TABLE 2

| | Resistivity [Ωcm] | | | | | | |
|---|---|---|---|---|---|---|---|
| | Sample | Sample | Sample | Sample | Sample group E | | |
| Index | group A | group B | group C | group D | Iₒₙ [μA] | Vₜₕ [V] | σ(Vₜₕ) [mV] |
| 1 | >4.5 × 10² | 9.52 | 1.11 | 1.05 × 10⁻² | n/a | n/a | n/a |
| 2 | >4.5 × 10² | >4.5 × 10² | 8.40 × 10⁻¹ | 9.19 × 10⁻³ | n/a | n/a | n/a |
| 3 | 1.95 | 2.15 | 4.70 × 10⁻¹ | 6.85 × 10⁻³ | n/a | n/a | n/a |
| 4 | 2.85 × 10⁻³ | 3.30 × 10⁻³ | 2.78 × 10⁻³ | 2.13 × 10⁻³ | 3.91 | 0.4 | 97.67 |
| 5 | 1.20 × 10⁻³ | 1.33 × 10⁻³ | 1.25 × 10⁻³ | 1.12 × 10⁻³ | 4.78 | 0.46 | 64.36 |
| 6 | 5.56 × 10⁻⁴ | 6.13 × 10⁻⁴ | 5.68 × 10⁻⁴ | 5.73 × 10⁻⁴ | 6.33 | 0.34 | 45.77 |
| 7 | 3.19 × 10⁻⁴ | 3.75 × 10⁻⁴ | 3.30 × 10⁻⁴ | 3.71 × 10⁻⁴ | 7.01 | −0.02 | 102.77 |
| 8 | 2.94 × 10⁻⁴ | 3.29 × 10⁻⁴ | 3.06 × 10⁻⁴ | 3.65 × 10⁻⁴ | 3.58 | −1.08 | 927.23 |
| 9 | 2.85 × 10⁻⁴ | 3.02 × 10⁻⁴ | 2.90 × 10⁻⁴ | 3.06 × 10⁻⁴ | 0.62 | −4.61 | 331843.04 |
| 10 | 2.81 × 10⁻⁴ | 2.83 × 10⁻⁴ | 2.86 × 10⁻⁴ | 3.02 × 10⁻⁴ | — | — | — |
| 11 | 2.59 × 10⁻⁴ | 2.80 × 10⁻⁴ | 2.66 × 10⁻⁴ | 3.20 × 10⁻⁴ | — | — | — |

In Table 2, “Index” represents the index, and “Resistivity” represents the resistivity of the tantalum nitride film. In Table 2, “>4.5×10²” means that the sheet resistance exceeds the upper measurement limit. Table 2 also shows the on-state current Iₒₙ, the threshold voltage Vₜₕ, and σ(Vₜₕ) calculated from the Id-Vg curves obtained. The on-state current Iₒₙ and the threshold voltage Vₜₕ in Table 2 are each an average value. The details of the Id-Vg curves and a sample group E will be described later.

In FIG. 20, the horizontal axis represents the index, and the first vertical axis on the left represents the resistivity [Ωcm]. The dotted line in FIG. 20 represents the upper measurement limit of the resistivity. FIG. 20 also shows the N/Ta ratio. In FIG. 20, the second vertical axis on the right and the black circles represent the N/Ta ratio.

As shown in Table 2 and FIG. 20, the resistivity of the tantalum nitride film is high in each of the samples 1A to 3A and the samples 1B to 3B, which indicates that the tantalum nitride films in those samples are not preferable for transistor electrodes. By contrast, the resistivity of the tantalum nitride film is low in each of the samples 4A to 11A and the samples 4B to 11B. In particular, the resistivity of the tantalum nitride film in each of the samples 7A to 11A and the samples 7B to 11B is within the range from 2.59×10⁻⁴ Ωcm to 3.75×10⁻⁴ Ωcm.

The results of the samples 4A to 7A show a tendency in which a decrease in DC power from 1.3 kW to 0.5 kW increases the resistivity from 3.19×10⁻⁴ Ωcm to 2.85×10⁻³ Ωcm. A similar tendency is found in each of the sample groups B, C, and D.

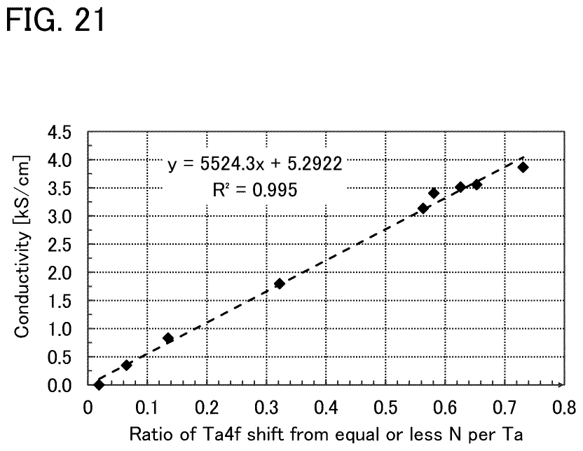

FIG. 21 shows the relationship between the conductivity and the chemical shift value of the tantalum nitride film. In FIG. 21, the horizontal axis represents the sum of the percentage of Ta(N<1) and the percentage of Ta(N=1) (Ratio of Ta4f shift from equal or less N per Ta in the graph), and the vertical axis represents the conductivity of the tantalum nitride film. The results from the samples 3A to 11A are plotted in FIG. 21. A linear approximate line of the plots is denoted by a dashed line in FIG. 21. The formula and coefficient of determination (R²) of the linear approximation are also shown in FIG. 21.

FIG. 21 reveals that the conductivity and the chemical shift value of the tantalum nitride film have a linear relationship. Specifically, it is found that as the sum of the percentage of Ta(N<1) and the percentage of Ta(N=1) becomes larger, the conductivity of the tantalum nitride film becomes higher. In other words, as the sum of the percentage of Ta(N<1) and the percentage of Ta(N=1) becomes smaller, the conductivity of the tantalum nitride film becomes lower. The tantalum 5d orbital mainly contributes to the conduction band of tantalum nitride. Thus, an increase in nitrogen content reduces the number of electrons in the tantalum 5d orbital, which probably results in a decrease in the conductivity of the tantalum nitride film.

In the linear approximation formula in FIG. 21, x is greater than or equal to 0 and less than or equal to 1. Note that y is the maximum value (5529.5922 S/cm) when x is 1 in the linear approximation formula shown in FIG. 21. Since the vertical axis represents the conductivity of the tantalum nitride film, the minimum value of the resistivity of the tantalum nitride film can be calculated by converting the maximum value of y into a reciprocal. Note that the minimum value of the resistivity is 180.9 μΩcm. That is, the resistivity is 180.9 μΩcm in the case where the sum of the percentage of Ta(N<1) and the percentage of Ta(N=1) is 100%.

### [XRD Analysis]

The samples 4A to 8A and the samples 4B to 8B were subjected to XRD analysis. In the XRD analysis, a θ-2θ scanning method which is a kind of an out-of-plane method was used. In a θ-2θ scanning method, X-ray diffraction intensity is measured while an incident angle of an X-ray is changed and the angle of a detector facing an X-ray source is set equal to the incident angle. The θ-2θ scanning method is called a powder method in some cases. The XRD analysis was performed using a multifunction thin film material evaluation X-ray diffractometer, D8 DISCOVER, produced by Bruker AXS. In the XRD analysis, a Cu-Kα ray (λ=0.15418 nm) was used as an X-ray source, the scanning range was 2θ=20 deg. to 45 deg., the step width was 0.01 deg., and the scanning speed was 6.0 deg/min.

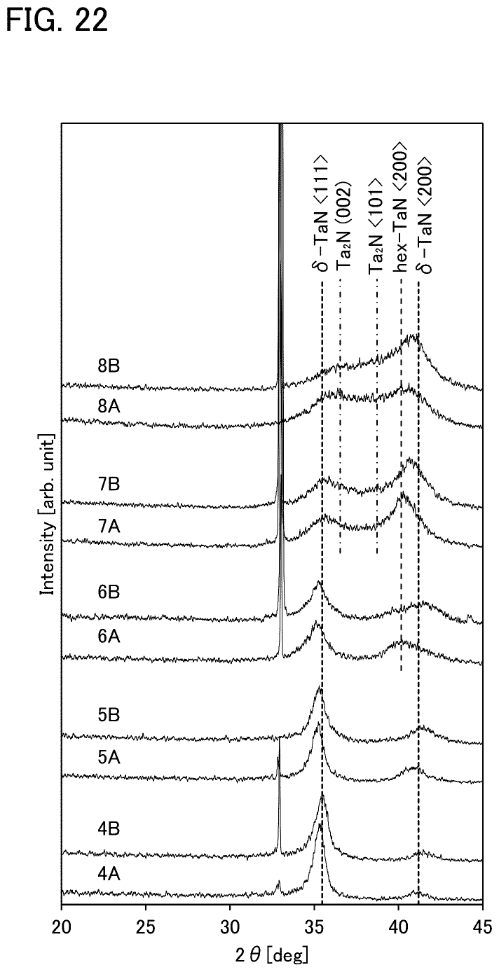

FIG. 22 shows the XRD analysis results of the samples. In FIG. 22, the horizontal axis represents the diffraction angle 2θ and the vertical axis represents the X-ray diffraction intensity. Note that a peak observed at 2θ of around 32.9 deg. is derived from diffraction at the (200) plane of silicon, which is forbidden reflection that is not supposed to appear.

In FIG. 22, a dashed line at around 2θ=35.5 deg. represents a peak position of a peak derived from the δ-TaN phase with a crystal orientation of <111>, which corresponds to the peak position of the first peak described in Embodiment 1. Note that the crystal system of δ-TaN is a cubic crystal system. A dashed-dotted line at around 2θ=36.5 deg. represents a peak position of a peak derived from the (002) plane of Ta₂N. A dashed-dotted line at around 2θ=38.7 deg. represents a peak position of a peak derived from a Ta₂N phase with a crystal orientation of <101>. A dashed line at around 2θ=40.2 deg. represents a peak position of a peak derived from a hexagonal TaN phase (denoted as hex-TaN in FIG. 22) with a crystal orientation of <200>. A dashed line at around 2θ=41.2 deg. represents a peak position of a peak derived from the δ-TaN phase with a crystal orientation of <200>, which corresponds to the peak position of the second peak described in Embodiment 1.

In FIG. 22, two peaks derived from the δ-TaN phases are observed in each of the samples 4A to 8A and the samples 4B to 8B. In each of the samples 4A to 6A, the peak level of the first peak is higher than that of the second peak. Specifically, the peak level ratio of the second peak to the first peak is 0.20 in the sample 4A, 0.35 in the sample 5A, and 0.70 in the sample 6A. Thus, it is found that the crystal orientation of the tantalum nitride film can be controlled by the deposition conditions of the tantalum nitride film and the heat treatment after the deposition of the tantalum nitride film.

The XRD analysis was also performed on the samples 1A to 3A, the samples 1B to 3B, the samples 9A to 11A, and the samples 9B to 11B.

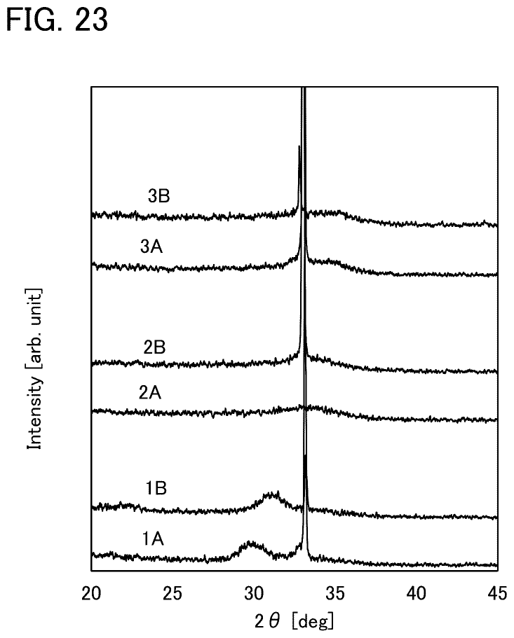

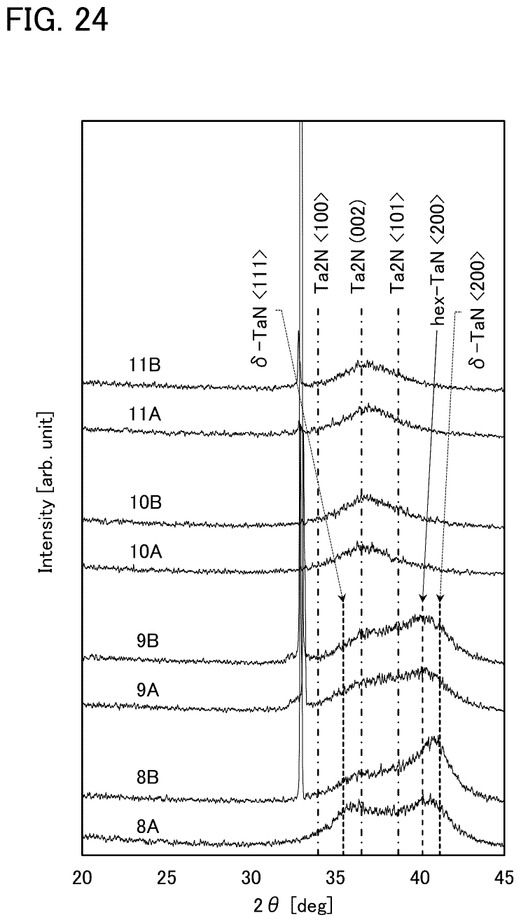

FIG. 23 and FIG. 24 show the XRD analysis results of the samples. In each of FIG. 23 and FIG. 24, the horizontal axis represents the diffraction angle 2θ and the vertical axis represents the X-ray diffraction intensity. Note that a peak observed at 2θ of around 32.9 deg. is derived from diffraction at the (200) plane of silicon, which is forbidden reflection that is not supposed to appear. FIG. 23 shows the XRD spectra of the samples 1A to 3A and the samples 1B to 3B, and FIG. 24 shows the XRD spectra of the samples 8A to 11A and the samples 8B to 11B.

In FIG. 24, two peaks derived from the δ-TaN phases and a peak derived from the Ta₂N phase are observed in each of the samples 8A, 8B, 9A, and 9B. In addition, a peak derived from the Ta₂N phase is observed in each of the samples 10A, 10B, 11A, and 11B.

### [D-Sims Analysis]

The samples 4D to 7D were subjected to analysis by secondary ion mass spectrometry in a dynamic mode (D-SIMS), which is hereinafter referred to as D-SIMS analysis. The analysis direction of the D-SIMS analysis is a direction from a silicon nitride film toward the substrate. The oxygen (¹⁸O) profiles in the samples 4D to 7D were obtained by the D-SIMS analysis. Note that the D-SIMS analysis was performed using an ADEPT-1010 quadrupole SIMS system produced by ULVAC-PHI, Inc.

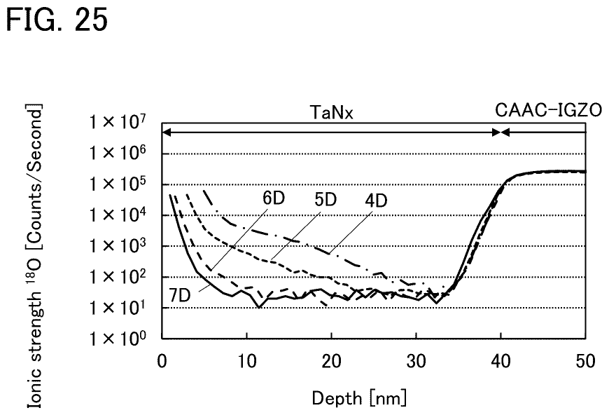

FIG. 25 shows the D-SIMS analysis results of the samples. In FIG. 25, the horizontal axis represents the depth from the surface of the tantalum nitride film and the vertical axis represents the ionic strength of ¹⁸O.

According to FIG. 25, the depth of oxygen entering the tantalum nitride film is the deepest in the sample 4D, followed in order by the sample 5D, the sample 6D, and the sample 7D. These results probably correspond to the results in FIG. 19 in which the sum of the percentage of TaON and the percentage of Ta₂O₅ is the largest in the sample 4D, followed in order by the sample 5D, the sample 6D, and the sample 7D.

### [Stem Image]

Cross-sectional scanning transmission electron microscopy (STEM) images of the samples 4C to 7C and the samples 4D to 7D were taken at an accelerating voltage of 200 kV with HD-2700, produced by Hitachi High-Tech Corporation. Note that the samples were thinned with XVision 200TBS, produced by Hitachi High-Tech Corporation.

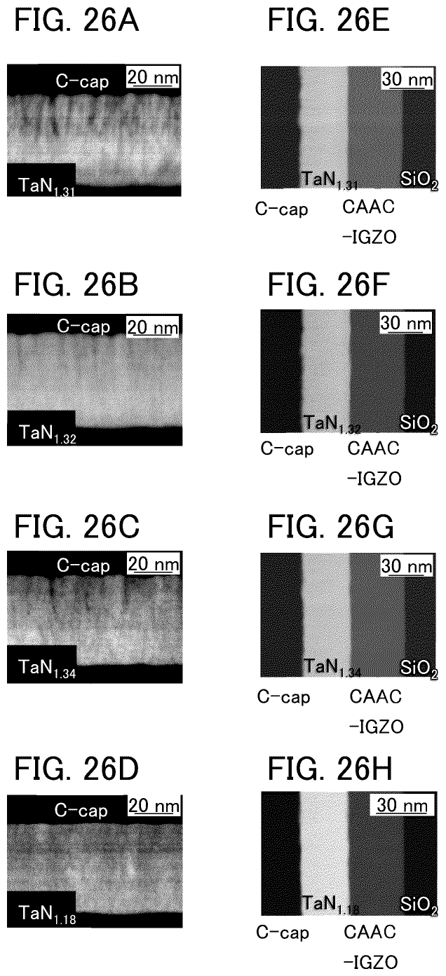

FIGS. 26A to 26H show the cross-sectional STEM images of the samples. FIG. 26A, FIG. 26B, FIG. 26C, FIG. 26D, FIG. 26E, FIG. 26F, FIG. 26G, and FIG. 26H show the cross-sectional STEM images of the sample 4C, the sample 5C, the sample 6C, the sample 7C, the sample 4D, the sample 5D, the sample 6D, and the sample 7D, respectively.

Note that as a protective film for STEM observation, a carbon film was formed over the layer 903. In FIGS. 26A to 26H, C-cap corresponds to the carbon film.

In FIGS. 26A to 26D, the columnar growth of crystal grains is observed in each of the samples 4C to 7C. In particular, the columnar growth of the crystal grains is observed most clearly in the sample 4C, followed in order by the sample 5C, the sample 6C, and the sample 7C. This indicates that as the DC power is lower, the columnar growth of the crystal grains appears at a higher frequency. The columnar growth of the crystal grains appearing at a high frequency leads to generation of a crystal grain boundary, which probably diffuses oxygen more deeply (see FIG. 25). In addition, electrons are presumably captured or scattered at the crystal grain boundary. Note that among the tantalum nitride films in the samples 4C to 7C, the tantalum nitride film in the sample 7C is the most uniform.

As shown in FIG. 26H, in the sample 7D, damage to the CAAC-IGZO is observed in the vicinity of its surface, especially in a region that is 1 nm to 2 nm from the interface between the tantalum nitride and the CAAC-IGZO. Note that in the samples 4D to 6D, such damage is not observed in the vicinity of the surface of the CAAC-IGZO (see FIGS. 26E to 26G).

As described above, it is found that as the sum of the percentage of Ta(N<1) and the percentage of Ta(N=1) becomes larger, the conductivity of the tantalum nitride film can be higher. It is also found that a lower percentage of Ta(N<1) results in less damage in the vicinity of the surface of the CAAC-IGZO.

It is also found that the crystal grain boundary can be reduced in the tantalum nitride film having the δ-TaN phase. In particular, when the content of the δ-TaN phase with a crystal orientation of <111> is almost equal to the content of the δ-TaN phase with a crystal orientation of <200>, the crystal grain boundary in the tantalum nitride film can be further reduced.

Thus, it is presumed that the tantalum nitride films deposited under the conditions of the samples 4A to 7A in Table 1 are suitable for electrodes of an OS transistor, and that the tantalum nitride films deposited under the conditions of the samples 4A to 6A in Table 1 are further suitable for the electrodes of the OS transistor.

### [STEM Image and EDX Analysis]

Cross-sectional STEM images of the samples 10C and 10D were taken under the above-described conditions.

The samples 10C and 10D were subjected to EDX line analysis and EDX mapping analysis. In each analysis, oxygen at the interface between the tantalum nitride film and the oxide semiconductor layer was focused on. The EDX line analysis was performed using Octane T Ultra W (Dual EDS) produced by EDAX Inc as an EDX detector of a STEM system.

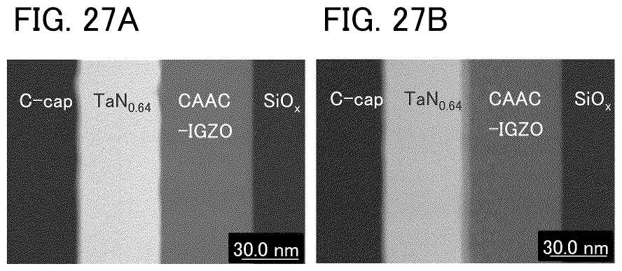

FIGS. 27A and 27B are the cross-sectional STEM images of the samples. FIG. 27A shows the cross-sectional STEM image of the sample 10C, and FIG. 27B shows the cross-sectional STEM image of the sample 10D.

Note that as a protective film for STEM observation, a carbon film was formed over the layer 903. In FIGS. 27A and 27B, C-cap corresponds to the carbon film.

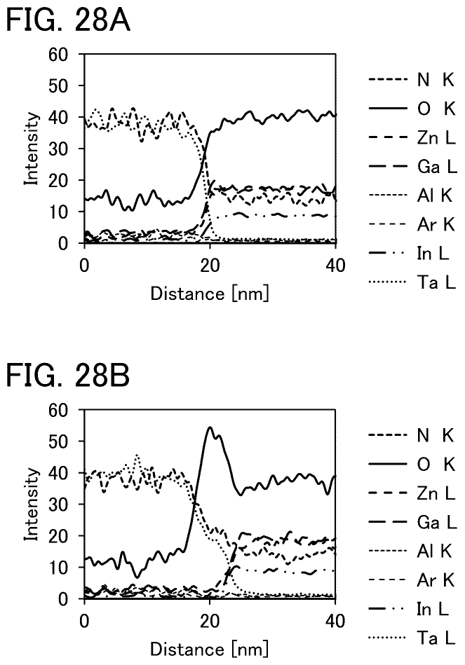

FIGS. 28A and 28B show the EDX line analysis results. In each of FIGS. 28A and 28B, the vertical axis represents the intensity and the horizontal axis represents the distance. Note that the interface between the tantalum nitride film and the oxide semiconductor layer was adjusted to be positioned at 20 nm on the horizontal axis. FIG. 28A shows the results of the sample 10C, and FIG. 28B shows the results of the sample 10D.

As shown in FIG. 27A and FIG. 28A, an extremely uniform tantalum nitride film having a clear interface is observed. Meanwhile, in FIG. 27B and FIG. 28B, an oxide film is clearly observed at the interface between the tantalum nitride film and the oxide semiconductor layer. These results reveal that the heat treatment causes the formation of the oxide film at the interface. Note that the oxide film contains tantalum, oxygen, and nitrogen, and has a thickness of 4.59 nm.

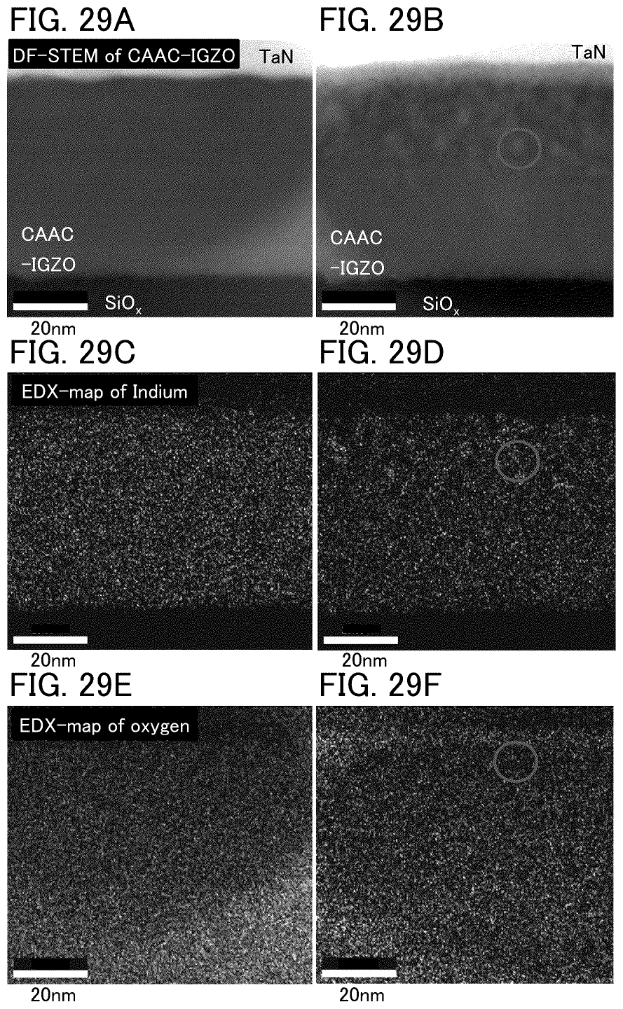

FIGS. 29A to 29F show the STEM images and the EDX mapping analysis results. FIG. 29A shows the STEM image of the sample 10C, and FIG. 29B shows the STEM image of the sample 10D. FIG. 29C shows the EDX map of indium in the sample 10C, and FIG. 29D shows the EDX map of indium in the sample 10D. FIG. 29E shows the EDX map of oxygen in the sample 10C, and FIG. 29F shows the EDX map of oxygen in the sample 10D. The STEM images in FIGS. 29A and 29B are dark-field images (DF-STEM images).

In the STEM image in FIG. 29B, a plurality of bright spots (indicated by a circle in FIG. 29B, for example) are observed in the oxide semiconductor layer. According to FIG. 29D, the region where the bright spots are observed is presumably a clumpy region with a high indium content. According to FIG. 29F, the region with a high indium content is presumably attributed to oxygen vacancies in the oxide semiconductor layer formed by the oxidation of the tantalum nitride film by the oxide semiconductor layer.

The features of the tantalum nitride films obtained from the XRD analysis and the STEM images are listed in Table 3. In Table 3, “Phase” represents the phase in the tantalum nitride film, and “Macrostructure” represents the state of the tantalum nitride film. As described above, the tantalum nitride films included in the indexes 4 to 6 have columnar crystal grains (represented as Column), and the tantalum nitride films included in the indexes 7 and 10 are uniform (represented as Uniform).

TABLE 3

| Index | 1 | 2 | 3 | 4 | 5 | 6 | 7 | 8 | 9 | 10 | 11 |
|---|---|---|---|---|---|---|---|---|---|---|---|
| N/Ta ratio | 1.62 | 1.54 | 1.52 | 1.31 | 1.32 | 1.34 | 1.18 | 0.91 | 0.84 | 0.64 | 0.37 |
| Phase | — | — | — | δ-TaN | δ-TaN | δ-TaN | δ-TaN | δ-TaN, | δ-TaN, | Ta₂N | Ta₂N |
| | | | | | | | | Ta₂N | Ta₂N | | |
| Macro- | — | — | — | Column | Column | Column | Uniform | — | — | Uniform | — |
| structure | | | | | | | | | | | |

### [Work Function and Optical Band Gap]

Next, the work functions and optical band gaps of tantalum nitride films were evaluated.

Samples 1F to 11F were fabricated for work function evaluation, and samples 1G to 11G were fabricated for optical band gap evaluation. Hereinafter, in some cases, the samples 1F to 11F are collectively referred to as a sample group F and the samples 1G to 11G are collectively referred to as a sample group G.

FIG. 16C is a schematic cross-sectional view of each of the sample groups F and G. As illustrated in FIG. 16C, the sample groups F and G each include the layer 901 and the layer 903 over the layer 901.

First, a method for fabricating the sample group F will be described. The sample group F differs from the sample group A in that the layer 902 is not provided. For the methods for forming the layers 901 and 903 in the sample group F, refer to the above description of the method for fabricating the sample group A. For the deposition conditions of the tantalum nitride films in the samples 1F to 11F, Table 1 can be referred to by replacing the samples 1A to 11A with the samples 1F to 11F.

In this manner, the sample group F was fabricated.

Next, a method for fabricating the sample group G will be described. For the method for forming the layer 903 in the sample group G, refer to the above description of the method for fabricating the sample group A. For the deposition conditions of the tantalum nitride films in the samples 1G to 11G, Table 1 can be referred to by replacing the samples 1A to 11A with the samples 1G to 11G.

A quartz substrate was prepared as the layer 901 included in the sample group G.

In this manner, the sample group G was fabricated.

The sample group F was subjected to ultraviolet photoelectron spectroscopy (UPS) measurement. For the UPS measurement, VersaProbe produced by PHI, Inc. was used. For an ultraviolet light source, He I ray (21.22 eV) was used. A detection area was set to 8 mm square or less. The bias voltage was set to −10 V. Before the measurement, the surface of the sample was cleaned by argon ion sputtering.

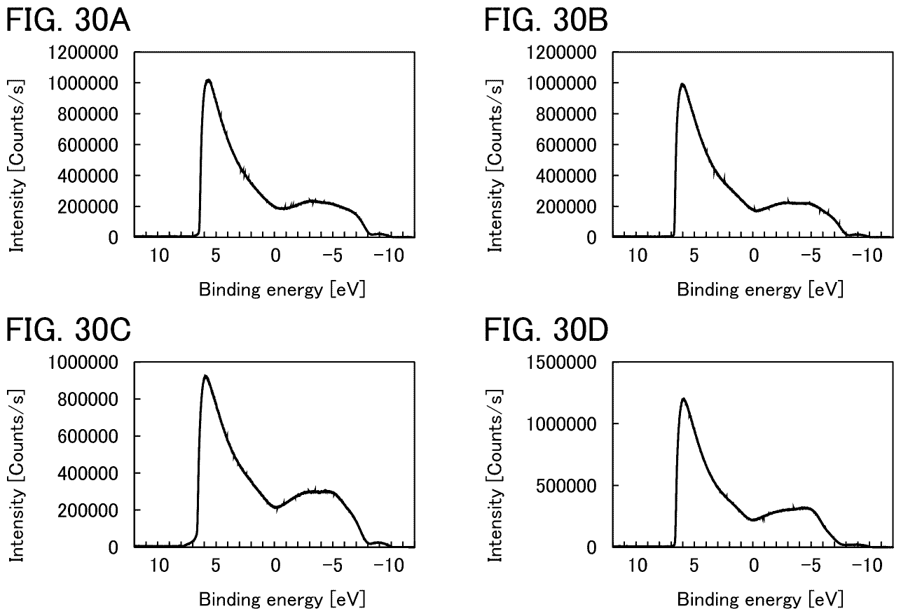

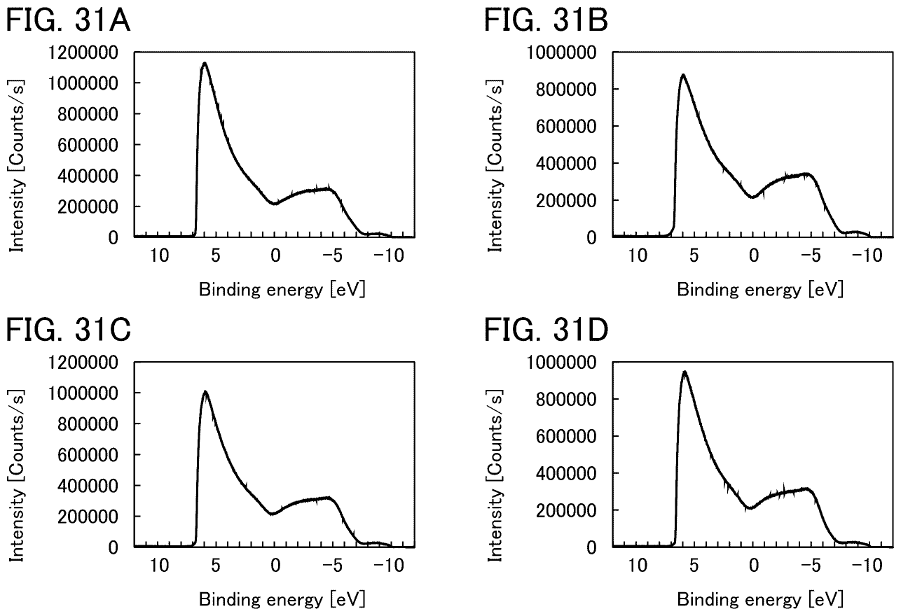

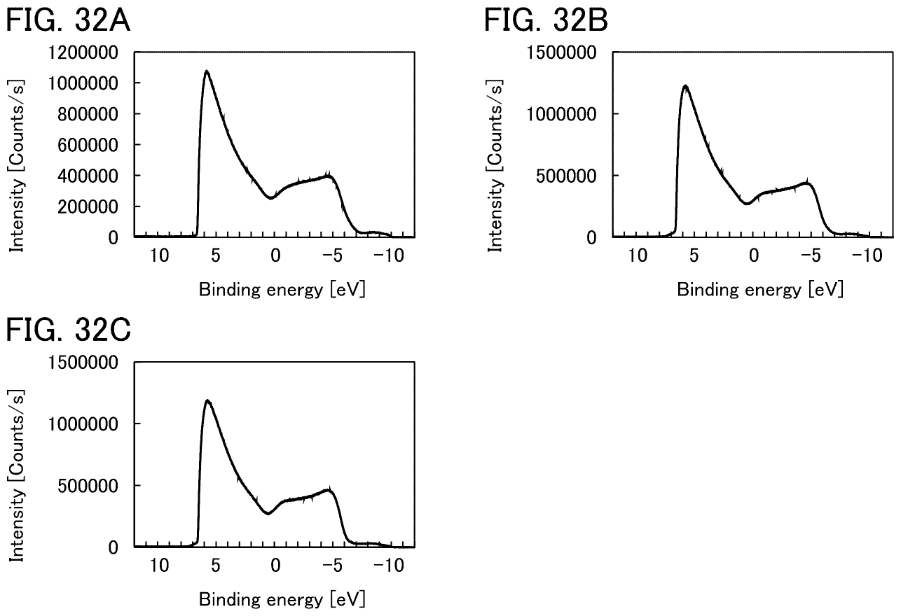

FIGS. 30A to 30D, FIGS. 31A to 31D, and FIGS. 32A to 32C show UPS spectra obtained by the UPS measurement. In each of FIGS. 30A to 30D, FIGS. 31A to 31D, and FIGS. 32A to 32C, the vertical axis represents the intensity and the horizontal axis represents the binding energy. FIG. 30A, FIG. 30B, FIG. 30C, and FIG. 30D show the UPS spectra of the sample 1G, the sample 2G, the sample 3G, and the sample 4G, respectively. FIG. 31A, FIG. 31B, FIG. 31C, and FIG. 31D show the UPS spectra of the sample 5G, the sample 6G, the sample 7G, and the sample 8G, respectively. FIG. 32A, FIG. 32B, and FIG. 32C show the UPS spectra of the sample 9G, the sample 10G, and the sample 11G, respectively.

Table 4 shows the UPS measurement results. In Table 4, “Eₖ(min)” represents the lowest energy crossing the barrier of the work function, and “Eₖ(max)” represents the highest energy crossing the barrier of the work function. In addition, “Ionization energy” corresponds to the work function, and is calculated by subtracting the absolute value of the difference between Eₖ(min) and Eₖ(max) from the energy of irradiation light (21.22 eV).

TABLE 4

| | | | Ionization |
|---|---|---|---|
| Sample | Eₖ(min) | Eₖ(max) | energy |
| name | [eV] | [eV] | [eV] |
| 1F | 6.3 | −10.0 | 4.9 |
| 2F | 6.6 | −10.0 | 4.6 |
| 3F | 6.5 | −10.0 | 4.7 |
| 4F | 6.6 | −10.0 | 4.6 |
| 5F | 6.7 | −10.0 | 4.6 |
| 6F | 6.6 | −10.0 | 4.6 |
| 7F | 6.6 | −10.0 | 4.6 |
| 8F | 6.5 | −10.0 | 4.7 |
| 9F | 6.5 | −10.0 | 4.7 |
| 10F | 6.5 | −10.0 | 4.7 |
| 11F | 6.5 | −10.0 | 4.8 |

According to Table 4, the work function of each of the samples 4F to 7F is 4.6 eV. In the samples 8F to 11F, the work function tends to be higher as the DC power is higher. There is no clear correlation between the samples 1F to 3F.

The electron affinity (the energy difference between the vacuum level and the conduction band minimum) of IGZO with an atomic ratio of In:Ga:Zn=1:1:1 is 4.6 eV. The use of the IGZO for the semiconductor layer and the tantalum nitride contained in any of the samples 4F to 7F for the source and drain electrodes can sometimes reduce contact resistance.

Next, the sample group G was subjected to analysis by ultraviolet-visible (UV-Vis) spectrophotometry. By the analysis, the transmittance and reflectance of each sample were measured to obtain absorption spectra and create the Tauc plot. The absorption edge was obtained from the Tauc plot, and such an absorption edge was regarded as the optical band gap. The analysis by UV-Vis spectrophotometry was performed using an ultraviolet-visible spectrophotometer (U-4100, produced by Hitachi High-Tech Corporation).

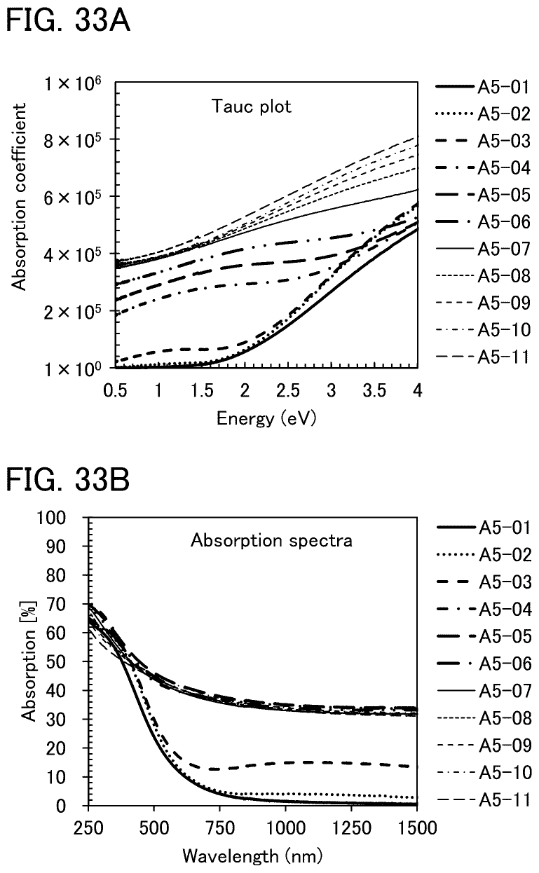

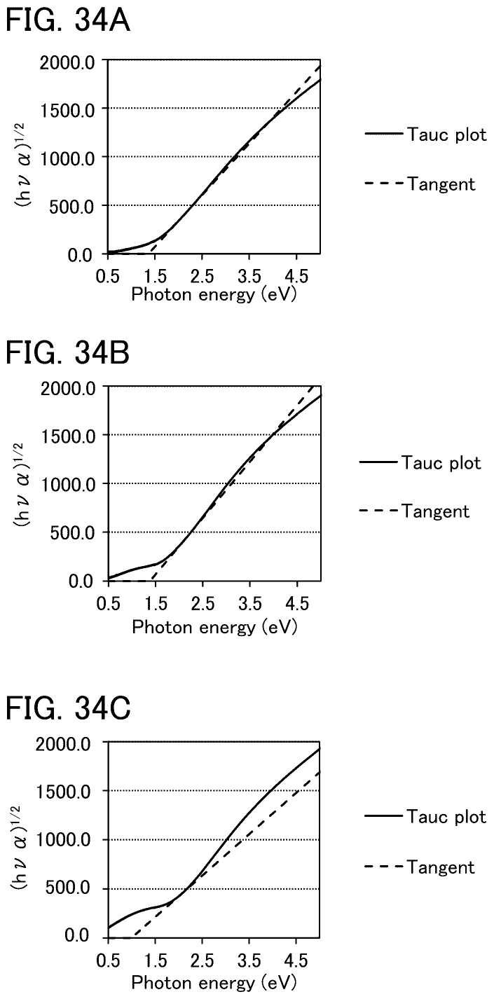

FIGS. 33A and 33B and FIGS. 34A to 34C show the results. In FIG. 33A, the vertical axis represents the absorption coefficient and the horizontal axis represents the energy. In FIG. 33B, the vertical axis represents the absorptance (Absorption in the graph) and the horizontal axis represents the energy. FIGS. 33A and 33B show the results of the samples 1G to 11G.

FIG. 33A reveals that the tantalum nitride films included in the samples 1G to 3G each have a band gap. Meanwhile, in the samples 4G to 11G, the absorption coefficient is not 0 even at an energy of 0 eV on the horizontal axis, which means that the tantalum nitride films included in the samples 4G to 11G have metallic properties.

According to FIG. 33B, the absorptance of the samples 4G to 11G converges to 32%, which indicates that the tantalum nitride films included in the samples 4G to 11G have metallic properties.

FIGS. 34A to 34C are graphs in each of which the vertical axis of FIG. 33A is replaced by (h να)ⁿ. Note that h represents the Planck constant, ν represents a frequency, and α represents an absorption coefficient. FIG. 34A, FIG. 34B, and FIG. 34C show the results of the sample 1G, the sample 2G, and the sample 3G, respectively. Note that a tantalum nitride film with a high nitrogen content is of indirect transition type. Thus, the Tauc plot is assumed to be of indirect transition type and n is set to ½.

According to FIGS. 34A to 34C, the optical band gap of the tantalum nitride film is 1.364 eV in the sample 1G, 1.383 eV in the sample 2G, and 0.994 eV in the sample 3G.

### <Evaluation of Electrical Characteristics of Transistor>

In this section, the evaluation results of the electrical characteristics of transistors containing tantalum nitride will be described.

### [Sample Fabrication 2]

In this example, samples 4E to 11E were fabricated. Hereinafter, the samples 4E to 11E are sometimes collectively referred to as the sample group E.

The sample group E includes transistors. Refer to FIG. 3 for a cross-sectional view of the transistors included in the sample group E. Note that the insulating layer 250 of each transistor included in the samples has a four-layer structure of the insulating layer 250d, the insulating layer 250c over the insulating layer 250d, the insulating layer 250a over the insulating layer 250c, and the insulating layer 250b over the insulating layer 250a as illustrated in FIGS. 5A and 5B. The designed channel length and channel width of each transistor included in the samples are 30 nm and 30 nm, respectively.

A method for fabricating the sample group E will be described below. Refer to Embodiment 1 for the details of the fabrication method.

As the insulating layer 214a, 60-nm-thick silicon nitride was used. The insulating layer 214a was deposited by a pulsed DC sputtering method using a silicon target. As the insulating layer 214b, 40-nm-thick aluminum oxide was used. The insulating layer 214b was deposited by a pulsed DC sputtering method using an aluminum target.

As the insulating layer 216, 130-nm-thick silicon oxide was used. The insulating layer 216 was deposited by a pulsed DC sputtering method using a silicon target.

The insulating layers 214a, 214b, and 216 were successively deposited without exposure to the air using a multi-chamber sputtering apparatus.

As the conductive layer 215a, a titanium nitride film was deposited by a metal CVD method. As the conductive layer 215b, a tungsten film was deposited by a metal CVD method.

As the insulating layer 222a, 5-nm-thick silicon nitride was deposited by an ALD method. As the insulating layer 222b, 15-nm-thick hafnium oxide was deposited by an ALD method.

As the insulating layer 224, 20-nm-thick silicon oxide was deposited by a sputtering method.

As the oxide semiconductor layer 230a, a 10-nm-thick In—Ga—Zn oxide film was deposited by an RF sputtering method. An oxide film to be the oxide semiconductor layer 230a was deposited using an oxide target with an atomic ratio of In:Ga:Zn=1:3:2.

As the oxide semiconductor layer 230b, a 15-nm-thick In—Ga—Zn oxide film was deposited by an RF sputtering method. An oxide film to be the oxide semiconductor layer 230b was deposited using an oxide target with an atomic ratio of In:Ga:Zn=1:1:1.2.

As each of the conductive layers 242a and 242b, a 20-nm-thick tantalum nitride film was deposited by a reactive sputtering method using a tantalum target and a nitrogen (N₂) gas. For each of the samples 4E to 11E, the tantalum nitride film was deposited under the conditions where the target-substrate distance was 286 mm and the substrate temperature was room temperature. For the deposition conditions of the tantalum nitride films in the samples 4E to 11E, Table 1 can be referred to by replacing the samples 4A to 11A with the samples 4E to 11E.

As each of the insulating layers 271a1 and 271b1, a 5-nm-thick silicon nitride film was used. As each of the insulating layers 271a2 and 271b2, a 10-nm-thick silicon oxide film was used. Note that the silicon nitride film and the silicon oxide film were successively deposited without exposure to the air using a multi-chamber sputtering apparatus.

As the insulating layer 275, 5-nm-thick silicon nitride was deposited by an ALD method.

As the insulating layer 280, silicon oxide was deposited by a sputtering method.

As the insulating layer 250d, a 1-nm-thick aluminum oxide film was deposited by an ALD method. As the insulating layer 250c, a 1.5-nm-thick silicon oxide film was deposited by an ALD method. As the insulating layer 250a, a 1-nm-thick hafnium oxide film was deposited by an ALD method. As the insulating layer 250b, a 1-nm-thick silicon nitride film was deposited by an ALD method.

As the conductive layer 260a, a 5-nm-thick titanium nitride film was deposited by a metal CVD method. As the conductive layer 260b, a tungsten film was deposited by a metal CVD method.

As the insulating layer 282, aluminum oxide was used. The insulating layer 282 was deposited by a pulsed DC sputtering method using an aluminum target.

As the insulating layer 283, 20-nm-thick silicon nitride was deposited by a sputtering method.

In this manner, the samples 4E to 11E including the transistors were fabricated.

### [Id-Vg Curve]

The electrical characteristics of a plurality of transistors selected from each sample in the sample group E were evaluated. Here, the drain current (Id)-gate voltage (Vg) curves were measured as the electrical characteristics. The Id-Vg curves were measured under the following conditions: the drain voltage was 1.2 V or 0.1 V, the source voltage was 0 V, and the gate voltage Vg was swept from −4 V to +4 V in increments of 0.1 V. The measurement was performed in an environment at room temperature. A semiconductor parameter analyzer produced by Keysight Technologies was used for the Id-Vg curves measurement.

The threshold voltage Vₜₕ was calculated from the Id-Vg curves obtained. In this example, the threshold voltage Vₜₕ is the gate voltage Vg at which Id is 1.0×10⁻¹² A in the Id-Vg curves with a drain voltage of 1.2 V. In addition, the on-state current Iₒₙ is the drain current Id at Vg=Vₜₕ+2.5 V. Furthermore, σ(Vₜₕ) is the deviation of the threshold voltage Vₜₕ.

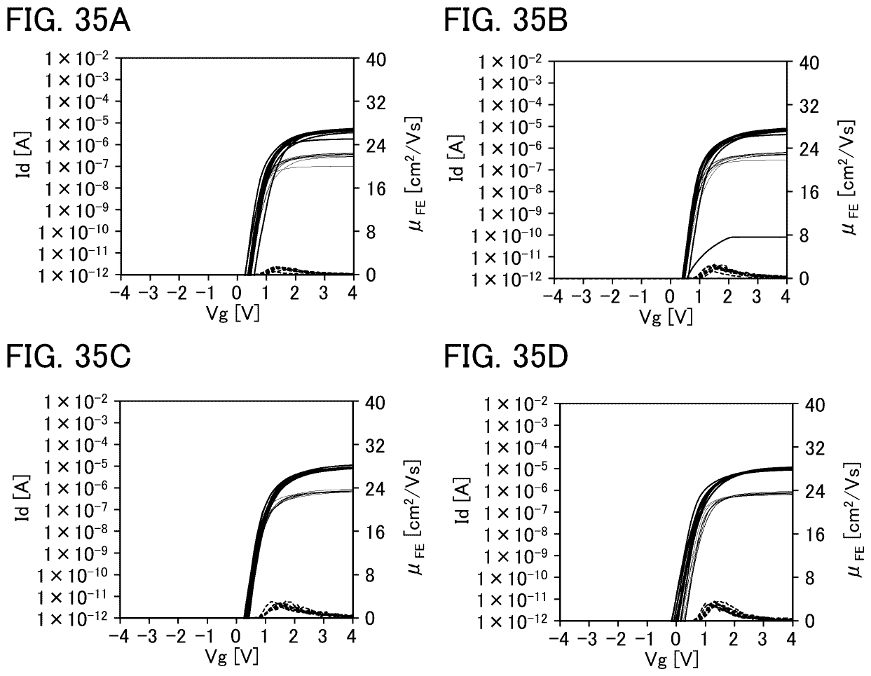

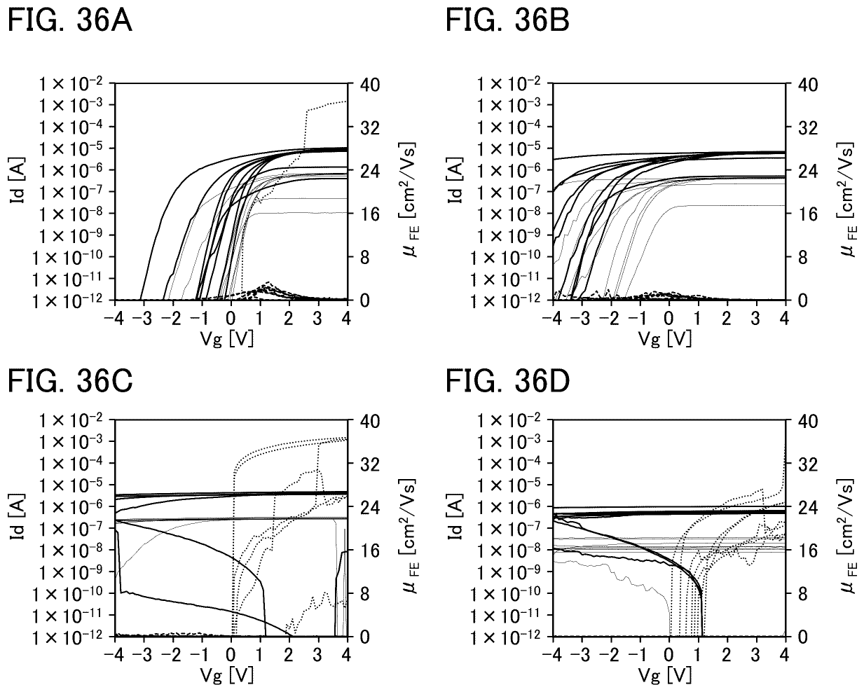

FIGS. 35A to 35D and FIGS. 36A to 36D show the Id-Vg curves of the transistors included in the sample group E. In each of FIGS. 35A to 35D and FIGS. 36A to 36D, the horizontal axis represents Vg [V], the first vertical axis on the left represents Id [A], and the second vertical axis on the right represents the field-effect mobility μ_{FE} [cm²/Vs]. FIG. 35A, FIG. 35B, FIG. 35C, and FIG. 35D show the Id-Vg curves of the transistors included in the sample 4E, the sample 5E, the sample 6E, and the sample 7E, respectively. FIG. 36A, FIG. 36B, FIG. 36C, and FIG. 36D show the Id-Vg curves of the transistors included in the sample 8E, the sample 9E, the sample 10E, and the sample 11E, respectively. In FIGS. 35A to 35D and FIGS. 36A to 36D, the Id-Vg curves at a drain voltage of 1.2 V are shown by thick solid lines, the Id-Vg curves at a drain voltage of 0.1 V are shown by thin solid lines, the field-effect mobility is shown by dashed lines, and gate leakage current is shown by dotted lines.

The average value of the on-state current Iₒₙ, the average value of the threshold voltage Vₜₕ, and σ(Vₜₕ) calculated from the Id-Vg curves obtained are shown in Table 2. Table 5 shows the median value of the threshold voltage Vₜₕ, σ(Vₜₕ), the median value of the on-state current Iₒₙ, the median value of the subthreshold swing S, the median value of the field-effect mobility μ_{FE}, and the median value of drain-induced barrier lowering (DIBL) calculated from the Id-Vg curves obtained. Note that DIBL refers to the amount of change in the threshold voltage Vₜₕ when the drain voltage (Vd) is changed by 1 V. Since transistors containing the tantalum nitrides deposited under the conditions of the samples 1A to 3A are not fabricated, Iₒₙ, Vₜₕ, σ(Vₜₕ), S, FE, and DIBL of the indexes 1 to 3 are denoted as n/a in Table 2 and Table 5.

TABLE 5

| Sample | Vₜₕ | σ(Vₜₕ) | Iₒₙ | S | μ_{FE} | DIBL |
|---|---|---|---|---|---|---|
| name | [V] | [mV] | [μA] | [mV/dec.] | [cm²/Vs] | [mV] |
| 1E | n/a | n/a | n/a | n/a | n/a | n/a |
| 2E | n/a | n/a | n/a | n/a | n/a | n/a |
| 3E | n/a | n/a | n/a | n/a | n/a | n/a |
| 4E | 0.39 | 97.67 | 3.90 | 111.7 | 1.76 | 70.39 |
| 5E | 0.47 | 64.36 | 5.58 | 103.3 | 2.57 | 64.93 |
| 6E | 0.34 | 45.77 | 7.69 | 108.8 | 3.14 | 73.62 |
| 7E | −0.03 | 102.77 | 9.08 | 131.3 | 3.54 | 248.78 |
| 8E | −3.84 | 927.23 | 5.27 | 217.1 | 0.60 | 689.02 |
| 9E | −3.68 | 331843.04 | 1.85 | 649.9 | 0.47 | 1665.60 |
| 10E | — | — | — | — | — | — |
| 11E | — | — | — | — | — | — |

FIGS. 35A to 35C reveal that the threshold voltage Vₜₕ is higher than 0 V in the transistors included in the samples 4E to 6E and accordingly the normally-off characteristics are observed. In addition, a tendency is observed in which as the DC power increases from 0.5 kW to 1.0 kW, the average value of the on-state current Iₒₙ increases from 3.91 μA to 6.33 μA (see Table 2). The on-state current increases along with a decrease in resistivity of tantalum nitride.

As shown in FIG. 35D, excellent switching characteristics are obtained in the transistors included in the sample 7E though the threshold voltage Vₜₕ is lower than 0 V and the normally-on characteristics are observed.

According to FIGS. 36A to 36D, the transistors included in the samples 8E to 11E are normally-on or have no switching characteristics, that is, are always in the on state. This is probably because high DC power at the time of depositing the tantalum nitrides causes significant damage to the channels. Since the samples 10E and 11E include the normally-on transistors, Iₒₙ, Vₜₕ, σ(Vₜₕ), S, μ_{FE}, and DIBL of the samples 10E and 11E are denoted by hyphens (-), which mean that they cannot be calculated, in Table 2 and Table 5.

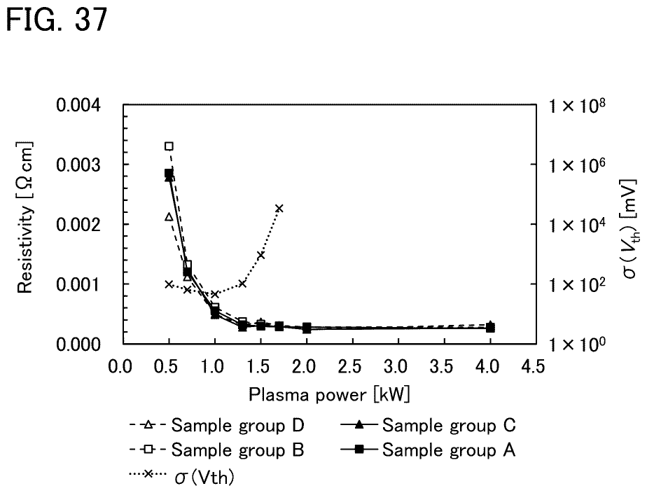

Here, FIG. 37 shows a graph in which the horizontal axis of FIG. 20 is replaced by DC power (Plasma power in the graph). In FIG. 37, the first vertical axis on the left represents the resistivity [Ωcm]. The first vertical axis is represented in a linear scale. FIG. 37 shows the resistivities of the samples 4A to 11A, the samples 4B to 11B, the samples 4C to 11C, and the samples 4D to 11D. FIG. 37 does not show the N/Ta ratio but shows σ(Vₜₕ) of the samples 4E to 9E. In FIG. 37, the second vertical axis on the right represents σ(Vₜₕ).

It is found that σ(Vₜₕ) in the case where the DC power is 1.0 kW or lower is smaller than σ(Vₜₕ) in the case where the DC power is 1.3 kW or higher. This suggests that the highest DC power at which the channel can withstand without loss of transistor characteristics falls within the range from 1.0 kW to 1.3 kW.

The above results demonstrate that the tantalum nitrides deposited under the conditions of the samples 3A to 7A shown in Table 1 are suitable for the electrodes of the transistor.

Here, the contact resistance at the time when a conductive layer is provided over and in contact with the oxide semiconductor layer was evaluated. The evaluation was performed by a transfer length method (also referred to as a TLM method).

The contact resistance can be calculated simply using the sum of the individual resistances of an FET. Here, the total FET resistance is assumed as in Formula (1).

$$[ Formula 1 ]$$

$$\begin{matrix}{R}_{FET} = {R}_{channel} + 2 {R}_{S / D} + 2 {R}_{contact} \\ = \frac{{ρ}_{channel}}{{σ}_{channel}} L + 2 {R}_{S / D} + 2 {R}_{contact}\end{matrix} \qquad ( 1 )$$

In Formula (1), R_{FET} is the total FET resistance, R_{channel} is channel resistance, ρ_{channel} is the resistivity of a channel, σ_{channel} is a cross-sectional area of the channel, L is channel length, R_{S/D} is the resistance of a source electrode (the resistance of a drain electrode), and R_{contact} is contact resistance between the source electrode and the channel (contact resistance between the drain electrode and the channel). In this example, the resistance of the source electrode was assumed to be the same as the resistance of the drain electrode.

In the case where the channel length L is approximated to 0 nm in Formula (1), Formula (2) is obtained.

$$[ Formula 2 ]$$

$${R}_{contact} = \frac{{R}_{FET} - 2 {R}_{S / D}}{2} = \frac{{R}_{intercept} - 2 {R}_{S / D}}{2} \qquad ( 2 )$$

In Formula (2), R_{intercept} is the total FET resistance in the case where the channel length L is approximated to 0 nm. Note that R_{intercept} corresponds to intercept obtained by linear regression on the total resistance of the FETs with different channel lengths.

Accordingly, the contact resistance R_{contact} can be obtained by calculating R_{intercept} and R_{S/D}.

First, R_{intercept} was calculated.

In this example, R_{FET} is a value obtained by dividing the drain voltage Vd by the on-state current Iₒₙ. The drain current at which the gate voltage is the sum of the threshold voltage Vₜₕ and 2.5 V is the on-state current Iₒₙ.

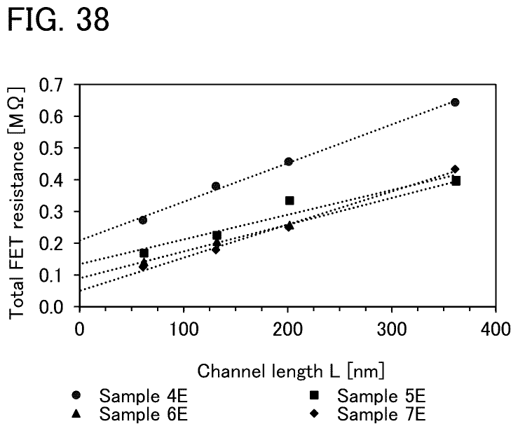

Table 6 and FIG. 38 show the results of the samples 4E to 7E obtained by the TLM method.

TABLE 6

| | Iₒₙ | | | | |
|---|---|---|---|---|---|
| Sample | (Vₜₕ + 2.5 V) | R_{FET} | L | W | Linear |
| name | [μA] | [Ω] | [nm] | [nm] | equation |
| 4E | 4.408 | 272217.0 | 61 | 79 | R_{FET} = 1216.5 L + |
| | 3.160 | 379755.2 | 131 | 79 | 208837 |
| | 2.626 | 457018.0 | 201 | 79 | |
| | 1.865 | 643566.4 | 361 | 79 | |
| 5E | 7.110 | 168773.9 | 62 | 76 | R_{FET} = 778.1 L + |
| | 5.336 | 224902.2 | 132 | 76 | 134205 |
| | 3.590 | 334273.8 | 202 | 76 | |
| | 3.010 | 398651.8 | 362 | 76 | |
| 6E | 8.526 | 140739.2 | 62 | 78 | R_{FET} = 842.3 L + |
| | 5.855 | 204956.0 | 132 | 78 | 88640 |
| | 4.671 | 256879.5 | 202 | 78 | |
| | 3.036 | 395314.8 | 362 | 78 | |
| 7E | 9.583 | 125220.4 | 61 | 78 | R_{FET} = 1042.7 L + |
| | 6.710 | 178838.3 | 131 | 78 | 50175 |
| | 4.806 | 249698.2 | 201 | 78 | |
| | 2.771 | 433126.1 | 361 | 78 | |

In Table 6, W represents a channel width. Table 6 shows the channel length L and the channel width W measured using SEM images. In Table 6, “Linear equation” represents a linear equation approximated in each sample.

In FIG. 38, the horizontal axis represents the channel length L and the vertical axis represents the total FET resistance. In FIG. 38, the circles represent the results of the sample 4E, the squares represent the results of the sample 5E, the triangles represent the results of the sample 6E, and the rhombuses represent the results of the sample 7E. The dotted lines in FIG. 38 are approximate straight lines of the samples.

Note that R_{intercept} corresponds to the intercept of each equation shown in the column of “Linear equation” in Table 6 or the intercept of each approximate straight line in FIG. 38.

Next, R_{S/D} was calculated. Note that R_{S/D} in the sample 4E was calculated from the resistivity of the tantalum nitride film included in the sample 4C, R_{S/D} in the sample 5E was calculated from the resistivity of the tantalum nitride film included in the sample 5C, R_{S/D} in the sample 6E was calculated from the resistivity of the tantalum nitride film included in the sample 6C, and R_{S/D} in the sample 7E was calculated from the resistivity of the tantalum nitride film included in the sample 7C. Refer to Table 2 for the resistivity of the tantalum nitride film included in each sample.

Table 7 shows R_{S/D} of each sample calculated from the resistivity of the tantalum nitride film.

TABLE 7

| Sample | Resistivity | Length | Cross-section | R_{S/D} | R_{contact} |
|---|---|---|---|---|---|
| name | [Ωcm] | [m] | [m²] | [Ω] | [Ω] |
| 4E | 2.78 × 10⁻⁵ | 20 × 10⁻⁹ | 2.88 × 10⁻¹⁴ | 19.31 | 104399.20 |
| 5E | 1.25 × 10⁻⁵ | 20 × 10⁻⁹ | 2.88 × 10⁻¹⁴ | 8.68 | 67093.82 |
| 6E | 5.68 × 10⁻⁶ | 20 × 10⁻⁹ | 2.88 × 10⁻¹⁴ | 3.94 | 44316.06 |
| 7E | 3.30 × 10⁻⁶ | 20 × 10⁻⁹ | 2.88 × 10⁻¹⁴ | 2.29 | 25085.21 |

In Table 7, “Length” represents the thickness of the source electrode or the drain electrode, and “Cross-section” represents the area where the source electrode or the drain electrode is in contact with the oxide semiconductor layer.

Note that R_{S/D} can be calculated in the following manner: the resistivity of the tantalum nitride film is multiplied by the thickness and the resulting value is divided by the area. Table 7 shows R_{S/D} calculated.

The contact resistance R_{contact} was obtained using R_{intercept} and R_{S/D} calculated. Table 7 shows the results.

Table 7 reveals that the contact resistance is the lowest in the sample 7E among the samples 4E to 7E. It is also found that when the DC power is decreased from 1.3 kW to 0.5 kW, the contact resistance is approximately quadruple.

Here, the contact conductance was calculated. The contact conductance can be calculated by converting the contact resistance R_{contact} into a reciprocal.

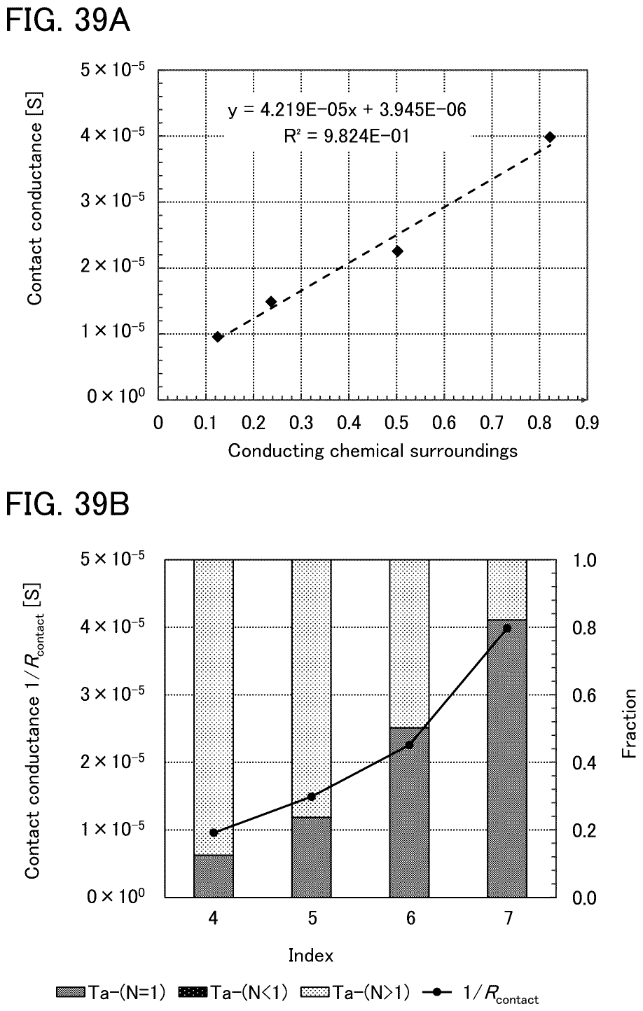

FIGS. 39A and 39B show the calculation results of the contact conductance.

In FIG. 39A, the vertical axis represents the contact conductance and the horizontal axis represents the conducting chemical surroundings. Note that the conducting chemical surroundings were assumed to be the same as those for the XPS analysis results of the sample group A. As described in [Sample fabrication 2], the conductive layers to be the source electrode and the drain electrode were formed under the conditions without oxygen. Furthermore, the oxidation of the source electrode and the drain electrode was assumed to possibly occur on their surfaces but not to occur in the bulk. That is, oxygen was assumed not to exist in the bulk of the source electrode and the drain electrode. Thus, in the source electrode and the drain electrode, not oxides (TaON and Ta₂O₅) but nitrides (Ta(N<1), Ta(N=1), and Ta(N>1)) were assumed to contribute to the tantalum bonding states. In that case, the conducting chemical surroundings refer to the proportion of the sum of the percentage of Ta(N<1) and the percentage of Ta(N=1) in the sum of the percentage of Ta(N<1), the percentage of Ta(N=1), and the percentage of Ta(N>1). FIG. 39A shows the results of the samples of the indexes 4 to 7.

In FIG. 39B, the horizontal axis represents the index, the first vertical axis on the left represents the contact conductance 1/R_{contact}, and the line chart represents contact conductance. FIG. 39B also shows the percentages of the tantalum bonding states. In FIG. 39B, the second vertical axis on the right represents the percentage of the tantalum bonding state (Fraction in the graph), and the bar chart represents the percentages of the tantalum bonding states. Note that FIG. 39B shows the percentage of Ta(N<1), the percentage of Ta(N=1), and the percentage of Ta(N>1).

FIGS. 39A and 39B indicate that the percentages of the tantalum bonding states relate to the contact conductance.

This application is based on Japanese Patent Application Serial No. 2023-065108 filed with Japan Patent Office on Apr. 12, 2023 and Japanese Patent Application Serial No. 2023-078845 filed with Japan Patent Office on May 11, 2023, the entire contents of which are hereby incorporated by reference.

What is claimed is:

1. A semiconductor device comprising:
a first conductive layer;
a first insulating layer over the first conductive layer;
an oxide semiconductor layer over the first insulating layer;
a second conductive layer, a third conductive layer, and a second insulating layer over the oxide semiconductor layer;
a third insulating layer over the second conductive layer and the third conductive layer; and
a fourth conductive layer over the second insulating layer,
wherein the third insulating layer comprises an opening portion reaching the oxide semiconductor layer,
wherein the second insulating layer and the fourth conductive layer are positioned in the opening portion,
wherein a top surface of the third insulating layer is level with a top surface of the fourth conductive layer,
wherein the second conductive layer and the third conductive layer each comprise tantalum and nitrogen,
wherein a percentage of a first tantalum bonding state is lower than or equal to 3% and a percentage of a second tantalum bonding state is higher than or equal to 5% in each of the second conductive layer and the third conductive layer,
wherein the first tantalum bonding state is a bonding state of tantalum metal and a bonding state of tantalum nitride with stoichiometrically less nitrogen per tantalum, and
wherein the second tantalum bonding state is a bonding state of tantalum nitride with stoichiometrically equal nitrogen per tantalum.

2. The semiconductor device according to claim 1,
wherein the percentage of the first tantalum bonding state and the percentage of the second tantalum bonding state are calculated by waveform analysis on an X-ray photoelectron spectroscopy spectrum of tantalum 4f obtained by X-ray photoelectron spectroscopy.

3. The semiconductor device according to claim 1,
wherein X-ray diffraction spectra of the second conductive layer and the third conductive layer each have a first peak having a peak position in a range of 2θ=35.5±1.0 degree and a second peak having a peak position in a range of 2θ=41.2±2.0 degree, and
wherein a ratio of a peak level of the second peak to a peak level of the first peak is greater than or equal to 0.2 and less than or equal to 1.0.

4. The semiconductor device according to claim 3,
wherein the oxide semiconductor layer comprises at least one of indium and zinc.

5. A semiconductor device comprising:
a first conductive layer;
a first insulating layer over the first conductive layer;
an oxide semiconductor layer over the first insulating layer;
a second conductive layer, a third conductive layer, and a second insulating layer over the oxide semiconductor layer;
a third insulating layer over the second conductive layer and the third conductive layer; and
a fourth conductive layer over the second insulating layer,
wherein the third insulating layer comprises an opening portion reaching the oxide semiconductor layer,
wherein the second insulating layer and the fourth conductive layer are positioned in the opening portion,
wherein a top surface of the third insulating layer is level with a top surface of the fourth conductive layer,
wherein X-ray diffraction spectra of the second conductive layer and the third conductive layer each have a first peak having a peak position in a range of 2θ=35.5±1.0 degree and a second peak having a peak position in a range of 2θ=41.2±2.0 degree, and
wherein a ratio of a peak level of the second peak to a peak level of the first peak is greater than or equal to 0.2 and less than or equal to 1.0.

6. The semiconductor device according to claim 5,
wherein the second conductive layer and the third conductive layer each comprise tantalum and nitrogen.

7. The semiconductor device according to claim 6,
wherein the oxide semiconductor layer comprises at least one of indium and zinc.
